(19) United States
(12) Patent Application Publication
(10) Pub. No.: US 2005/0230833 A1
(43) Pub. Date: Oct. 20, 2005

(54) Semiconductor device

(76) Inventors: Hidenori Kato, Hyogo (JP); Masahide Mori, Osaka (JP)

Correspondence Address: DICKSTEIN SHAPIRO MORIN & OSHINSKY LLP, 2101 L Street, NW, Washington, DC, 20037, US

(21) Appl. No.: 11/079,315

(22) Filed: Mar. 15, 2005

(30) Foreign Application Priority Data
Mar. 16, 2004 (JP) NO. 2004-074946

(51) Int. Cl. B21B 1/00; B21C 1/00; B21F 1/00

(52) U.S. Cl. 257/758

(57) ABSTRACT

A semiconductor device includes a base insulation film formed on a semiconductor substrate via another layer, a metal thin-film resistance formed on the base insulation film, and a laser beam interruption film of a metal material interposed between the semiconductor substrate and the base insulation film.

### BACKGROUND OF THE INVENTION

The Present invention generally relates to semiconductor devices and more particularly to a semiconductor device having a metal film resistance formed of a metal thin-film, which in turn is formed on an insulation film.

Resistance elements constitute an important part of analog integrated circuit.

Particularly, a resistance element of a metal thin-film (called hereinafter as metal thin-film resistance) attracts attention in view of its small temperature dependence of the resistance value (TCR).

For the material of such metal thin-film resistance, chromium-silicon (CrSi), nickel chromium (NiCr), tantalum nitride (TaN), chromium silicide (CrSi₂), chromium silicide nitride (CrSiN), chromium silicon oxy (CrSiO), and the like, are used.

With a semiconductor device having such a metal thin-film resistance, it is generally practiced to form the metal thin-film resistance with very small thickness of 1000 Angstroms or less in order to meet for the demand of high integration density and for higher sheet resistance.

Further, a laser trimming process is conducted generally in semiconductor devices after completion of the physical structure thereof for trimming of performance thereof, by irradiating a laser beam to fuse or resistance elements therein for disconnection or modification (reference should be made to Patent Reference 1).

However, with such a laser trimming process, there has been a problem, upon irradiation of the semiconductor substrate such as a silicon substrate via an insulation film such as a silicon oxide film with the laser beam, in that the irradiated laser beam causes damages in the insulation film or silicon substrate and the reliability of the semiconductor device is degraded. Further, there has been a problem, in the trimming process called on-line trimming in which trimming is conducted while measuring the performance of the semiconductor device, in that electron-hole pairs are induced in the silicon substrate as a result of irradiation of the laser beam upon the silicon substrate. Such electron-hole pairs cause noise at the time of performance measurement, and it has been difficult to carry out precise trimming.

In order to minimize such problems there have been various proposals such as disposing a film opaque to the laser beam around the resistance element (reference should be made to Patent Reference 2) or disposing a laser beam shield of polysilicon, refractory metal or refractory metal silicide between a fuse of polysilicon and a silicon substrate (reference should be made to Patent Reference 3).

Conventionally, following methods are known for achieving electrical connection with a metal thin-film resistance:

1) Directly connecting a metal interconnection pattern to the metal thin-film resistance (Patent Reference 4);

2) Forming an interlayer insulation film after formation of the metal thin-film resistance; forming a contact hole in the interlayer insulation film; and connect a metal interconnection via the foregoing contact hole (Patent Reference 5 and Patent Reference 6).

3) Forming a barrier layer on the metal thin-film resistance and connecting a metal interconnection to such a barrier film (Patent Reference 7 and Patent Reference 8); and

4) Forming an electrode in a contact hole formed in an insulation film, forming a resistance film on the insulation film, and forming a pattern of the resistance body by applying an anisotropic etching process to the resistance film such that the resistance pattern makes a contact with the electrode (Patent Reference 4).

Hereinafter, the method of achieving electrical connection to the metal thin-film resistance of the prior art 1)-4) above will be explained with reference to FIG. 35.

1) Referring to FIG. 35, the method of forming a metal interconnection directly on the metal thin-film resistance will be explained.

First, a first interlayer insulation film 5 is formed on a silicon substrate 1 still in the form of wafer but already formed with a device isolation oxide 3 and transistors (not illustrated), and a metal thin-film resistance 101 is formed on the first layer interlayer insulation film 5. Further, a metal film is formed on the entire surface of the first layer interlayer insulation film 5 including the metal thin-film resistance 101 for the purpose of interconnection, and a first layer metal interconnection pattern 103 is formed by patterning the metal film by using a wet etching process.

Here, it should be noted that, in the general fabrication process of semiconductor devices, a dry etching process is used for etching a metal film for formation of interconnection pattern, while in the present case, there exists a metal thin film resistance 101 of small film thickness right underneath the metal film to be patterned, and thus, it is not possible to use the dry etching process, as such a dry etching process causes etching of the metal thin film resistance 101 at the time of the overetching process. Thus, there is a need of forming the first layer metal interconnection pattern 103 by patterning the metal film for interconnection by using a wet etching process.

2) Next, with reference to FIG. 36, the method of forming an interlayer insulation film after formation of the metal thin-film resistance and connecting a metal interconnection by forming a contact hole in such an interlayer insulation film will be explained.

In this process, the device isolation oxide 3, the first interlayer insulation film 5 and the metal thin-film resistance 101 are formed on a silicon substrate 1, and a CVD (chemical vapor deposition) oxide film 105 are formed on the first layer interlayer insulation film 5 including the metal thin-film resistance 101 as an interlayer insulation film to the metal interconnection. Further, a resist pattern having a resist opening in correspondence to both end parts of the metal thin-film resistance 101 is formed on the CVD oxide film 105 for formation of the contact hole used for connection to metal interconnection patterns, and the CVD oxide film 105 is removed selectively by a wet etching process while using the resist pattern as a mask, to form a contact hole 107. After removal of the resist pattern, a metal film of AlSiCu for interconnection is formed on the CVD oxide film 105 so as to include the contact hole 107. By patterning the metal film, a first layer metal interconnection pattern 109 is formed.

In general fabrication process of semiconductor devices, a dry etching process is used generally for formation of such a contact hole 107. In the case in which the thickness of the metal thin-film resistance 101 is smaller than 1000 Angstroms, however, it is difficult to prevent the contact hole 107 to penetrate through the thin metal thin-film resistance 107, and thus, it has been necessary to use a wet etching process for the formation of the contact hole 107.

3) Next, the method of forming a barrier film on a metal thin-film resistance and connect a metal interconnection so such a barrier film will be explained with reference to FIG. 37.

Referring to FIG. 37, the device isolation oxide 3, the first layer interlayer insulation film 5 and the metal thin-film resistance 101 are formed on the silicon substrate 1, and a refractory metal film such as TiW is formed on the first interlayer insulation film 5 including the metal thin-film resistance 101 as a barrier film to the metal interconnection pattern. Thereafter, a metal film for interconnection is formed thereon, and the first layer metal interconnection pattern 111 is formed by patterning the metal film for interconnection by using a dry etching process. Because of the existence of the refractory metal film underneath the interconnection metal film, there arises no problem that the metal thin-film resistance 101 undergoes etching even when a dry etching process is used for the patterning of the metal interconnection pattern 111.

Thereafter, a wet etching process is used to remove the refractory metal film selectively by using the first layer metal interconnection pattern 111 as a mask, and there is formed a refractory metal film pattern 113. In this step of patterning of the foregoing refractory metal film, it should be noted that the use of dry etching process is difficult in view of the existence of the refractory metal film immediately on the metal thin-film resistance 101.

4) Next, the process of forming electrode in a contact hole in an insulation film and forming a resistance pattern by forming a resistance film on the insulation film and patterning the same by a dry etching process in contact with the electrode will be explained with reference to FIG. 38. In the example explained with reference to FIG. 45, a metal interconnection pattern is formed further on the metal interconnection pattern formed underneath the contact hole.

Referring to FIG. 45, the first layer interlayer insulation film 5 is formed on the silicon substrate 1 and a first layer metal interconnection pattern 115 is formed on the first layer metal interlayer insulation film 5.

After formation of an insulation film 117 on the first interlayer insulation film 5, a first contact hole 119 is formed in the insulation film 117 formed on the first layer metal interconnection pattern 115 in correspondence to both ends of the metal thin-film resistance, and a conductive plug (electrode) 121 is formed by filling the first contact hole 119 with a conductive material. In this step, it should be noted that no contact hole is formed for electrical connection with a second layer metal interconnection pattern to be formed later.

Next, a metal film for metal thin-film resistance is formed on the entire surface of the insulation film 117, and the metal thin-film resistance 101 is formed on the conductive plug 121 and the insulation film 117 by patterning the metal film.

Further, an insulation film 123 is formed on the entire surface of the insulation film 117 so as to prevent etching of the metal thin-film resistance 101 at the time of patterning the second metal interconnection pattern to be later by using a dry etching process. Further, a second contact hole 125 is formed in the insulation films 117 and 123 on the first layer metal interconnection pattern in an area different from the area where the metal thin-film resistance 101 is formed for electrical connection with the second layer metal interconnection pattern. Further, a second conductive plug 127 is formed by filling the second contact hole with a conductive material. Further, a metal film for the second layer metal interconnection is formed on the insulation film 123 so as to include the region where the second conductive plug 127 is formed, and the metal film is patterned by a photolithographic process and dry etching process to form a second layer metal interconnection pattern 129 on the second conductive plug 127 and the insulation film 123.

Further, there is disclosed a semiconductor integrated circuit device equipped with a resistance, although not a thin-film resistance, formed on the uppermost interconnection electrode via an insulation film in electrical connection with the foregoing uppermost interconnection electrode (reference should be made to Patent Reference 9, for example).

Referring to FIG. 39, a hypothetical case in which such a structure is applied to a metal thin-film resistance is explained.

Referring to FIG. 39, the first interlayer insulation film 5 is formed on the silicon substrate 1 carrying the device isolation oxide 3, and after formation of the first layer metal interconnection pattern 115 on the first layer interlayer insulation film 5, an underlying insulation film 131 is formed on the entire surface of the first interlayer insulation film 5 including the first layer metal interconnection pattern 115. Further, a contact hole 133 is formed in the underlying insulation film 131 on the first metal interconnection pattern 115 by using a photolithographic process and a dry etching process. Further, a metal thin-film for the metal thin-film resistance is formed on the entire surface of the underlying insulation film 131 including the region where the contact hole 133 is formed, and the metal thin-film resistance 101 is formed by patterning the metal thin-film in a predetermined shape.

Further, there is a disclosure of a semiconductor integrated circuit carrying a metal thin-film resistance on an insulation film, wherein the contact between the metal thin film resistance and the metal interconnection in the electrode part of the metal thin-film resistance is achieved in an end part and at least a top part of the terminal region of the metal interconnection (reference should be made to Patent Reference 10).

Referring to FIG. 40, the method of achieving electrical contact between the metal thin-film resistance and the metal interconnection at the end part and at least a part of the top surface of the metal interconnection will be explained.

Referring to FIG. 40, the first interlayer insulation film 5 is formed on the silicon substrate 1 carrying the device isolation oxide film 3, and the first metal interconnection pattern 115 is formed on the first interlayer insulation film 5. Further, a plasma nitride film 135 is formed on the entire surface of the first interlayer insulation film 5 including the first layer metal interconnection pattern 115, and the end part and a part of the to surface of the first layer metal interconnection pattern are exposed by removing a part of the plasma nitride film 135. Thereafter, a metal thin film for the metal thin-film resistance is deposited by evaporation deposition process, and the metal thin-resistance 101 is formed by patterning the metal thin-film thus formed.

### REFERENCES

Patent Reference 1 Japanese Laid-Open Patent Application 8-124729 official gazette
Patent Reference 2 Japanese Laid-Open Patent Application 56-58256 official gazette
Patent Reference 3 Japanese Laid-Open Patent Application 58-170 official gazette
Patent Reference 4 Japanese Laid-Open Patent Application 2002-124639 official gazette
Patent Reference 5 Japanese Laid-Open Patent Application 2002-261237 official gazette
Patent Reference 6 Japanese Patent 2,699,559
Patent Reference 7 Japanese Patent 2,932,940
Patent Reference 8 Japanese Patent 3,185,677
Patent Reference 9 Japanese Laid Open Patent Application 58-148443 official gazette
Patent Reference 10 Japanese Laid-Open Patent Application 61-100956 official gazette

### SUMMARY OF THE INVENTION

With the conventional semiconductor device explained with reference to FIGS. 35 through 40, there has been a problem in that, upon irradiation of the semiconductor substrate such as a silicon substrate via an insulation film such as a silicon oxide film with the laser beam at the time of trimming of the metal thin-film resistance, the irradiated laser beam causes damages in the insulation film or silicon substrate and the reliability of the semiconductor device is degraded. Further, there has been a problem at the time of on-line trimming process in that electron-hole pairs are induced in the silicon substrate as a result of irradiation of the laser beam upon the silicon substrate. Such electron-hole pairs cause noise at the time of performance measurement, and it has been difficult to carry out precise trimming.

In order to avoid such problems, it is necessary to set the laser power to the range between a minimum power capable of disconnecting or modifying the metal thin-film resistance and the maximum power in which the semiconductor substrate undergoes modification, while it should be noted that such a range is narrow and stable trimming is difficult.

Thus, the present invention provides a semiconductor device capable of eliminating irradiation of laser beam upon the semiconductor substrate at the time of laser trimming process in which a laser beam having an intensity sufficient to cause disconnection or modification in the metal thin-film resistance is irradiated.

More specifically, the semiconductor device of the present invention comprises a base insulation film formed over a semiconductor substrate via another layer; a metal thin-film resistance formed on said base insulation film; and a laser beam interruption film of a metal material disposed between said semiconductor substrate and said base insulation film in a region underneath said metal thin-film resistance.

With the method 1) of forming electrical connection with the metal thin-film resistance explained with reference to FIG. 35, it is not possible to carry out the patterning of the first layer metal interconnection pattern 103 by a dry etching process in view of the fact that the first layer metal interconnection pattern 103 is formed directly on the metal thin-film resistance 101. Thus, there has been a problem that formation of minute patterns is difficult and increase of integration density is difficult.

Further, the metal thin-film resistance 101 easily undergoes oxidation, and there has been a problem that good electrical contact is not attained between the metal thin-film resistance 101 and the first layer metal interconnection pattern 103 even when the metal film for the first layer metal interconnection pattern 103 is formed in the state that the surface of the metal thin-film resistance 101 is oxidized.

In generally used fabrication process of semiconductor devices, good electrical contact to a metal interconnection is achieved by removing the native oxide film on the surface of silicon substrate, or the like, by using a hydrofluoric acid solution. However, the metal thin-film resistance 101 undergoes substantial etching when applied with a fluoric acid, and thus, there has been a problem that the resistance value of the metal thin-film resistance 101 may change variously when an oxide film removal process is applied before formation of the metal film for the first layer metal interconnection pattern 103 by using a hydrofluoric acid.

In the method 2) explained with reference to FIG. 36, on the other hand, it is possible to carry out the patterning of the metal film for forming the first layer metal interconnection pattern 109 by forming the interlayer insulation film 85 on the metal thin-film resistance 101.

However, with regard to the formation of the contact hole 107 for connecting the metal thin-film resistance 101 and the first layer metal interconnection pattern 109 electrically, there is a need of using a wet etching process as explained before, while the use of wet etching process is contradictory to the increase of integration density by way of device miniaturization. Further, in relation to the use of hydrofluoric acid solution at the time of the wet etching process for formation of the contact hole 107, there has been a need of providing additional steps such as formation of a barrier film on the metal thin-film resistance 101 and patterning of such a barrier film in order to prevent the problem of the metal thin-film resistance 101 being etched by the hydrofluoric acid solution, while such additional steps increases the fabrication cost of the semiconductor integrated circuit.

Further, with the method 3) explained with reference to FIG. 37, it is possible to carry out the etching process of the first layer metal interconnection pattern 111 by using a dry etching process. Further, formation of contact hole can be eliminated. However, this conventional process requires the use of a wet etching process for patterning of the refractory metal film at the time of formation of the refractory metal pattern 113 that determines the length of the metal thin-film resistance substantially, and there arises a problem that the refractory metal pattern 113 may be etched beyond the desired etching region, while this leads to the problem of increased variation in the length of the metal thin-film resistance 101 and hence increased variation of the resistance. Associated with this, there arises a difficulty that miniaturization becomes difficult.

Further, the surface of the metal thin-film is oxidized at the time of formation of the refractory metal film for the refractory metal pattern 113, and thus, it becomes necessary to conduct removal of the oxide film from the surface of the metal thin-film resistance 101 by using a hydrofluoric acid for ensuring good electrical contact with the refractory metal pattern 113. However, such oxide removal process by hydrofluoric acid causes the problem of variation of resistance of the metal thin-film resistance 101 when it is conducted before formation of the refractory metal pattern 113.

Thus, as explained heretofore, any of the methods 1)-3) explained with reference to FIGS. 35-37 has necessitated a wet etching process in any of the process steps therein in view of the very small thickness of the metal thin-film resistance, while the use of such a wet etching process has caused the problem of increased variation of the resistance value and places obstacles in the device miniaturization.

Further, the metal thin-film resistance easily undergoes oxidation and it is difficult to achieve good electrical contact with a metal interconnection. Thus, it has been necessary to provide additional steps of forming a barrier film dedicated for the metal thin-film resistance or removal of the surface oxide film by using a hydrofluoric acid solution. However, such additional process steps increases the number of process steps at the time of fabrication of a semiconductor integrated circuit and also causes increased of variation of the resistance value.

In order to overcome the foregoing problems, the semiconductor device according to the first mode of the present invention has a construction comprising: a lower insulation film formed underneath a base insulation film serving for an underlying film of a metal thin-film resistance; a metal interconnection pattern formed on said lower insulation film; and a contact hole formed in said base insulation film on said metal interconnection pattern, said metal thin-film resistance extending from a top surface of said base insulation film to an interior of said contact hole and connected electrically to said metal interconnection pattern in said contact hole.

Here, the base insulation film underlying the metal thin-film resistance may be a single layer insulation film or a laminated film in which plural insulation films are laminated.

Further, in the case of forming the metal thin-film resistance such that a part of the metal thin-film resistance is located inside the contact hole formed in the base insulation film on the metal interconnection pattern, there arises a problem as shown in FIG. 39 that the step coverage of the metal thin film resistance 101 is deteriorated at the inner sidewall surface of the contact hole 133, particularly at the part close to the bottom of the contact hole 133, and there tends to appear the problem of large contact resistance between the metal thin-film resistance 101 and the first layer metal interconnection pattern 115. Associated with this, there arises large variation of contact resistance.

In order to eliminate such problems, it is possible to modify the construction of the first mode such that at least a top edge part of the contact hole has a tapered shape and an Ar sputter etching residue containing at least the material of the metal interconnection pattern, the material of the insulation film and Ar as the constituent elements thereof, is formed on the inner wall of the contact hole. It should be noted that such an Ar sputter etching residue and the tapered shape at the top edge part of the contact hole can be formed by applying, after formation of the contact hole in the base insulation film, an Ar sputter etching process while using an Ar gas (referred to hereinafter as Ar sputter etching).

Further, it is possible to construct the first mode of the present invention such that the metal interconnection pattern is formed of a metal pattern and a refractory metal film formed at least on the top surface of the metal pattern.

According to a second mode of the present invention, there is provided a semiconductor device, comprising: a lower insulation film formed underneath said base insulation film; a metal interconnection pattern formed on said lower insulation film; a contact hole formed in said base insulation film above said metal interconnection pattern, and a conductive plug formed in said contact hole, said metal thin-film resistance being formed so as to extend from said top surface of said insulation film to said conductive plug.

In any of the semiconductor devices of the first mode and the second mode, the metal interconnection pattern may be the uppermost metal interconnection pattern.

Further, in the second mode, it is possible to construct the semiconductor device such that the semiconductor device further includes: a second contact hole, in addition to said first contact hole, such that the second contact hole is formed in said base insulation film above said metal interconnection pattern at a location different from said first contact hole; a second conductive plug in addition to said first conductive plug such that said second conductive plug is formed in said second contact hole simultaneously with said first conductive plug; and a second interconnection pattern formed on said second conductive plug and said insulation film, said first conductive plug and said second conductive plug being formed of a first conductive material formed on an inner wall surface of said first contact hole and said second contact hole, and a second conductive material formed on said first conductive material, a top end part of said first contact hole being formed with a separation from a top edge part of said first contact hole and a top surface of said second conductive material in said first contact hole formed underneath said metal thin-film resistance, an outer periphery of a top surface of said second conductive material and said top edge part of said first contact hole forming a tapered shape, a space formed on said first conductive material between an inner wall of said first contact hole and said first conductive material being formed with an Ar sputter etching residue containing therein at least a material of said base insulation film, said first conductive material and Ar.

The tapered shape and the Ar sputter etching residue can be formed by applying an Ar sputter etching process to the base insulation film in the state in which there is formed a depression around the first conductive plug at the time of selectively removing a metal film formed on the first conductive plug for formation of the second metal interconnection pattern, after forming the first conductive plug and the second conductive plug by filling the first contact hole and the second contact hole with the conductive material and forming the foregoing metal film for the second metal interconnection pattern on the both conductive plugs and on the base insulation film The second metal interconnection pattern may be the uppermost metal interconnection pattern.

In the first and second modes, it is possible to form the laser beam interruption film on the lower insulation film by using the same material as metal interconnection pattern.

In the first mode and second mode, it is possible that the laser beam interruption film may be disposed below the metal interconnection pattern.

According to the third mode of the present invention, the semiconductor device may include a metal interconnection pattern formed on the insulation film. Thereby, the metal thin-film resistance is formed so as to extend from the top surface of the insulation film to the metal interconnection pattern.

In this third mode, it is possible to construct such that there is provided with a sidewall insulation film on the sidewall surface of the metal interconnection pattern and form the metal thin-film resistance so as to extend from the top surface of the base insulation film to the metal interconnection pattern via the surface of the sidewall insulation film.

In the foregoing third mode, it is further possible to construct the semiconductor device such that there is formed an Ar sputter etching residue on the surface of the sidewall insulation film close to the base insulation film such that the Ar sputter etching residue contains at least the material of the sidewall insulation film and Ar as the constituent elements. It should be noted that such an Ar sputter etching residue can be formed by applying an Ar sputter etching process after formation of the metal interconnection pattern and the sidewall insulation film.

With the fourth mode of the present invention, the semiconductor device comprises a lower insulation film formed underneath said base insulation film and a metal interconnection pattern formed on said lower insulation film, wherein said base insulation film is formed on said lower insulation film with a thickness such that a top surface of said metal interconnection pattern is exposed, said metal thin-film resistance being formed so as to extend from a top surface of said base insulation film over said metal interconnection pattern.

In the embodiment of third mode in which the metal interconnection pattern carries the sidewall insulation film on the sidewall surface thereof, and also in the fourth mode of the present invention, the metal interconnection pattern may be formed of a metal pattern and a refractory metal film may be formed at least on the top surface of the metal pattern.

Further, in the embodiments of the foregoing third mode and further in the foregoing fourth mode, it is possible to form the metal thin-film resistance so as to intersect with the metal interconnection pattern. Here, the phrase “the metal thin-film resistance intersects the metal interconnection pattern” means in the foregoing third mode that a part of the metal thin-film resistance is formed so as to extend over the metal interconnection pattern from the sidewall insulation film at a first side of the metal interconnection pattern to the sidewall insulation film at a second, opposite side of the metal interconnection pattern. In the fourth mode, on the other hand, this means that a part of the thin-film resistance extends from a part of the base insulation film located in the vicinity of one side of the metal interconnection pattern to the base insulation film located at the opposite side over the metal interconnection pattern.

Further, in the foregoing third mode and fourth mode, the metal interconnection pattern may be the metal interconnection pattern of the uppermost layer.

In the semiconductor device of the present invention, the metal thin-film resistance may have the thickness of 5-1000 Angstroms, preferably 20-500 Angstroms.

Further, in the semiconductor device of the present invention, the base insulation film may be processed with a planarization process.

In the semiconductor device of the present invention, it is possible to provide a metal nitride film covering the top surface of the metal thin-film resistance such that no metal oxide film is formed between the top surface of the metal thin-film resistance and the metal nitride film.

In another example, the semiconductor integrated circuit device of the present invention may be applied to a semiconductor device having a voltage divider providing a divided voltage output by using two or more resistance elements and capable of adjusting the voltage output by laser beam irradiation to the resistance elements.

In a further example, the semiconductor integrated circuit device of the present invention may be applied to a semiconductor device having a voltage detection circuit including therein a voltage divider dividing an input voltage and producing a divided voltage; a reference voltage generator producing a reference voltage; and a comparator comparing the divided voltage from the voltage divider and the reference voltage from the reference voltage generator. Thereby, the voltage divider constituting the voltage detection circuit uses the metal thin-film resistance of the present invention for the resistance elements.

In a further example, the semiconductor integrated circuit device of the present invention may be applied to a semiconductor device having a constant voltage generator including therein: an output driver for controlling an output of an input voltage; a voltage divider dividing the output voltage to provide a divided voltage; a reference voltage generator providing a reference voltage; and a comparator circuit comparing the divided voltage from the voltage divider and the reference voltage from the reference voltage generator and controlling the operation of the output driver in response to the result of the comparison. Thereby, the voltage divider constituting the constant voltage generator uses the metal thin-film resistance and the laser beam interruption film of the present invention for the resistance elements thereof.

With the semiconductor device of the present invention, a laser beam interruption film of a metal material is interposed between the semiconductor substrate and the base insulation film serving for the underlying film of the metal thin-film resistance, and thus, it is possible to reflect the laser beam passed through the base insulation film, in the case a laser beam of sufficient energy for causing disconnection or modification of the metal thin-film resistance is irradiated to the metal thin-film resistance at the time of the laser trimming process, in the direction away from the semiconductor substrate. Further, with such a construction, it becomes possible to prevent degradation of reliability of the semiconductor device originating from the laser beam irradiation to the semiconductor substrate at the time of the trimming process. Further, formation of electron-hole pairs associated with laser beam irradiation to the semiconductor substrate is suppressed at the time of the on-line trimming processing, and it becomes possible to conduct high precision trimming.

In the semiconductor device according to the first mode of the present invention, the lower insulation film is formed underneath the base insulation film, which is used for the underlying film of the metal thin-film resistance, in addition to the construction that uses the laser beam interruption film, wherein the semiconductor device further includes the metal interconnection pattern formed on the lower insulation film and the contact hole formed in the base insulation film above the metal interconnection pattern. Thereby, the metal thin-film resistance is formed so as to extend from the top surface of the insulation film to the interior of the contact hole such that the metal thin-film resistance is connected electrically to the metal interconnection pattern in the contact hole.

Further, with such a construction, there is no need of carrying out a patterning process after formation of the metal thin-film resistance by using a wet etching process, contrary to the conventional technology explained with reference to FIGS. 35-37. Further, because the contact surface of the metal thin-film resistance to the metal interconnection pattern is not exposed to the air, good electrical contact is guaranteed between the thin-film resistance and the metal interconnection pattern without applying a surface oxide removal process or forming an etching stop barrier film to the metal thin-film resistance. With this, it becomes possible to achieve miniaturization of the metal thin-film resistance and simultaneously stabilization of the resistance value irrespective of the thickness of the metal thin-film resistance, without increasing the number of fabrication steps.

Further, by forming a tapered shape in at least the top edge part of the contact hole and forming the Ar sputter etching residue, containing the material of the metal interconnection pattern, the material of the foregoing base insulation film and Ar as the constituent elements thereof, on the inner wall of the contact hole, the step coverage of the metal thin-film resistance in the contact hole is improved as a result of existence of the Ar sputter etching residue, and stabilization of contact resistance is achieved between the metal thin-film resistance and the metal interconnection pattern. Further, as a result of the tapered shape formed at least in the top edge part of the contact hole, formation of overhang structure by the metal thin film deposited in the vicinity of the top edge part of the contact hole is prevented, and adversary effect of such an overhang structure on the deposition of the metal film inside the contact hole is reduced. Thereby, step coverage of the metal thin film and hence the step coverage of the metal thin-film resistance is improved.

Conventionally, there has been a problem that the metal thin-film resistance is affected by the underlying film such as the resistance value thereof is changed depending on the composition of the underlying film or with the time elapsed after formation of the underlying film.

As noted already, the present invention preferably uses the Ar sputter etching process after formation of the contact hole in the base insulation film for formation of the tapered shape at the top edge part of the contact hole and for formation of the deposits of the Ar sputter etching residue, while the use of such Ar sputter etching process to the base insulation film in advance of formation of the metal thin-film for the metal thin-film resistance reduces at the same time the problem of dependence of the sheet resistance of the metal thin-film resistance on the underlying film and the problem of aging of the metal thin-film resistance.

The effect achieved by applying an Ar sputter etching process to the underlying film of the metal thin-film resistance will be explained in detail in later.

Further, by forming the metal interconnection pattern in the form of lamination of the metal material pattern and the refractory metal film formed at least on such a metal material pattern, it becomes possible interpose the refractory metal film between the metal thin-film resistance and the metal material pattern in any of the first, second and third modes of the present invention, and variation of contact resistance between the metal thin-film resistance and the metal interconnection pattern can be reduced. Thereby, the precision of the resistance value is improved together with the yield of production of the semiconductor device. Further, it becomes possible to eliminate the problem caused in the structure in which a metal thin-film resistance and a metal material make a direct contact, in that the contact resistance changes significantly when a thermal annealing process is applied at a relatively low temperature of 300-400° C.

According to the second mode of the present invention, in which the lower insulation film and the metal interconnection are disposed between the semiconductor substrate and the base insulation film serving for the underlying layer of the metal thin-film resistance, and in which the contact hole and conductive plug are formed in the foregoing base insulation film in the part located above the metal interconnection pattern, and in which the metal thin-film resistance is formed so as to extend from the base insulation film over the conductive plug. Thus, it is possible to eliminate the patterning step by a wet etching process after formation of the metal thin-film resistance, similarly to the first mode of the present invention. Further, there is no chance that the contact surface of the metal thin-film resistance to the metal interconnection pattern is exposed to the air, and it is possible to achieve good electrical contact between the metal thin-film resistance and the metal interconnection pattern without conducting a surface oxide removal process or forming an etching stop barrier film to the metal thin-film resistance. With this, it is possible to achieve miniaturization of the metal thin-film resistance and stabilization of the resistance value irrespective of the thickness of the metal thin-film resistance, without increasing the number of the process steps.

Further, because the metal thin-film resistance is formed so as to extend on the conductive plug and on the base insulation film, increase of variation of the resistance value or increase of the contact resistance as explained with reference to FIG. 39, in which case the electrical contact is made between the metal thin-film resistance and the metal interconnection pattern via the contact hole formed on the metal interconnection pattern and there is caused an increase of variation of the resistance value in the metal thin-film resistance or increase of contact resistance between the metal thin-film resistance and the electrode as a result of poor step coverage, is successfully avoided.

Further, in any of the first and second modes of the present invention, it is possible to increase the degree of freedom of design by using the metal interconnection pattern for the uppermost metal interconnection pattern. Thereby, it becomes possible to achieve layout change of the metal thin-film resistance easily by changing the layout of the metal thin-film resistance and further the uppermost metal interconnection pattern.

Further by forming the metal thin-film resistance at the upper level of the insulation film on which the uppermost metal interconnection pattern is formed, the metal thin-film resistance is covered with the insulative final passivation film, and it becomes possible to reduce the variation of such a passivation film by reducing the thickness of the insulation film formed on the metal thin-film resistance as compared with the case in which other insulation films are formed on the metal thin-film resistance in addition to the final passivation film.

With this, variation of leaser beam interference caused by the insulation material on the metal thin-film resistance is reduced at the time of conducting a trimming process by applying a laser beam to the metal thin-film resistance, and the variation of laser beam energy provided to the metal thin-film resistance is reduced. Thereby, the precision of trimming is improved. Further, by reducing the thickness of the insulating material on the metal thin-film resistance, it is possible to improve the efficiency of heat radiation caused by temperature rise at the time of the trimming processing, which in turn is caused by the laser beam irradiation.

Further, in the second mode, in which the semiconductor device further includes a second contact hole formed in the foregoing base insulation film in the part located above the metal interconnection pattern but different from the foregoing first contact hole, a second conductive plug formed in the second contact hole simultaneously to the formation of the first conductive plug, and the second metal interconnection pattern formed over the second conductive plug and the base insulation film, the foregoing first conductive plug and the second conductive plug being formed of the first conductive material formed on the inner wall surface of the respective first contact hole and the second contact hole, and the second conductive material formed on the first conductive material, the top end of the first conductive material being formed, in the first contact hole formed underneath the metal thin-film resistance, with a separation from the top edge part of the first contact hole and the top surface of the second conducive material, the outer periphery of the top surface of the first conducive material and the top edge part of the first contact hole being shaped to have a tapered form, an Ar sputter etching residue containing at least the material of the base insulation film, and the first conductive material and Ar as the constituent elements thereof filling a space formed on the first conductive material between the inner wall surface of the first contact hole and the second conducive material, it becomes possible to improve the step coverage of the metal thin-film resistance in the vicinity of the first contact hole as compared with the case in which no such a tapered shape or Ar sputter etching residue is formed. Thereby, the resistance value of the metal thin-film resistance is improved together with the precision thereof.

Further, while it is possible to form the foregoing tapered shape and the Ar sputter etching residue by applying an Ar sputter etching process to the foregoing base insulation film in the state in which a depression is formed around the conductive plug as a result of removal of the top part of the first conductive material constituting the conductive plug as noted above, such an Ar sputter etching process applied to the underlying film of the metal thin-film resistance before formation of the metal thin-film for the metal thin-film resistance brings forth the effect of reducing the dependence of sheet resistance of the metal thin-film resistance upon the underlying film and reducing the aging effect of the sheet resistance of the metal thin-film resistance. The effect attained by applying the Ar sputter etching process to the underlying film of the metal thin-film resistance will be explained in detail later.

Further, by providing the foregoing second metal interconnection pattern as the uppermost metal interconnection pattern, it is possible to achieve the effects such as increase in the degree of freedom of design, improvement of precision of trimming, improvement of heat radiation efficiency, and the like, similarly to the case the first metal interconnection pattern is the uppermost metal interconnection pattern.

Further, in the first and second modes noted above, it is possible to form a laser beam interruption film without using a dedicated process by forming the lower beam interruption film on the lower insulation film with the material identical with the material of the metal interconnection pattern, and it becomes possible to avoid increase of the fabrication process steps. Here, the laser beam interruption film may be formed in continuation with the metal interconnection pattern or with separation from the metal interconnection pattern.

Further, in the first and second modes of the present invention, it is possible to avoid irradiation of laser beam upon the semiconductor substrate by forming the laser beam interruption film underneath the metal interconnection pattern.

With the third mode of the present invention, the metal interconnection pattern is formed on the base insulation film used for the underlying film of the metal thin-film resistance, and the metal thin-film resistance is formed so as to extend over the metal interconnection pattern from the top surface of the base insulation film.

In this mode, too, there is no need of carrying out a patterning process after formation of the metal thin-film resistance by using a wet etching process. Further, because the contact surface of the metal thin-film resistance to the metal interconnection pattern is not exposed to the air, good electrical contact is guaranteed between the thin-film resistance and the metal interconnection pattern without applying a surface oxide removal process or forming an etching stop barrier film to the metal thin-film resistance. With this, it becomes possible to achieve miniaturization of the metal thin-film resistance and simultaneously stabilization of the resistance value irrespective of the thickness of the metal thin-film resistance, without increasing the number of fabrication steps.

Further, because the metal thin-film resistance is formed so as to extend over the metal interconnection pattern from the top surface of the base insulation film, there is no need of conducting a series of process steps of forming a contact hole contrary to he case of achieving electrical connection between the metal thin-film resistance and the metal interconnection pattern via a contact hole formed on the metal interconnection pattern, and thus, it is possible to reduce or simplify the fabrication process. Further, it is possible to avoid the problem of variation of resistance value of the metal thin-film resistance or increase of contact resistance to the electrode caused by the poor step coverage of the metal thin-film at such a contact hole.

Further, by providing the sidewall insulation film on the sidewall surface of the metal interconnection pattern in the third mode of the present invention and form the metal thin-film resistance so as to extend over the metal interconnection pattern from the base insulation film over the surface of the sidewall insulation film, it is possible to avoid deterioration of step coverage for the metal thin-film resistance by eliminating the sharp step at the sidewall surface of the metal interconnection pattern, and the resistance value of the metal thin-film resistance is stabilized.

Further, while it is possible to form the Ar sputter etching residue containing at least the material of the sidewall insulation film and Ar as the constituent elements thereof on the surface of the sidewall insulation film close to the base insulation film, by applying the Ar sputter etching after formation of the metal interconnection pattern and the sidewall insulation film, it is possible to reduce the dependency of sheet resistance of the metal thin-film resistance on the underlying base film and further reduce the aging of the sheet resistance by applying an Ar sputter etching process to the base film of the metal thin-film resistance before formation of the metal thin-film used for formation of the metal thin-film resistance. Detailed description will be made about the effect achieved by applying such an Ar sputter etching process to the underlying film of the metal thin-film resistance.

With the semiconductor device according to the fourth mode of the present invention, in which the lower insulation film and the metal interconnection pattern are formed underneath the base insulation film serving for the underlying film of the metal thin-film resistance and the base insulation film is formed on the lower insulation film with the thickness exposing the top surface of the metal interconnection pattern, and the metal thin-film resistance is formed so as to extend over the metal interconnection pattern from the foregoing base insulation film, there is no need of conducting a patterning process after formation of the metal thin-film resistance by using a wet etching process. Further, because the contact surface of the metal thin-film resistance for contact with the metal interconnection pattern is not exposed to the air, it is possible to achieve good electrical contact between the metal thin-film resistance and the interconnection pattern without applying a surface oxide removal process or formation of etching barrier film to the metal thin-film resistance.

Thus, with this mode, too, it is possible to miniaturize the metal thin-film resistance and stabilize the resistance value thereof irrespective of the thickness of the metal thin-film resistance, without increasing the number of the process steps.

Further, by forming the metal interconnection pattern in the form of lamination of at least a metal material pattern and a refractory metal film formed on such a metal material pattern in the embodiment of the third mode in which a sidewall insulation film is formed on the sidewall surface of the metal interconnection pattern or in the fourth mode, it becomes possible interpose the refractory metal film between the metal thin-film resistance and the metal material pattern, and variation of contact resistance between the metal thin-film resistance and the metal interconnection pattern can be reduced, similarly to the case of the first mode in which the metal interconnection pattern is formed of the metal pattern and the refractory metal film. Thereby, the precision of the resistance value is improved together with the yield of production of the semiconductor device. Further, it becomes possible to eliminate the problem caused in the structure in which a metal thin-film resistance and a metal material make a direct contact, in that the contact resistance changes significantly when a thermal annealing process is applied at a relatively low temperature of 300-400° C.

Further, by forming the metal thin-film resistance in the third and fourth modes of the present invention so as to cross the metal interconnection pattern, it becomes possible to eliminate the variation of the contact area between the electrode and the metal thin-film resistance caused by misalignment of the metal interconnection pattern and the metal thin-film resistance or by the rounding of the end part of the metal thin-film resistance, and further stabilized contact resistance ca be attained.

Further, by providing the foregoing metal interconnection pattern as the uppermost metal interconnection pattern in the third and fourth modes of the present invention, it is possible to achieve the effects such as increase in the degree of freedom of design, improvement of precision of trimming, improvement of heat radiation efficiency, and the like, similarly to the case the first and second modes.

In the first mode, second mode, third mode and fourth mode, there is no need of conducting a patterning process after formation of the metal thin-film resistance by a wet etching process even in the case the metal thin-film resistance has the thickness of 5-1000 Angstroms, preferably 20-500 Angstroms, and there is no need of conducting a patterning process after formation of the metal thin-film resistance by using a wet etching process. Further, because the contact surface of the metal thin-film resistance for contact with the metal interconnection pattern is not exposed to the air, it is possible to achieve good electrical contact between the metal thin-film resistance and the interconnection pattern without applying a surface oxide removal process or formation of etching barrier film to the metal thin-film resistance.

Thus, with this mode, too, it is possible to miniaturize the metal thin-film resistance and stabilize the resistance value thereof irrespective of the thickness of the metal thin-film resistance, without increasing the number of the process steps.

Particularly, with the mode in which there is provided the foregoing Ar sputter etching residue, the dependence of sheet resistance value of the metal thin-film resistance on the underlying film is reduced, and it becomes possible to stabilized the resistance value of the metal thin-film resistance even when the present invention is applied to the semiconductor devices having metal thin-film resistance of the foregoing film thickness.

Further, it is possible to suppress the variation of resistance value of the metal thin-film resistance caused by the steps formed on the base insulation film, by applying a planarization process to the base insulation film, which is used for the underlying film of the metal thin-film resistance.

Further, in the semiconductor device of the present invention, it is possible to eliminate the problem of oxidation of the top surface of the metal thin-film resistance by forming a metal nitride film covering the top surface of the metal thin-film resistance such that there is formed no metal oxide film between the top surface of the metal thin-film resistance and the metal nitride film. Thereby, the resistance value of the metal thin-film resistance is improved together with the precision thereof.

Further, in the semiconductor device having a voltage divider providing a voltage output by voltage dividing by using two or more resistance elements and capable of adjusting the voltage output by irradiation of laser beam to the resistance elements, the present invention provides the resistance elements constituting the voltage divider such that the resistance element is formed of the metal thin-film resistance and the laser beam interruption film. Thereby, irradiation of the laser beam upon the semiconductor substrate is avoided even in the case the laser beam is irradiated with the intensity sufficient for causing disconnection or modification of the metal thin-film resistance for the purpose of laser trimming, and it becomes possible to improve the precision of the output voltage of the voltage divider.

Also, in the semiconductor device including a voltage divider for producing a divided voltage by dividing an input voltage, a reference generator for producing a reference voltage, and a comparator circuit for comparing the divided voltage from the voltage divider and the reference voltage from the reference voltage generator, it becomes possible to improve the precision of the output voltage of the voltage divider by using the thin-film resistance and the laser beam interruption film of the present invention for the voltage divider. Thereby, the precision of voltage detection of the voltage detector is improved.

Also, in the semiconductor device including an output driver controlling an output of an input voltage, a voltage divider for producing a divided voltage by dividing the output voltage, a reference voltage generator for producing a reference voltage, and a comparator circuit comparing the divided voltage from the voltage divider and the reference voltage from the reference voltage generator and controlling the operation of the output driver in response to the result of comparison, it becomes possible to improve the precision of the output voltage of the voltage divider by using the metal thin-film resistance of the present invention for the resistance elements of the voltage divider and by using the laser beam interruption film. Thus, the output voltage of the constant voltage generator is stabilized.

### BRIEF DESCRIPTION OF THE DRAWINGS

FIGS. 1A and 1B are cross-sectional diagrams showing an embodiment of the first mode of the present invention wherein FIG. 1A is a cross-sectional view showing a region where a metal thin-film resistance is formed while FIG. 1B is an enlarged cross-sectional diagram showing a part of FIG. 1A circled by a broken line;

FIGS. 2A-2D are cross-sectional diagrams showing a fabrication process of the foregoing embodiment;

FIG. 3 is a cross-sectional diagram showing the state of a contact hole in the fabrication process of FIGS. 2A-2D after applying an AR Ar sputter etching process;

FIG. 4 is a diagram showing a relationship between a sheet resistance and film thickness of the metal thin-film resistance formed according to the present invention, wherein the vertical axis represents the sheet resistance in terms of Ω/□, while the horizontal axis represents the thickness of a CrSi film in terms of Angstroms;

FIG. 5 is a diagram showing the relationship between a quantity a/AVE representing the standard deviation a of the sheet resistance values of the metal thin-film resistance of the present invention measured at 63 points on the wafer surface as divided by the average AVE thereof and the film thickness, wherein the vertical axis represents the quantity σ/AVE in terms of percent, while the horizontal axis represents the film thickness of the CrSi film in terms of Angstroms;

FIGS. 6A and 6B are diagrams showing the relationship between the sheet resistance of a CrSi thin-film resistance and the time elapsed after formation of the underlying film of the metal thin-film resistance for the case an Ar sputter etching process is applied before formation of a metal thin-film for the metal thin-film resistance and for the case no such Ar sputter etching process has been conducted, wherein FIG. 6A shows the case in which the Ar sputter etching has been conducted while the FIG. 6B shows the case no such Ar sputter etching process has been conducted, the vertical axis representing the sheet resistance in terms of Ω/□, the horizontal axis representing the time elapsed after formation of the underlying film in terms of hours;

FIG. 7 is a diagram showing the relationship between the amount of Ar sputter etching process and the sheet resistance wherein the vertical axis represents the sheet resistance in terms of Ω/□ while the horizontal axis represents the etching amount converted to the etching amount of a thermal oxide film represented in terms of Angstroms;

FIG. 8 is a diagram showing the relationship between the change rate of sheet resistance (ΔR/R) of a CrSi thin-film formed for the metal thin-film resistance defined with reference to the sheet resistance of the as-formed state and the duration in which the CrSi thin-film formed for the metal thin-film resistance is left in the ambient of 25° C. and 45% humidity after formation thereof, the vertical axis representing the quantity ΔR/R in terms of percent, the horizontal axis representing the duration left in the ambient in terms of hours;

FIG. 9 is a diagram showing the variation of contact resistance between the metal thin-film and the metal interconnection caused by thermal annealing process for the samples in which a refractory metal film is left at the bottom of the contact hole at the time of formation of the contact hole and the sample in which the refractory metal film is completely removed from the bottom part of the contact hole, the vertical axis representing the value normalized by the contact resistance value before the thermal annealing process, the horizontal axis representing the number of thermal annealing processing;

FIGS. 10A and 10B are cross-sectional diagrams showing another embodiment of the first mode of the present invention, in which FIG. 10A shows the cross-sectional diagram showing the region where the metal thin-film resistance is formed while FIG. 10B is an enlarged cross-sectional diagram showing the part circled by a broken line in FIG. 10A in enlarged scale;

FIG. 11 is a diagram showing the relationship between the N₂ partial pressure in the gas used for forming a CrSiN film and the resistivity of the CrSiN film thus formed, wherein the vertical axis represents the resistivity ρ in terms of mohm·cm, while the horizontal axis represents the N₂ partial pressure in terms of percent;

FIGS. 12A and 12B are cross-sectional diagrams showing a further embodiment of the first mode of the present invention, in which FIG. 12A shows the cross-sectional diagram showing the region where the metal thin-film resistance is formed while FIG. 12B is an enlarged cross-sectional diagram showing the part circled by a broken line in FIG. 12A in enlarged scale;

FIGS. 13A and 13B are cross-sectional diagrams showing a further embodiment of the first mode of the present invention, in which FIG. 13A shows the cross-sectional diagram showing the region where the metal thin-film resistance is formed while FIG. 13B is an enlarged cross-sectional diagram showing the part circled by a broken line in FIG. 13A in enlarged scale;

FIGS. 14A and 14B are cross-sectional diagrams showing a further embodiment of the first mode of the present invention, in which FIG. 14A shows the cross-sectional diagram showing the region where the metal thin-film resistance is formed while FIG. 14B is an enlarged cross-sectional diagram showing the part circled by a broken line in FIG. 14A in enlarged scale;

FIGS. 15A and 15B are cross-sectional diagrams showing a further embodiment of the first mode of the present invention, in which FIG. 15A shows the cross-sectional diagram showing the region where the metal thin-film resistance is formed while FIG. 15B is an enlarged cross-sectional diagram showing the part circled by a broken line in FIG. 15A in enlarged scale;

FIGS. 16A-16C are cross-sectional diagrams showing an embodiment of the second mode of the present invention, wherein FIG. 16A is a plan view, FIG. 16B is a cross-sectional view showing the region of a first contact hole with enlarged scale, while FIG. 18C shows the region of a second contact hole with enlarged scale;

FIGS. 17A-17F are diagrams explaining the fabrication process of the embodiment FIGS. 18A-18C;

FIGS. 18A-18C are cross-sectional diagrams showing an embodiment of the semiconductor device according to the second mode of the present invention, wherein FIG. 18A is a cross-sectional view, FIG. 18B is a cross-sectional view showing the region of the first contact hole with enlarged scale, while FIG. 18C is a cross-sectional view showing the region of the second contact hole with enlarged scale;

FIGS. 19A-19C are cross-sectional diagrams showing another embodiment of the semiconductor device according to the second mode of the present invention, wherein FIG. 19A is a cross-sectional view, FIG. 19B is a cross-sectional view showing the region of the first contact hole with enlarged scale, while FIG. 19C is a cross-sectional view showing the region of the second contact hole with enlarged scale;

FIGS. 20A-20C are cross-sectional diagrams showing a further embodiment of the semiconductor device according to the second mode of the present invention, wherein FIG. 20A is a cross-sectional view, FIG. 20B is a cross-sectional view showing the region of the first contact hole with enlarged scale, while FIG. 20C is a cross-sectional view showing the region of the second contact hole with enlarged scale;

FIGS. 21A-21C are cross-sectional diagrams showing a further embodiment of the semiconductor device according to the second mode of the present invention, wherein FIG. 21A is a cross-sectional view, FIG. 21B is a cross-sectional view showing the region of the first contact hole with enlarged scale, while FIG. 21C is a cross-sectional view showing the region of the second contact hole with enlarged scale;

FIGS. 22A-22C are cross-sectional diagrams showing a further embodiment of the semiconductor device according to the second mode of the present invention, wherein FIG. 22A is a cross-sectional view, FIG. 22B is a cross-sectional view showing the region of the first contact hole with enlarged scale, while FIG. 22C is a cross-sectional view showing the region of the second contact hole with enlarged scale;

FIGS. 23A-23C are cross-sectional diagrams showing an embodiment of the third mode of the present invention, wherein FIG. 23A is a plan view, FIG. 23B is a cross-sectional view taken along a line A-A in FIG. 23A, while FIG. 23C shows the part of FIG. 23A surrounded by a broken line with enlarged scale;

FIGS. 24A-24C are diagrams explaining the fabrication process of the embodiment FIGS. 24A-24C;

FIGS. 25A-25C are cross-sectional diagrams showing another embodiment of the third mode of the present invention, wherein FIG. 25A is a plan view, FIG. 25B is a cross-sectional view taken along a line B-B in FIG. 25A, while FIG. 25C shows the part of FIG. 20A surrounded by a broken line with enlarged scale;

FIGS. 26A-26C are cross-sectional diagrams showing a further embodiment of the third mode of the present invention, wherein FIG. 26A is a plan view, FIG. 26B is a cross-sectional view taken along a line C-C in FIG. 26A, while FIG. 26C shows the part of FIG. 26A surrounded by a broken line with enlarged scale;

FIGS. 27A-27C are cross-sectional diagrams showing a further embodiment of the third mode of the present invention, wherein FIG. 27A is a plan view, FIG. 27B is a cross-sectional view taken along a line D-D in FIG. 27A, while FIG. 27C shows the part of FIG. 27A surrounded by a broken line with enlarged scale;

FIGS. 28A-28C are diagrams showing the region of a semiconductor device where a metal thin-film resistance according to an embodiment of the fourth mode of the present invention is formed, wherein FIG. 28A is a plan view, FIG. 28B is a cross-sectional view taken along a line E-E of FIG. 28A, and FIG. 28C is an enlarged cross-sectional view showing the part surrounded by a broken line in FIG. 28B with an enlarged scale;

FIGS. 29A-29C are cross-sectional diagrams showing an example of the fabrication process of forming the semiconductor device of FIGS. 28A-28C;

FIGS. 30A-30C are cross-sectional diagrams showing another embodiment of the fourth mode of the present invention, wherein FIG. 30A is a plan view, FIG. 30B is a cross-sectional view taken along a line F-F in FIG. 30A, while FIG. 30C shows the part of FIG. 30A surrounded by a broken line with enlarged scale;

FIG. 31 is a circuit diagram showing an embodiment of the semiconductor device having an analog constant voltage generator circuit;

FIG. 32 is a circuit diagram showing an embodiment of the semiconductor device having an analog voltage detection circuit;

FIG. 33 is a circuit diagram showing a part of the voltage divider;

FIG. 34 is a layout diagram showing an example of the layout of the resistance element for coarse adjustment and the resistance element for fine adjustment used in the voltage divider circuit;

FIG. 35 is a cross-sectional diagram showing a conventional semiconductor device;

FIG. 36 is a cross-sectional diagram showing another conventional semiconductor device;

FIG. 37 is a cross-sectional view showing a further conventional semiconductor device;

FIG. 38 is a diagram explaining the problem arising with a further conventional semiconductor device;

FIG. 39 is a cross-sectional diagram for explaining the problems arising with a further conventional semiconductor device;

FIG. 40 is a cross-sectional diagram showing a further conventional semiconductor device.

### DETAILED DESCRIPTION OF THE PREFERRED EMBODIMENT

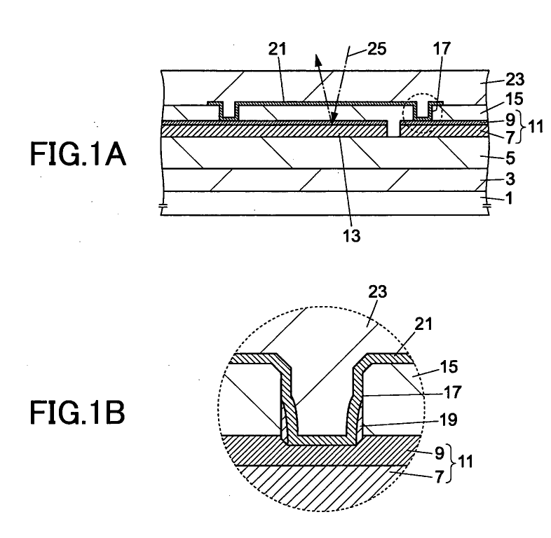

FIGS. 1A and 1B are cross-sectional diagrams showing an embodiment of the first mode of the present invention wherein FIG. 1A is a cross-sectional view showing a region where a metal thin-film resistance is formed while FIG. 1B is an enlarged cross-sectional diagram showing a part of FIG. 1A circled by a broken line. In the embodiments described hereinafter, it should be noted that transistors or capacitors are formed on the same substrate while illustration thereof are omitted.

On a silicon substrate 1, there is formed a device isolation oxide 3, and a first layer interlayer insulation film (lower insulation film) is of BPSG (borophosphosilicate grass) or a PSG (phosphosilicate glass) is formed on the silicon substrate 1 including the region where the device isolation oxide 3 is formed. Further, a first layer metal interconnection pattern 11 of a metal pattern 7 and a refractory metal film 9 formed on the metal pattern 7 is formed on the first layer interlayer insulation film 5.

The metal pattern 7 is formed for example by an AlSiCu film, while the refractory metal film 9 may be formed of a TiN film, for example. The refractory metal film 9 functions as an antireflection film and also a barrier film. A part of the first layer metal interconnection pattern 11 extends to the region where the metal thin-film resistance is formed and constitutes a laser beam interruption film 13.

Further, there is formed a second layer interlayer insulation film (base insulation film) 15 on the first layer interlayer insulation film so as to cover the region where the first layer metal interconnection pattern 11 and the laser beam interruption film 13 are formed, wherein the second layer interlayer insulation film 15, illustrated in FIG. 1A as if it is a single-layer film, is actually formed of consecutive lamination of a lowermost plasma CVD oxide film, an SOG film on the plasma CVD oxide film and a plasma CVD oxide film formed thereon. Further, the second layer interlayer insulation film 15 is formed with contact holes 17 in correspondence to both end parts of the metal thin-film resistance and the first layer interconnection pattern 11.

As shown in FIG. 1B, a surface part of the refractory metal film 9 is removed at the bottom part of the contact hole. Further, it will be noted that there is formed a tapered part at the top edge part of the contact hole 17. In addition, it should be noted that an Ar sputter etching residue 19 is formed on the inner wall surface of the contact hole 17. It should be noted that illustration of the foregoing tapered part and the Ar sputter etching residue 19 is omitted in FIG. 1A.

It should be noted that such a tapered part at the top edge part of the contact hole 17 or the Ar sputter etching residue at the inner wall surface of the contact hole 17 is formed by applying an Ar sputter etching process to the second layer interlayer insulation film 15 in the state that the contact hole 17 is formed already in the interlayer insulation film 15. Thus, the Ar sputter etching residue 19 contains the elements constituting the refractory metal film 9 and the elements constituting the second layer interlayer insulation film 15 in addition to Ar. In the present example, the Ar sputter etching residue 19 contains the elements of Ti, N, Si, O and Ar.

On the second layer interlayer insulation film 15, there is formed a CrSi thin-film resistance (metal thin-film resistance) 21 so as to extend from the region between the contact holes 17 including the interior of the contact holes 17 and over the first layer metal interconnection pattern 11 exposed at the bottom of the contact holes 17. Thereby, it should be noted that both end parts of the CrSi thin-film resistance 21 are connected to the respective first layer metal interconnection patterns 11 in the corresponding contact holes 17. Further, there extend the first layer metal interconnection patterns 11a underneath the CrSi thin-film resistance 21 via the second layer interlayer insulation film 15.

Further, on the second layer interlayer insulation film 15, there is formed a final passivation film 23, wherein the passivation film 23, illustrated in FIG. 1A as if it is a single-layer film, is actually formed of lamination of a lower silicon oxide film and an upper silicon nitride film

With this embodiment, in which the laser beam interruption film 13 of metal material is interposed between the second layer interlayer insulation film 15 and the silicon substrate 1 in the region underneath the CrSi thin-film resistance 21, the laser beam 25 passed through the second layer interlayer insulation film 15 is reflected by the laser beam interruption film 13 in the direction opposite to the silicon substrate 1 when a laser beam 25 is irradiated upon the CrSi thin-film resistance 21 at the time of laser trimming processing with the intensity sufficient for causing disconnection or modification of the CrSi thin-film resistance 21, and irradiation of the laser beam 25 upon the silicon substrate 1 is avoided.

With this, it is possible to avoid the problem of degradation of reliability of the semiconductor device caused by the laser beam irradiation to the silicon substrate 1 at the time of the trimming processing. Further, occurrence of electron-hole pairs associated with the laser beam irradiation upon the silicon substrate 1 is avoided at the time of on-line trimming, and it becomes possible to carry out high-precision trimming.

Further, because of the formation of the Ar sputter etching residue on the inner wall surface of the contact hole 17 as shown in FIG. 1B, the step coverage of the CrSi thin-film resistance 21 inside the contact hole 17 is improved. With this, it is possible to reduce the contact resistance between the CrSi thin-film resistance 21 and the first layer metal interconnection pattern 11.

Further, because of formation of the tapered shape at the top edge part of the contact hole 17, formation of the overhang structure of CrSi thin film blocking the contact hole 17 at the top part thereof at the time of deposition of the Cr thin-film for the formation of the CrSi thin-film resistance is successfully prevented, and the adversary effect on the deposition of the CrSi thin film inside the contact hole 17 is reduced. Thereby, the step coverage of the CrSi thin-film is improved and hence the step coverage of the CrSi thin-film resistance 21.

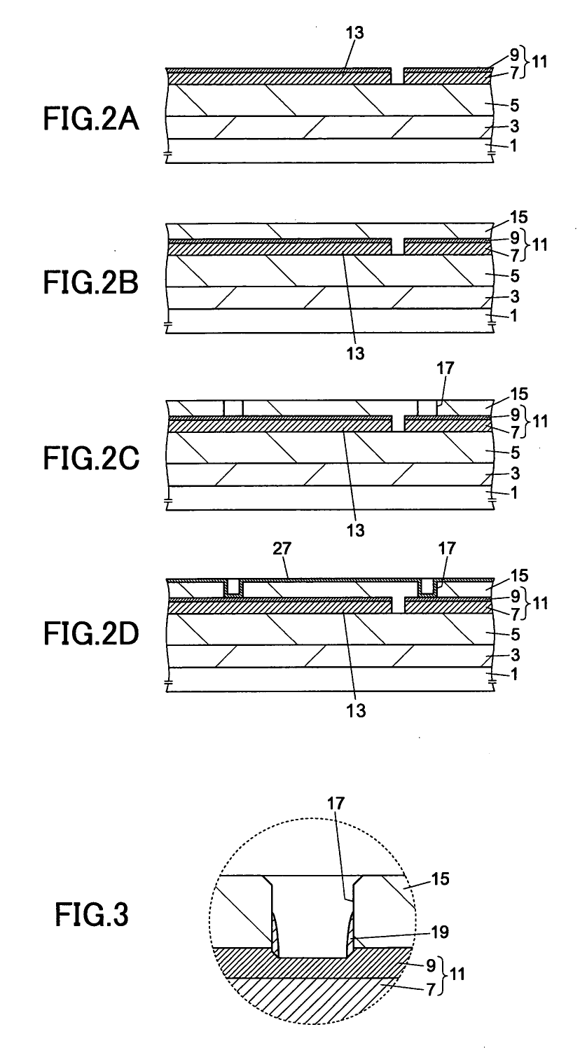

FIGS. 2A-2D are cross-sectional diagrams explaining an example of the process steps for fabricating the embodiment of FIGS. 1A and 1B, while FIG. 3 is a cross-sectional diagram showing the state of the part including the contact hole after conducting the foregoing Ar sputter etching process with enlarged magnification. It should be noted that FIGS. 2A-2D omit the illustration of the sidewall film formed on the inner wall surface of the contact hole or the tapered shape formed at the top edge part of the contact hole.

Hereinafter, the fabrication process of the present embodiment will be explained.

(1) By using an atmospheric pressure CVD apparatus, the first layer interlayer insulation film 5 of BPSG or PSG is formed on the silicon substrate 1, on which the device isolation oxide 3 and the transistors are already formed, with the thickness of about 8000 Angstroms. Thereafter, the surface of the first layer interlayer insulation film 5 is planarized by conducting a thermal annealing process such as reflowing process.

For example, an interconnection metal film of AlSiCu alloy is formed on the first layer interlayer insulation film 5 by using a D.C. magnetron sputtering apparatus with the thickness of about 5000 Angstroms.

Thereafter, a refractory metal film such as a TiN film is formed in vacuum in continuation to the formation of the interconnection metal film with a thickness of about 800 Angstroms, wherein it is known that the refractory metal film thus formed functions as an antireflection coating. Here, it should be noted that the refractory metal film functions also as a barrier film for achieving improved contact between the interconnection pattern formed later from the interconnection metal film and the metal thin-film resistance to be formed. Thus, it is preferable to form the refractory metal film in continuation to the interconnection metal film without breaking the vacuum.

Next, in the step of FIG. 2A, the refractory metal film and the interconnection metal film are patterned by using a known photolithographic process and etching process, and as a result, there are formed first layer metal interconnection patterns 11 and 11a, each formed of lamination of a metal interconnection pattern 7 and a refractory metal film 9. Thereby, the refractory metal film functions as an antireflection coating, and thus, it becomes possible to minimize the variation of resist pattern width that defines the shape of the first layer interconnection pattern 11. It should be noted that the first layer metal interconnection pattern 11a is formed on the conductive plug 6b and on the first layer interlayer insulation film 5 in correspondence to the region located underneath the CrSi thin-film resistance to be formed.

In this step, it should be noted that the metal thin-film resistance is not yet formed, and the underlying film of the metal interconnection pattern 11 is provided by the first layer interlayer insulation film 5. Thus, it is possible to carry out the patterning of the first layer metal interconnection pattern 11 by using a dry etching process with sufficient overetching for ensuring the patterning. Here, there is no need of using a wet etching process, which has caused various problems in the conventional art, and there arises no problem in the miniaturization of the circuit pattern.

(2) Next, in the step of FIG. 2B, a plasma CVD oxide film is formed on the first layer interlayer insulation film by using a plasma CVD process so as to cover the region where the first layer metal interconnection patterns 11 and 11a are formed with the thickness of about 6000 Angstroms. Further, by applying a known planarization process by applying an SOG coating and subsequent etch-back process, a planarized structure is obtained in which an SOG film is laminated on the plasma CVD oxide film.

Further, a plasma CVD oxide film is formed thereon with a thickness of about 2000 Angstroms for preventing diffusion of the constituent elements from the SOG film. With this, there is formed a second layer interlayer insulation film 15 formed of the lowermost plasma CVD oxide film, the SOG film and the upper plasma CVD oxide film.

(3) Next, in the step of FIG. 2C, a resist pattern is formed by using a known photolithographic process in correspondence to the contact hole to be formed in the second layer interlayer insulation film 15 in correspondence to the both end parts of the metal thin-film resistance, and the second layer interlayer insulation film 15 is removed selectively by using a parallel-plate plasma etching apparatus, for example, while using the resist pattern as a mask, under the etching condition of: RF power set to 700 W; Ar flow rate set to 500 SCCM; CHF₃ flow rate set to 500 SCCM; CF₄ flow rate set to 500 SCCM; and process pressure set to 3.5 Torr. With this, contact holes 17 are formed in the second layer interlayer insulation film 15. Thereby, it should be noted that the contact hole 17 exposes the refractory metal film 9 used for the antireflection coating and simultaneously functioning as a barrier film at the bottom thereof with the thickness of about 600 Angstroms. Thereafter, the resist pattern is removed.

Here, it is possible to conduct, after formation of the contact hole 17, a process of removing the byproducts of etching adhered to the sidewall surface of the contact hole 17. Further, in order to improve the step coverage of the metal thin-film resistance inside the contact hole 17, it is possible to apply various improvements for the shape of the contact hole 17 such as taper etching by changing the etching condition during the etching process, or by combining a wet etching process and a dry etching process.

In the foregoing step (3), it is possible to suppress the etching rate of the refractory metal film 9 with regard to the etching rate of the second layer interlayer insulation film 15 by optimizing the condition of the plasma etching process. Thus, it is possible to increase the thickness of the refractory metal film 9 remaining at the bottom part of the contact hole 17 as compared with the thickness vale noted before. Further, it is possible to secure sufficient film thickness for the refractory metal film 9 after formation of the contact hole 17 while suppressing the thickness of the refractory metal film 9 at the time of formation thereof.

Because the formation of the contact hole 17 is thus conducted in the state in which the metal thin-film resistance is not formed yet, it is possible to carry out the formation of the contact hole 17 freely without being restrained by the small thickness of the metal thin-film resistance contrary to the conventional process, and it becomes possible to achieve miniaturization of the pattern by applying a dry etching process.

(4) Next, in the step of FIG. 2D, an Ar sputter etching process is applied to the surface of the second layer interlayer insulation film 15 including the contact hole 17 in an Ar sputter etching chamber of a multi-chamber sputtering apparatus in a vacuum environment under the condition of: DC bias set to 1250V; Ar flow rate set to 20 SCCM, process pressure set to 8.5 mTorr; and processing time of 20 seconds. This etching condition is equivalent to the case of etching a thermal oxide film formed at 1000° C. in a wet ambient with the depth of about 50 Angstroms. After this Ar sputter etching process, the refractory metal film 9 remaining at the bottom of the contact hole 17 had the thickness of about 500 Angstroms.

Next, upon completion of the Ar sputter etching process, formation of a CrSi thin-film (metal thin-film) 27 is conducted for formation of the metal thin-film resistance in continuation, without breaking the vacuum.

More specifically, the semiconductor wafer is transported from the Ar sputter etching chamber to a sputter chamber equipped with a CrSi target (Si/Cr=80/20 wt %), and deposition of the CrSi thin-film 27 is conducted on the entire surface of the second layer interlayer insulation film 15 including the contact hole 17 with the thickness of about 50 Angstroms under the condition of: DC power set to 0.7 kW; Ar flow rate set to 85 SCCM; process pressure set to 8.5 mTorr; and process duration of 9 seconds.

Thus, by applying an Ar sputter etching process to the second layer interlayer insulation film 15 including the contact hole 17 before formation of the CrSi thin film 27 for the metal thin-film resistance, the Ar sputter etching residue 19 containing the material of the refractory metal film 9, the second layer interlayer insulation film 15 and Ar, is formed on the inner wall surface of the contact hole 17 as shown in FIG. 3. Further, the tapered shape is formed at the top edge part of the contact hole 17.

As a result of existence of the Ar sputter etching residue 19, the step coverage of the CrSi thin film 27 in the contact hole 17 is improved, and formation of the overhang structure by the CrSi thin film 27 deposited at the top edge part of the contact hole 17 upon formation of the CrSi thin film 27 is successfully avoided with the tapered shape formed at the tope edge part of the contact hole 17. Thereby, the influence of such an overhang structure on the deposition of the CrSi thin-film 27 in the contact hole 17 is reduced and the step coverage of the CrSi thin-film 27 is improved.

Further, by applying the foregoing Ar sputter etching process, the native oxide film formed on the surface of the refractory metal film 9 at the bottom of the contact hole 17 ca be removed, and it becomes possible to achieve good electrical contact between the first layer metal interconnection pattern 11 and the CrSi thin-film 27.

Further, as a result of the foregoing Ar sputter etching process, the dependence of the CrSi thin-film resistance, formed of the CrSi thin-film, on the underlying film can be improved. This effect will be explained later.

(5) Next, by using a photolithographic process, a resist pattern for defining the region of the metal thin-film resistance is formed on the CrSi thin film 27, and the CrSi thin film 27 is patterned in an RIE (reactive ion etching) apparatus for example while using the resist pattern as a mask. Thereby, a CrSi thin-film resistance 21 is formed. Thereafter, the resist pattern is removed.

Here, it should be noted that the Cr thin-film resistance 21 is connected electrically to the first layer metal interconnection pattern 11 in the contact hole 17, and thus, it is no longer necessary to apply a process for removing metal oxide from the surface of the CrSi thin-film resistance for electrical connection at the top surface of the metal thin-film resistance by using a hydrofluoric acid solution as in the conventional art.

For example, by using a plasma CVD process, a silicon oxide film and a silicon nitride film are formed consecutively on the second layer interlayer insulation film 15 including the region of the CrSi thin-film resistance 21 by a plasma CVD process, for example, as a passivation film 23. With this, fabrication of the semiconductor device (see FIGS. 1A and 1B) is completed.

Thus, with the embodiment explained with reference to FIGS. 1A and 1B, in which the CrSi thin-film resistance 21 is formed after formation of the first layer metal interconnection pattern 11 and the contact hole 17 and electrical connection is made between the CrSi thin-film resistance 21 and the first layer metal interconnection pattern 11 in the contact hole 17, there is no need of conducting a patterning process by a wet etching process after patterning the CrSi thin-film resistance 21.

Thereby, it should be noted that there is no possibility that the contact surface of the CrSi thin-film resistance 21 to the first metal interconnection pattern 11 is exposed to the air, and thus, it is possible to achieve stable electrical connection between the CrSi thin-film resistance 21 and the first layer metal interconnection pattern 11 without conducting surface oxide film removal process and formation of etching stop barrier film.

With this, it becomes possible to achieve miniaturization and stabilization of resistance value of the CrSi thin-film resistance 21 irrespective of the thickness of the CrSi thin-film resistance 21, without increasing the number of process steps.

Further, because of the existence of the refractory metal film 9 functioning also as a barrier film between the CrSi thin-film resistance and the metal pattern 7, variation of contact resistance between the CrSi thin-film resistance 21 and the first layer metal interconnection pattern 11 is reduced, and the precision of resistance value is improved together with yield of production.

Further, because the refractory metal film 9 functions as a barrier film and also an antireflection film, and because the refractory metal film 9 can be formed without increasing the number of fabrication process steps, it is possible to stabilize the contact resistance between the metal thin-film resistance and the metal interconnection pattern while avoiding increase of the fabrication cost.

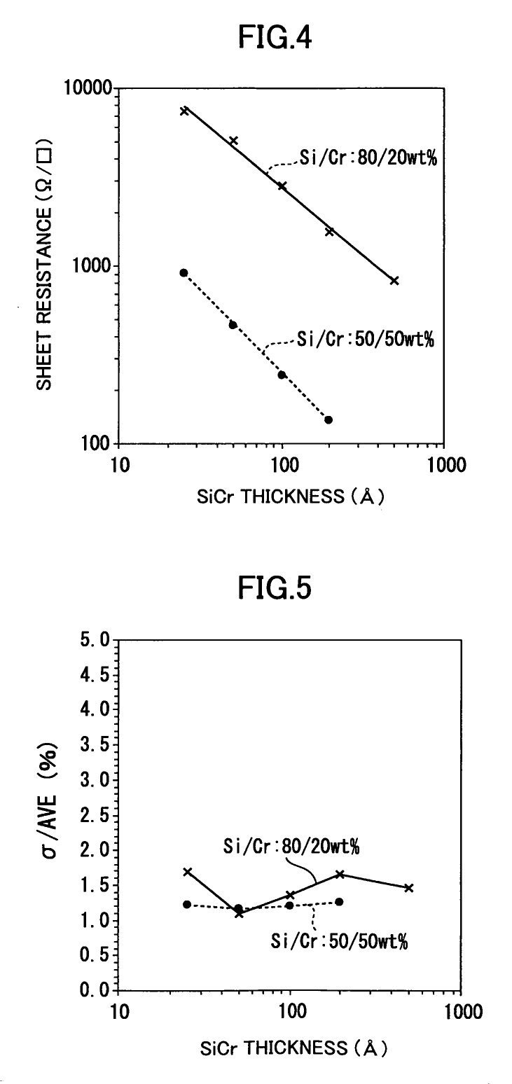

Next, the characteristics of the metal thin-film resistance formed with the construction similar to that of the foregoing embodiment will be explained with reference to FIGS. 4 and 5, wherein FIG. 4 shows the relationship between the sheet resistance of the metal thin-film resistance and the film thickness, while FIG. 5 shows the relationship between the quantity a/AVE, defined as a standard deviation σ of the sheet resistance values measured for the metal thin-film resistance at 63 points on the wafer surface divided by the average value thereof, and the CrSi film thickness, wherein the vertical axis of FIG. 4 shows the sheet resistance in terms of Ω/□ while the horizontal axis of FIG. 4 shows the CrSi thickness in terms of Angstroms. Further, the vertical axis of FIG. 5 shows the quantity σ/AVE (%), while the horizontal of FIG. 5 axis represents the CrSi film thickness in terms of Angstroms.

In the experiments, the metal thin-film resistance has been formed by using a multi-chamber sputtering apparatus with the condition of: DC power set to 0.7 kW; Ar flow rate set to 85 SCCM; and process pressure set to 8.5 mTorr, while using two kinds of targets, one having the composition Sr/Cr=50/50 wt % and the other having the composition 80/20 wt %, wherein the deposition has been made such that the CrSi thin-film has the thickness of 25-500 Angstroms by adjusting the duration of deposition. With regard to the experiment that uses the target composition of Si/Cr=50/50 wt %, the sample of the thickness of 500 Angstroms was not prepared.

Further, the Ar sputter etching process prior to the formation of the CrSi thin-film is conducted by using a multi-chamber sputtering apparatus under the condition of: DC bias set to 1250V; Ar flow rate set to 20 SCCM; and process pressure set to 8.5 mTorr, for the duration of 160 second. It should be noted that this process corresponds to the etching process of a thermal oxide film formed at the temperature of 1000° C. in a wet ambient with the depth of 400 Angstroms.

Further, in the present experiment, an AlSiCu film having the thickness of 5000 Angstroms is used for the metal interconnection underneath the metal thin-film resistance, wherein a structure has been used in which formation of the TiN film is suppressed from the top surface of the AlSiCu film in correspondence to the bottom part of the contact hole where the AlSiCu film and the CrSi thin film are contacted.

The measurement of the sheet resistance was conducted by two-terminal method in which a voltage of 1V is applied at both ends of one of the twenty metal thin-film resistances formed in the shape of strip each having a width of 0.5 μm and a length of 50 μm for measurement of the current value. In this example, the contact hole used for connecting the metal interconnection pattern and the CrSi thin-film resistance was formed to have a size of 0.6 μm×0.6 μm.

As can be seen from FIG. 4, excellent linearity is maintained between the film thickness and sheet resistance from the large film thickness of 200 Angstroms or more to the very small film thickness of 25 Angstroms, irrespective of the composition of the target (Si/Cr=50/50 wt % and Sr/Cr=80/20 wt %). Thus, it becomes possible to form extremely fine metal thin-film resistance not possible with the conventional art with extremely small thickness.

Further, the variation of sheet resistance measured at the 63 points on the wafer surface in FIG. 5 indicates that the variation of the resistance value undergoes little influence of the film thickness in any of the cases of the target of the composition Si/Cr=50/50 wt % is used and the target of the composition of Si/Cr=80/20 wt % is used, and that the variation of the resistance is very small.

From this, it is concluded that, with the use of the Ar sputter etching process at the time of formation of the sidewall in the contact hole, it becomes possible to form extremely fine metal thin-film resistance patterns irrespective of the film thickness of the metal thin-film resistance.

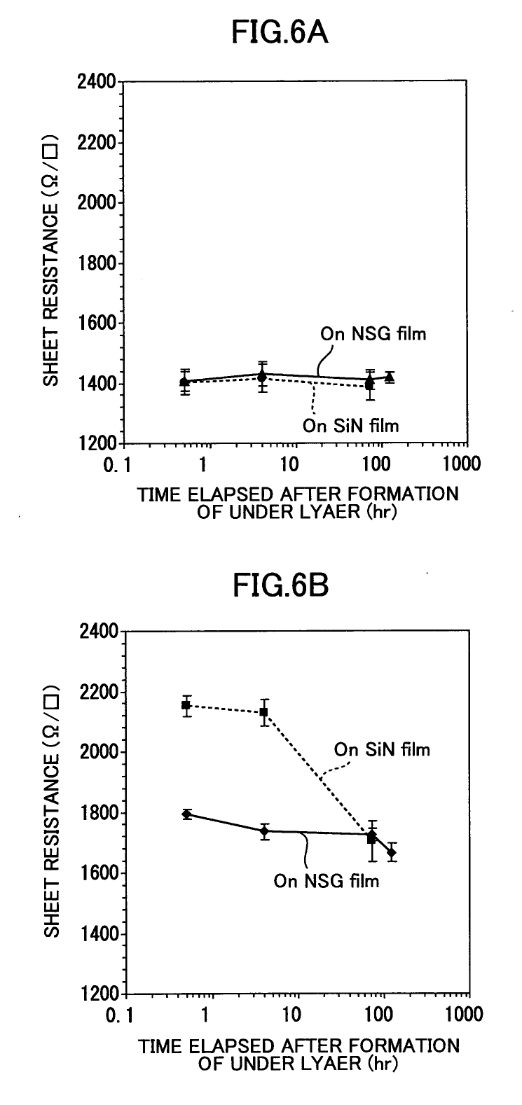

FIGS. 6A and 6B are diagrams showing the relationship between the sheet resistance of the CrSi thin-film resistance and the time elapsed after formation of the underlying film of the metal thin-film resistance for the case the Ar sputter etching process was not conducted before the formation of the metal thin-film for the metal thin-film resistance and the Ar sputter etching process was conducted before the formation of the metal thin-film for the metal thin-film resistance, wherein FIG. 6A shows the case in which the Ar sputter etching has been conducted while FIG. 6B shows the case in which no Ar sputter etching has been conducted. In FIGS. 6A and 6B, the vertical axis represents the sheet resistance in terms of Ω/□ while the horizontal axis represents the time elapsed after formation of the underlying film.

In the experiment of FIGS. 6A and 6B, two silicon wafers are prepared, one carrying a plasma SiN film formed by a plasma CVD process with the thickness of 2000 Angstroms for the underlying layer and the other carrying a plasma NSG (non-doped silicate glass) film formed by a plasma CVD process with the thickness of 2000 Angstroms, wherein a CrSi thin-film resistance is formed on these silicon wafers and the sheet resistance was measured by using four terminal method.

Here, the underlying plasma SiN film was formed by using a parallel plate plasma CVD apparatus at the temperature of 360° C. under the process pressure of 5.5 Torr with the RF power of 200 W while supplying an SiH₄ gas, an N₂ gas and an NH₃ gas with respective flow rates of 70 SCCM, 3500 SCCM and 40 SCCM.

On the other hand, the underlying plasma NSG film was formed by using the parallel plate plasma CVD apparatus at the temperature of 400° C. under the process pressure of 3.0 Torr with the RF power of 250 W while supplying an SiH₄ gas and an N₂O gas with respective flow rates of 16 SCCM and 1000 SCCM.

Further, the CrSi thin-film resistance was formed by using a multi-chamber sputtering apparatus provided with a target of the composition of Si/Cr=80/20 wt % under the DC power of 0.7 kW, while setting the Ar flow rate to 85 SCCM, the process pressure to 8.5 mTorr and the deposition time of 13 seconds, such that the CrSi thin-film resistance has a thickness of 100 Angstroms.

In the case of conducting the Ar sputter etching process, the foregoing multi-chamber sputtering apparatus was used with the condition of DC bias set to 1250V, the Ar flow rate set to 20 SCCM and the process pressure set to 8.5 mTorr, wherein the processing was conducted for the duration of 80 seconds. It should be noted that this etching process corresponds to the etching of a thermal oxide film formed at 1000° C. in a wet ambient for the depth of 200 Angstroms.

As can be seen from FIG. 6B, there appears a large difference in the sheet resistance value, in the case the Ar sputter etching process is not applied before formation of the CrSi thin-film, depending on the underlying film (whether it is an SiN film or an NSG film). Further, it will be noted that the sheet resistance value experiences significant effect by the duration elapsed after formation of the underlying film until the CrSi thin-film resistance is formed.

In the case there has been conducted the Ar sputter etching process shown in FIG. 6A, on the other hand, it can be seen that the sheet resistance value of the CrSi thin-film resistance experiences little effect by the type of the underlying film or the elapsed time.

From this, it is concluded that the variation of the resistance value, caused by the elapsed time from the previous process steps or by the type of the underlying film, which may be changed depending on the product, can be improved significantly by conducting the Ar sputter etching process and then forming the metal thin-film for the metal thin-film resistance in continuation with the previous step without breaking the vacuum.

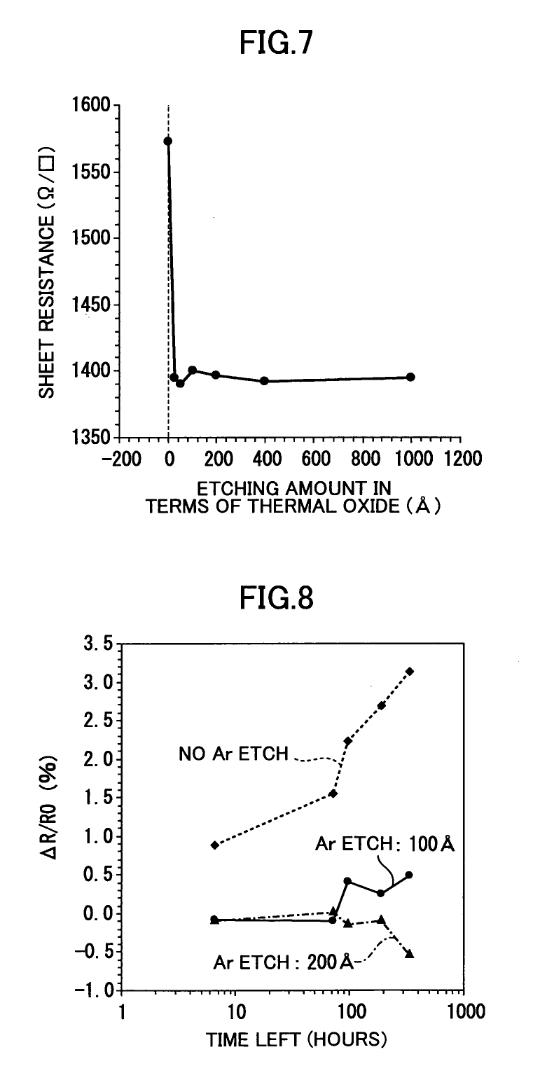

FIG. 7 is a diagram showing the relationship between the amount of the Ar sputter etching and the sheet resistance, wherein the vertical axis represents the sheet resistance represented in terms of Ω/□, while the horizontal axis represents the amount of etching for the case of the thermal oxide film represented in terms of Angstroms.

In the experiment of FIG. 7, a CrSi thin-film resistance formed on a plasma NSG film under the condition similar to the case of FIGS. 6A and 6B has been used. Further, an Ar sputter etching process was applied to the plasma NSG film after one week from the formation thereof, and a CrSi thin-film resistance was formed on such a plasma NSG film. Thereby, the Ar sputter etching process was conducted under the same condition as in the case of FIGS. 6A and 6B except for the etching amount, wherein the etching amount is adjusted respectively to 0 Angstroms (no Ar sputter etching), 25 Angstroms, 50 Angstroms, 100 Angstroms, 200 Angstroms, 400 Angstroms and 1000 Angstroms in terms of the etching amount of a thermal oxide film formed in a wet ambient. Further, the sheet resistance of the CrSi thin-film resistance was measured by the four terminal method.

From the result of FIG. 7, it was discovered that desired stabilization of resistance value of the CrSi thin-film resistance is achieved by merely conducting the Ar sputter etching process with the amount of 25 Angstroms or more in terms of the equivalent etching amount of thermal oxide film formed in a wet ambient. In the experiment of FIG. 7 made with regard to the Ar sputter etching processing condition, samples have been prepared up to the etching amount of 1000 Angstroms in terms of the equivalent etching amount of the thermal oxide film. However, the result of FIG. 7 allows prediction that a similar effect of Ar sputter etching would be obtained even when the etching is conducted with the amount larger than 1000 Angstroms in terms of the equivalent etching amount of thermal oxide film, as long as there remains an underlying film in the region where the metal thin-film resistance is formed.

Further, it was discovered that the Ar sputter etching process not only provides influence on the effect of the underlying film to the resistance value of the CrSi thin-film resistance but also to the resistance value of the CrSi thin-film resistance itself.

FIG. 8 is a diagram showing the relationship between the change rate (ΔR/R0) of the sheet resistance value with regard to the sheet resistance value R0 of the thin-film resistance in the as-formed state and the duration in which the CrSi thin-film has been left in the ambient of 25° C. and 45% humidity after formation thereof. In FIG. 8, the vertical axis represents the quantity ΔR/R0 (%) while the horizontal axis represents the duration (hours) in which the CrSi thin-film resistance has been left in the ambient.

In the experiment of FIG. 8, a plasma NSG film and a CrSi thin-film resistance thereon formed under the same condition as in the case of the experiments of FIGS. 6A and 6B were used for the CrSi thin-film resistance and the underlying insulation film.

With regard to the Ar sputter etching process, three experiments were prepared: one in which no Ar reverse processing was made (no Ar etching); one in which an Ar sputter etching was conducted for 40 seconds with the etching amount of 100 Angstroms in terms of equivalent etching amount of the thermal oxide (Ar etch: 100 Angstroms); and one in which an Ar sputter etching was conducted for 80 seconds with the etching amount of 200 Angstroms in terms of equivalent etching amount of thermal oxide.

In the sample not processed with the Ar sputter etching (no Ar etch), it can be seen that the resistance value increases with time after formation of the thin-film resistance and there appears a shift of resistance value of 3% or more after the thin-film resistance has been left in the ambient over 300 hours or more.

In the samples in which the Ar sputter etching processing has been made (Ar etch: 100 μm and Ar etch: 200 μm), on the other hand, it can be seen that the variation of the resistance value is decreased significantly, and deviation of the resistance value beyond ±1% from the as-deposited sheet resistance was not observed even when the thin-film resistance was left in the ambient over 300 hours or longer.

Further, the comparison of the experiments of: Ar etch=100 Angstroms and Ar etch=200 Angstroms, it was revealed that there is no significant difference, indicating that the amount of the Ar sputter etching is not important and only a small amount of etching provides the desirable effect.

Heretofore, the effect of the Ar sputter etching on the influence provided by the underlying film to the sheet resistance of the metal thin-film resistance or the effect of the Ar sputter etching on the influence of the duration in which the metal thin-film resistance has been left in the air has been examined with reference to FIGS. 4-8. It should be noted that these effects are by no means limited to the case in which the target has the specific composition of Si/Cr=50/50 wt % or Si/Cr=80/20 wt %, but similar effects are observed for all of the CrSi thin-films and the CrSiN films formed by using the target of the composition of Si/Cr=50/50-90/10 wt %.

Further, the Ar sputter etching process is by no means limited to the DC bias sputter etching process explained with the foregoing embodiment.

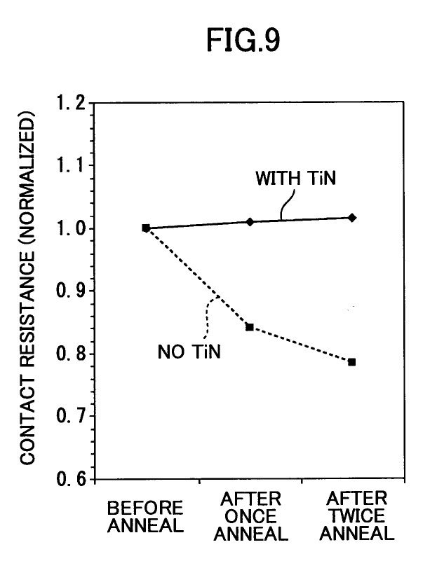

FIG. 9 shows the contact resistance between the metal thin-film resistance and the metal interconnection pattern caused by thermal annealing process for the sample in which the refractory metal film is left at the bottom of the contact hole and the sample in which the refractory metal film is removed completely from the bottom of the contact hole at the time of formation of the contact hole. In FIG. 9, the vertical axis represents the contact resistance value normalized by the contact resistance value before the thermal annealing process, while the horizontal axis represents the number of the thermal annealing processes.

In the experiment of FIG. 9, the sample in which the refractory metal film is left at the bottom part of the contact hole with the thickness of about 500 Angstroms and the sample in which the refractory metal film is completely removed from the bottom part of the contact hole were prepared by adjusting the dry etching time at the time of formation of the contact hole. In this experiment, a TiN film was used for the refractory metal film.

In the experiment, the CrSi thin-film resistance was formed with the thickness of 50 Angstroms by using the target of the composition of Si/Cr=80/20 wt % with the DC power of 0.7 kW under the process pressure of 8.5 mTorr while setting the Ar flow rate to 85 SCCM for the duration of 6 seconds.

Further, the Ar sputter etching process before the formation of the CrSi thin-film resistance was conducted by setting the DC bias to 1250V, the Ar flow rate to 20 SCCM; the process pressure to 8.5 mTorr; and the processing time set to 160 seconds. It should be noted that this etching process corresponds to the process of etching a thermal oxide film formed at the temperature of 1000° C. in the wet ambient with the depth of 400 Angstroms.

In the experiment, the contact hole was formed to have a square form in the plan view having a size of 0.6 μm×0.6 μm. The contact resistance was measured by using four terminal method.

Thus, in the experiment, change of the contact resistance was investigated for the foregoing samples by adding a thermal annealing process conducted at 350° C. for the duration of 30 minutes.

Referring to FIG. 9, it can be seen that there is caused little change of contact resistance with respect to the contact resistance value before the thermal annealing process even when such a thermal annealing process is conducted twice in the sample in which the TiN film is left at the bottom of the contact hole (TiN: Yes). On the other hand, with regard to the sample (TiN: No) in which the TiN film is completely removed, it can be seen that there has been caused a change of contact resistance value of 20% or more as compared with the state before the thermal annealing process, as a result of the thermal annealing process conducted twice.

This indicates that the TiN film successfully functions as a barrier film preventing the resistance change caused by interaction of the CrSi thin-film and the metal interconnection pattern.

By interposing such a TiN film between the CrSi thin-film resistance and the metal interconnection pattern, it becomes possible to minimize the variation of the contact resistance caused by the thermal annealing process in the semiconductor fabrication process such as sintering process or CVD process. Further, it becomes possible to suppress the variation of contact resistance caused by the thermal process used in the assembling process such as soldering process. With this, it becomes possible to maintain the preset contact resistance and avoid any change of contact resistance associated with the assembling process. Thereby, the precision of the semiconductor device product is improved and the yield of production is improved.

In the fabrication process explained with reference to FIGS. 1-3, the metal film for the first layer metal interconnection pattern 11 and the refractory metal film are formed in continuation in the vacuum environment in the step (1), while it should be noted that the fabrication process of the present invention is by no means limited to this example.

For example, there arises a problem of difficulty of achieving electrical contact because of the native oxide film on the surface of the interconnection metal film in the case the metal film for the first layer interconnection pattern 11 is exposed to the air and then the refractory metal film is formed. In such a case, it is possible to achieve secure electrical connection between the first layer metal interconnection pattern 11 and the CrSi thin-film resistance 21 by removing the refractory metal film 9 entirely from the bottom of the contact hole 17 in the step of forming the contact hole 17 in the second layer interlayer insulation film 15 on the first metal interconnection pattern 11 formed of the metal pattern and the refractory metal film 9 formed as a result of patterning of the metal film and the refractory metal film.

Further, while the refractory metal film is formed in the foregoing step (1) with the thickness of 800 Angstroms in the prospect of using the same also as an antireflection coating in addition to the barrier film, formation process of the refractory metal film is by no means limited to this.

Generally, the refractory metal film for use as antireflection coating is used with the thickness of 500 Angstroms or less, while in the case it is desired to leave the refractory metal film 9 at the bottom of the contact hole as a barrier film, it is preferable to form the refractory metal film 9 to have the thickness of 500 Angstroms or more in order to obtain the performance of stable barrier film, in view of the possibility of loss of the film thickness of the refractory metal film 9 at the time of overetching used for formation of the contact hole 17 (see step (3) noted before) or at the time of the Ar sputter etching process (see step (4) noted before) at the time of formation of the metal thin-film.

Of course, it is possible to minimize the loss of film thickness of the refractory metal film 9 and realize a reliable barrier film even in the case the refractory metal film 9 has a thickness of 500 Angstroms or less, by optimizing the etching condition at the time of formation of the contact hole or the Ar sputter etching condition.

Further, while the foregoing step (4) carries out the Ar sputter etching process immediately before formation of the CrSi thin-film 27, electrical contact can be achieved between the CrSi thin-film 27 and the first layer interlayer metal interconnection pattern 11 without carrying out such an Ar sputter etching process in the case the refractory metal film 9 is left at the bottom part of the contact hole 17 as a barrier film, and the refractory metal film 9 of TiN does not form a solid native oxide as in the case of an AlSiCu film when the it is exposed to the air. In the case the Ar sputter etching process is not applied, the tapered shape is not formed at the top edge part of the contact hole 17 and the Ar sputter etching residue 19 is not formed also. However, it is preferable to carry out the Ar sputter etching process because the resistance value of the CrSi thin-film resistance 21 is stabilized as a result of such an Ar sputter etching process conducted immediately before formation of the CrSi thin film 27.

Further, while the foregoing embodiment uses a planarized film for the second layer interlayer insulation film 15 by forming an SOG film and by etching back the same, it should be noted that the insulation film forming the underlying film of the metal thin-film resistance is not limited to this.

Thus, for the insulation film constituting the underlying film of the metal thin-film resistance, it is possible use other insulation films such as a planarized insulation film planarized by a CMP (chemical mechanical polishing) process, a plasma CVD oxide film not applied with planarization process, an SOG film planarized by thermal annealing process after applying an SOG, a planarized CVD insulation film planarized by etch-back process after film formation by an HDP (high-density plasma) CVD process, and the like.

In the case of analog resistance elements, there are often the cases in which the resistance elements are used with the construction in which not only TCR but also parity or relative precision is important. Thus, in the case the metal thin-film resistance of the present invention is to be used for an analog resistance element, it is preferable that the underlying insulation film of the metal thin-film resistance is processed with a planarization processing.

In the foregoing embodiment, the passivation film 23 is formed on the CrSi thin-film resistance 21, while it should be noted that the present invention is by no means limited to such a specific construction. For example, the insulation film formed on the CrSi thin-film resistance may be any insulation film such as the interlayer insulation film used for forming a second layer metal interconnection thereon.

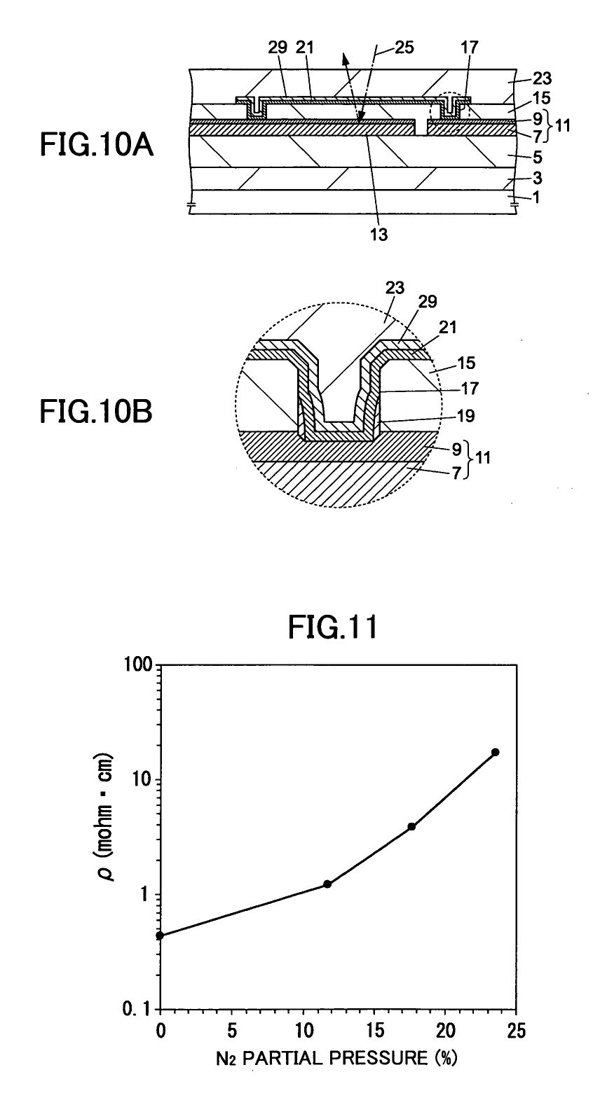

FIGS. 10A and 10B are cross-sectional diagrams showing other embodiment of the first mode of the present invention, wherein FIG. 10A is a cross-sectional diagram showing the region where the metal thin-film resistance is to be formed, while FIG. 10B shows the part surrounded in FIG. 10A by a broken line with enlarged scale. In FIGS. 10A and 10B, those parts corresponding to the parts described with reference to FIGS. 1A and 1B are designated by the same reference numerals and the description thereof will be omitted.

Referring to FIGS. 10A and 10B, it can be seen that the first metal interconnection pattern 11, the laser beam interruption film 13 and the second layer interlayer insulation film 15, wherein the first layer metal interconnection pattern and the laser beam interruption film 13 are formed of lamination of the metal pattern 7 and the refractory metal film 9. Further, the second layer interlayer insulation film 15 is formed with the contact hole 17 in correspondence to both end parts of the metal thin-film resistance and the first layer metal interconnection pattern 11. An Ar sputter etching residue 19 is formed on the inner wall of the contact hole 17, and the top edge part of the contact hole 17 is formed to have a tapered shape.

On the second layer interlayer insulation film 15, the CrSi thin-film resistance 21 is formed so as to extend from the region between the contact holes 17 and 17 to the interior of the contact holes 17 and further to the first layer metal interconnection pattern 11. Further, the laser beam interruption film 13 is disposed underneath the CrSi thin-film resistance 21 via the second layer interlayer insulation film 15. A CrSiN film (metal nitride film) 29 is formed on the top surface of the CrSi thin-film resistance 21, while no CrSiO is formed between the CrSi thin-film resistance 21 and the CrSiN film 29.

Further, a passivation film 23 is formed on the second layer interlayer insulation film 15 including the region where the CrSi thin-film resistance 21 and the CrSiN film 29 are formed.

With this embodiment, too, the laser beam interruption film 13 of a metal material is interposed between the semiconductor substrate 1 and the base insulation film 15 in the region underneath the CrSi thin-film resistance 21, and thus, it is possible to reflect the laser beam 25 passed through the base insulation film 15, in the case a laser beam of sufficient energy for causing disconnection or modification of the CrSi thin-film resistance 21 is irradiated to the CrSi thin-film resistance 21 at the time of the laser trimming process, in the direction away from the semiconductor substrate 1.

Next, the fabrication process of the semiconductor device of the present embodiment will be described.

First, the device isolation oxide 3 is formed on the silicon substrate 1 still in the state of wafer, and the first layer interlayer insulation film 5, the first layer metal pattern 11 formed of lamination of the metal pattern 7 and the refractory metal film 9, the layer beam interruption film 13, the second layer interlayer insulation film 15 and the contact holes 17 are formed according to the processes similar to the processes (1)-(3) explained with reference to FIGS. 2A-2C.

Next, under the same condition as the step (4) explained with reference to FIG. 2D, an Ar sputter etching process is applied to the surface of the interlayer insulation film 5 in a vacuum environment by using an Ar sputtering chamber of a multi-chamber sputtering apparatus, and the Ar sputter etching residue 19 is formed together with the tapered shape at the top edge part of the contact hole 17. Next, a CrSi film for the CrSi thin-film is formed without breaking the vacuum.

Next, after formation of the CrSi thin film, a CrSiN film is formed on the CrSi thin-film without breaking the vacuum.

For example, the CrSi target of the composition of Si/Cr=80/20 wt % used with the formation of the CrSi thin film is used, and the deposition of the CrSiN film is made on the CrSi thin-film with the thickness of about 50 Angstroms under the condition of: DC power set to 0.7 kW; flow rate of Ar+N₂ (a mixed gas of Ar and nitrogen) set to 85 SCCM, the process pressure set to 8.5 mTorr, for the duration of 6 seconds.

Next, the CrSiN film and the CrSi thin-film are patterned, and a laminated pattern of the CrSiN film 30 and the CrSi thin-film resistance 21 is formed.

Similarly to the process explained with reference to FIGS. 1A and 1B through FIG. 3, the CrSi thin-film resistance is electrically connected to the first layer metal interconnection pattern 11, and there is no need of conducting removal process metal oxide from the surface of the CrSi thin-film resistance by using a hydrofluoric acid solution as in the case of the conventional art. Further, because the top surface of the CrSi thin-film resistance 21 is now covered with the CrSiN film 30, there occurs no oxidation at the top surface of the CrSi thin-film resistance even when it is exposed to the ambient containing oxygen.

Thereafter, the passivation film 23 is formed on the second layer interlayer insulation film 15.

Generally, metal thin-film is highly reactive with oxygen, and thus, there occurs a change of resistance value in the case the metal thin-film is left in the air over a long time.

In this example, the problem of change of the resistance value of the CrSi thin film resistance 21 caused by exposure of the top surface of the CrSi thin-film resistance 21 to the air is prevented by forming the CrSiN thin film 30 on the top surface of the CrSi thin-film resistance 21.

Here, it should be noted that the electrical connection between the CrSi thin film and the first layer metal interconnection pattern 11 is completed in the state in which the CrSi thin-film for the CrSi thin-film resistance 21 is formed. Thus, the CrSi thin-film 21 does not experience any change of the characteristics even when a new film is formed thereon.

FIG. 11 is a diagram showing the relationship between the N₂ partial pressure used in the ambient gas for formation of the CrSiN film and the resistivity of the CrSiN film, wherein the vertical axis represents the resistivity ρ in terms of mohm·cm and the horizontal axis represents the N₂ partial pressure represented in terms of percent. Here, the target having the composition of Si/Cr=50/50 wt % is used under the condition of: DC power set to 0.7 kW; Ar+N₂ flow rate set to 85 SCCM; process pressure set to 8.5 mTorr, wherein the processing is conducted over the duration of 6 seconds while controlling the N₂ partial pressure of the Ar+N₂ gas.

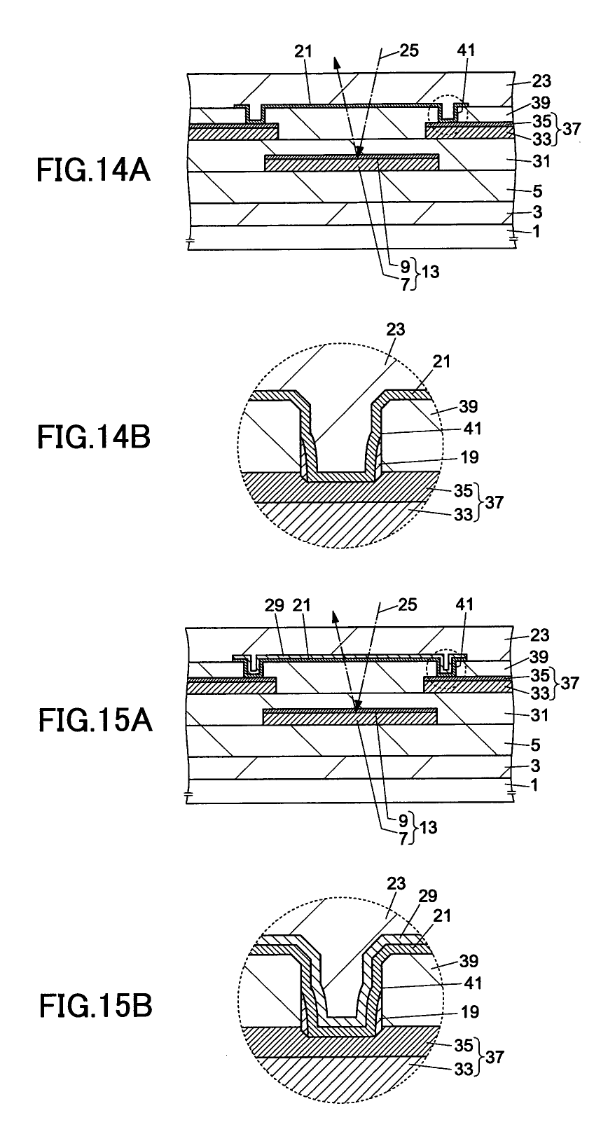

It will be noted form FIG. 14 that the CrSiN film formed by such a reactive sputtering process under the N₂ partial pressure set to 18% or more shows the resistivity value larger than the case in which no addition of N₂ was made (0% N₂ partial pressure) by ten times or more.

Thus, by forming the CrSiN film by setting the N₂ partial pressure to 18% or more, the overall resistance value of the CrSi thin-film resistance is determined by the CrSi thin film even when the CrSiN film is formed directly on the CrSi thin-film resistance, and the CrSiN film provides no substantial effect on the resistance value.

Here, the upper limit of the N₂ partial pressure is about 90%. When the N₂ partial pressure is increased beyond 90%, there is caused a serious decrease of sputtering rate, leasing to degradation of production efficiency.

Further, in the case the CrSiN film is formed with such a reactive sputtering process while setting the N₂ partial pressure to 6-11%, it is possible to use the CrSiN film itself as the metal thin-film resistance.

While the foregoing embodiment has the CrSiN film 29 on the CrSi thin-film resistance 21, it is also possible to construct such that the CrSi thin-film resistance 21 carries a CVD insulation film such as a CVD silicon nitride film. However, general multi-chamber sputtering apparatus does not include a CVD chamber, and it is necessary to introduce a new facility for forming a CVD insulation film, which such addition of new facility increases the production cost of the semiconductor device substantially.

On the other hand, with the foregoing embodiment in which the CrSiN film 29 is formed on the CrSi thin-film 27 for formation of the CrSi thin-film resistance 21, it is not possible to form the CrSiN film 29 functioning as the anti-oxidation cover film of the CrSi thin-film resistance 21 by using the existing multi-chamber sputtering apparatus, without introducing a new apparatus.

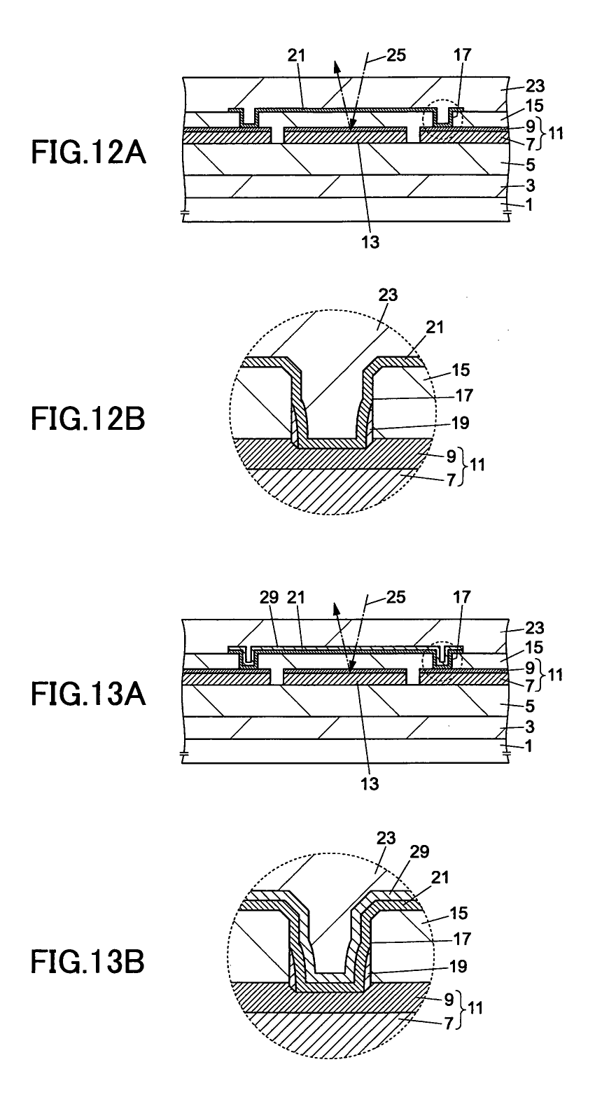

FIGS. 12A and 12B are cross-sectional diagrams showing a further embodiment of the first mode, wherein FIG. 12A is a cross-sectional diagram showing the region where the metal thin-film resistance is formed while FIG. 12B is a cross-sectional diagram showing a part of FIG. 12A surrounded by a broken line. In the drawings, those parts corresponding to the parts described previously with reference to FIGS. 1A and 1B are designated by the same reference numerals and the description thereof will be omitted.

The embodiment of FIGS. 12A and 12B is distinct over the embodiment explained with reference to FIGS. 1A and 1B in that the laser beam interruption film of the metal pattern 7 and the refractory metal film 9 is provided separately from the first layer metal interconnection pattern 11. Otherwise, the present embodiment has the same structure as in the case of the embodiment explained with reference to FIGS. 1A and 1B through FIG. 3. It should be noted that such a structure can be easily formed by modifying the mask used for patterning the first layer metal interconnection pattern 11 and the laser beam interruption film 13 in the fabrication process explained with reference to FIGS. 1A and 1B through FIG. 3.

FIGS. 13A and 13B are cross-sectional diagrams showing a further embodiment of the first mode, wherein FIG. 13A is a cross-sectional diagram showing the region where the metal thin-film resistance is formed while FIG. 13B is a cross-sectional diagram showing a part of FIG. 13A surrounded by a broken line. In the drawings, those parts functioning identically to the parts described previously with reference to FIGS. 10A and 10B are designated by the same reference numerals and the description thereof will be omitted.

The embodiment of FIGS. 13A and 13B is distinct over the embodiment explained with reference to FIGS. 10A and 10B in that the laser beam interruption film of the metal pattern 7 and the refractory metal film 9 is provided separately from the first layer metal interconnection pattern 11. Otherwise, the present embodiment has the same structure as in the case of the embodiment explained with reference to FIGS. 1A and 1B through FIG. 3.

With the embodiments explained with reference to FIGS. 12A and 12B and FIGS. 13A and 13B, too, the laser beam 25 is reflected in the direction away from the silicon substrate 1 by the laser beam interruption film 13 of metal material disposed between the silicon substrate 1 and the second layer interlayer insulation film 15 in the region underneath the CrSi thin-film resistance 21 even when the laser beam 25 is irradiated upon the CrSi thin-film resistance 21 with sufficient intensity for disconnecting or modifying the CrSi thin-film resistance 21 at the time of the laser trimming process, and irradiation of the laser beam 25 upon the silicon substrate 1 is prevented.

It is noted that, in the embodiments shown in FIGS. 1A and 1B, FIGS. 10A and 10B, FIGS. 12A and 12B and FIGS. 13A and 13B, the laser beam interruption film 13 is formed of the same material as the first layer metal interconnection pattern 11 connected electrically to the CrSi thin-film resistance 21. However, the present invention is by no means limited to such a construction, and it is possible to construct the laser beam interruption film by a metal material different from the metal material used for the first layer metal interconnection pattern 11. Thereby, the laser beam interruption film is formed separately from the first layer metal interconnection pattern 11.

Further, while the laser beam interruption film 13 and the first layer metal interconnection pattern 11 connected electrically to the CrSi thin-film resistance 21 are both formed on the first layer interlayer insulation film 5 in the foregoing embodiment, the layer beam interruption film and the metal interconnection pattern may be formed on respective, different insulation films.

FIGS. 14A and 14B are cross-sectional diagrams showing a further embodiment of the first mode, wherein FIG. 14A is a cross-sectional diagram showing the region where the metal thin-film resistance is formed while FIG. 14B is a cross-sectional diagram showing a part of FIG. 14A surrounded by a broken line. In the drawings, those parts functioning identically to the parts described previously with reference to FIGS. 1A and 1B are designated by the same reference numerals and the description thereof will be omitted.

Referring to FIGS. 14A and 14B, the first layer interlayer insulation film 5 is formed on the silicon substrate 1 including the region where the device isolation oxide 3 is formed. Further, the laser beam interruption film 13 formed of the metal pattern 7 and the refractory metal film 9 is formed on the first layer interlayer insulation film 5 in the region corresponding to the metal thin-film resistance. While not illustrated, it should be noted that that the first layer interlayer insulation film 5 carries the first layer metal interconnection pattern formed of the metal pattern 7 and the refractory metal film 9.

On the first layer interlayer insulation film 5 including the region where the laser beam interruption film 31 is formed, there is formed a second interlayer insulation film (lower insulation film) 31 in the form of consecutive lamination of a plasma CVD oxide film, an SOG film and a plasma CVD oxide film, wherein FIG. 14A shows the interlayer insulation film 31 as if it is a single layer film. Further, a second layer metal interconnection pattern 37 formed of a metal pattern 33 and a refractory metal film 35 formed on the metal pattern 33 is formed on the second layer interlayer insulation film 31, wherein the metal pattern 33 may for example be formed of an AlSiCu film. The refractory metal 35 may be formed for example by a TiN film that functions as an antireflection film and at the same time a barrier film.

On the second layer interlayer insulation film 31 including the region where the second layer metal interconnection pattern 37 is formed, there is formed a third interlayer insulation film (base insulation film) 39 in the form of consecutive lamination of a plasma CVD oxide film, an SOG film and a plasma CVD oxide film, wherein FIG. 14A shows the interlayer insulation film 39 as if it is a single layer film. Further, a contact hole 41 is formed in the third layer interlayer insulation film 39 in correspondence to both end parts of the metal thin-film resistance and the second layer metal interconnection pattern 37.

As shown in FIG. 14B, a surface part of the refractory metal film 35 is removed at the bottom part of the contact hole 41. Further, it will be noted that there is formed a tapered part at the top edge part of the contact hole 41. In addition, it should be noted that the Ar sputter etching residue 19 is formed on the inner wall surface of the contact hole 41. It should be noted that illustration of the foregoing tapered part and the Ar sputter etching residue 19 is omitted in FIG. 14A.

It should be noted that such a tapered part at the top edge part of the contact hole 41 or the Ar sputter etching residue 19 at the inner wall surface of the contact hole 41 is formed by applying an Ar sputter etching process to the third layer interlayer insulation film 39 in the state that the contact hole 41 is formed already in the interlayer insulation film 39. Thus, the Ar sputter etching residue 19 contains the elements constituting the refractory metal film 35 and the elements constituting the third layer interlayer insulation film 39 in addition to Ar. In the present example, the Ar sputter etching residue 19 contains the elements of Ti, N, Si, 0 and Ar.

On the third layer interlayer insulation film 39, the CrSi thin-film resistance (metal thin-film resistance) 21 is formed so as to extend from the region between the contact holes 41 including the interior of the contact holes 41 and over the second layer metal interconnection pattern 37, wherein the both end parts of the CrSi thin-film resistance 21 are connected to the respective second layer metal interconnection patterns 37 in the corresponding contact holes 41. Further, the laser beam interruption film 13 is disposed underneath the CrSi thin-film resistance 21 via the third layer interlayer insulation film 39 and the second layer interlayer insulation film 31.

Further, the passivation film 23 is formed on the third layer interlayer insulation film 39 so as to include the region where4 the CrSi thin-film resistance 21 is formed.

With this embodiment, in which the laser beam interruption film 13 of metal material is interposed between the third layer interlayer insulation film 39 and the silicon substrate 1 in the region underneath the CrSi thin-film resistance 21, the laser beam 25 passed through the third layer interlayer insulation film 39 and the second layer interlayer insulation film 31 is reflected by the laser beam interruption film 13 in the direction opposite to the silicon substrate 1 when a laser beam 25 is irradiated upon the CrSi thin-film resistance 21 at the time of laser trimming processing with the intensity sufficient for causing disconnection or modification of the CrSi thin-film resistance 21, and irradiation of the laser beam 25 upon the silicon substrate 1 is avoided.

Further, because the inner wall of the contact hole 41 is formed with the Ar sputter etching residue 19 and because the top edge part of the contact hole 41 is formed to have a tapered shape, the step coverage of the CrSi thin-film resistance 21 in the vicinity of the contact hole 41 is improved similarly to the embodiment explained with reference to FIGS. 1A and 1B in which the Ar sputter etching residue 19 is formed on the inner wall surface of the contact hole 17 and the top edge part of the contact hole 17 is formed to have the tapered shape, and the contact resistance between the CrSi thin-film resistance 21 and the metal interconnection pattern 37 is stabilized.

The semiconductor device of the present embodiment can be fabricated by forming the first layer interlayer insulation film 5 and the laser beam interruption film 13 on the silicon substrate 1 already formed with the device isolation oxide 3, similarly to the process (1) explained with reference to FIG. 2A, and further by forming the second layer interlayer insulation film 31 similarly to the process (2) explained with reference to FIG. 2B.

Further, the second layer metal interconnection pattern 37 is formed on the second layer interlayer insulation film 31 in the form of lamination of the metal pattern 33 and the refractory metal film 35, and the third interlayer insulation film 39 is formed further thereon according to the step similar to the process steps (1) through (4) explained with reference to FIGS. 2A-2D, in which the first layer metal interconnection pattern 11 of the metal pattern 7 and the refractory metal film 9, the second layer interlayer insulation film 15, the contact hole 17, the Ar sputter etching residue 19 and the CrSi thin-film 27, are formed on the first layer interlayer insulation film 5. Thereafter, the contact hole 17 is formed in the third layer interlayer insulation film 39, and the tapered shape at the top edge part of the contact hole 17 and the Ar sputter etching residue are formed by conducting the Ar sputter etching process. Further, the CrSi thin-film for the CrSi thin-film resistance 21 is formed.

Thereafter, the CrSi thin-film is patterned and the CrSi thin-film resistance 21 is formed. Further, by forming the passivation film 23, fabrication of the semiconductor device of the present embodiment is completed.

Thus, with the present embodiment, too, various advantageous effects similar to the embodiment explained with reference to FIGS. 1A and 1B, such as: elimination of the need of patterning the CrSi thin-film resistance 21 after patterning thereof by using a wet etching process; elimination of exposure of the contact surface of the CrSi thin-film resistance 21 to the metal interconnection pattern 27; existence of the refractory metal film 35 between the CrSi thin-film resistance 21 and the metal interconnection pattern 33 as a barrier film; and the effect associated with the Ar sputter etching process to the third layer interlayer insulation film 39 used for the underlying film before formation of the CrSi thin-film for the CrSi thin-film resistance, are attained.

Further, as shown in FIGS. 15A and 15B, it is possible to form the CrSiN film 29 on the top surface of the CrSi thin-film resistance 21 similarly to the embodiment explained with reference to FIGS. 10A and 10B. In the present embodiment, too, no CrSiO is formed between the CrSi thin-film resistance 21 and the CrSiN film 29. In the embodiment of FIGS. 15A and 15B, it should be noted that the CrSiN film 30 can be formed similarly to the method explained with reference to FIGS. 10A and 10B.

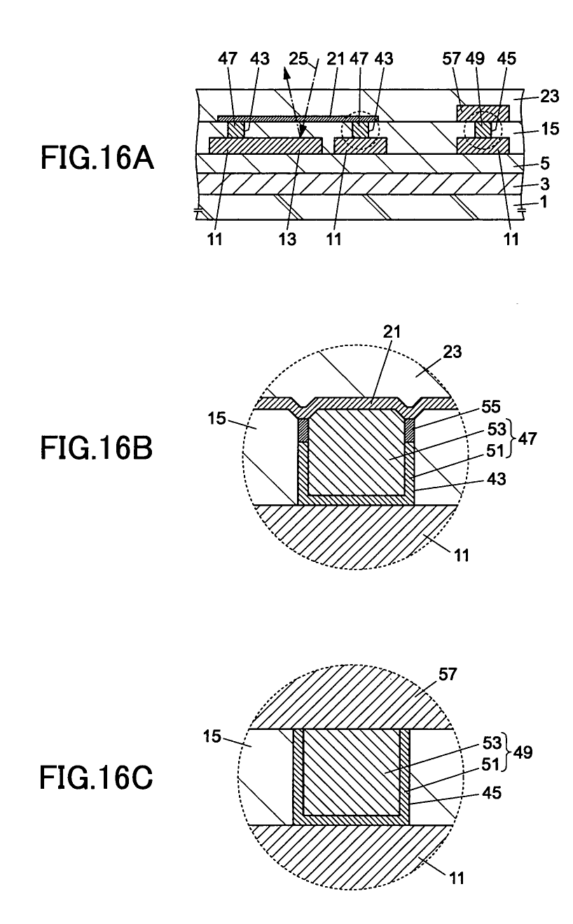

FIGS. 16A-16C are diagrams showing an embodiment of the second mode of the present invention, wherein FIG. 16A is a cross-sectional view, while FIG. 16B shows the region of the second contact hole with enlarged scale. Further, FIG. 16C shows the region of the second contact hole with enlarged scale. In the drawings those parts corresponding to the parts explained previously with reference to FIGS. 1A and 1B are designated by the same reference numerals and the description thereof will be omitted.

Referring to FIGS. 16A-16C, the device isolation oxide 3 is formed on the silicon substrate 1 and the first layer interlayer insulation film 5 is formed on the silicon substrate 1 including the region where the device isolation oxide 3 is formed.

The first interlayer insulation film 5 carries the first layer metal interconnection pattern 11, wherein the first layer metal interconnection pattern 11 is formed of a metal pattern of an AlSiCu film, for example, and a refractory metal film such as a TiN film formed on the surface of the metal pattern. FIG. 16A represents the metal pattern and the refractory metal film as if they form a single layer. A part of the first layer metal interconnection pattern 11 extends to the region where the metal thin-film resistance is formed and forms the laser beam interruption film 13.

On the first layer interlayer insulation film 5 including the region where the first layer metal interconnection pattern 11 is formed, the second interlayer insulation film (base insulation film) 15 is formed as a consecutive lamination of a plasma CVD oxide film, an SOG film and a plasma CVD oxide film, wherein FIG. 16A shows the interlayer insulation film 15 as if it is a single layer film. Further, a first contact hole and a second contact hole are formed in the second layer interlayer insulation film in correspondence to the first layer metal interconnection pattern 11, wherein the first contact hole 43 is used for electrically connecting the first layer metal interconnection pattern with the metal thin-film resistance formed on the second layer interlayer insulation film 15. The second contact hole 45 is used for connecting the first layer metal interconnection pattern to the second layer metal interconnection pattern formed on the second layer interlayer insulation film 15.

The first contact hole 43 is filled with a conductive material and a first conductive plug 47 is formed in the first contact hole 43. Further, the second contact hole 45 is filled with a conductive material and a second conductive plug 49 is formed in the second contact hole 45. The first conductive plug 47 and the second conductive plug 49 are formed for example of a barrier metal (first conductive material) 51 of titanium formed on the inner wall surface of the contact hole and a tungsten plug (second conductive material) 53 formed on the barrier metal 51. In FIG. 16A, it should be noted that the first conductive plug 47 and the second conductive plug 49, formed of the barrier metal 51 and the tungsten plug 53, are represented as if they form a unitary body.

As shown in FIG. 16B, the top end part of the barrier metal 51 is formed with a separation from the top edge part of the first contact hole 43 or from the top surface of the tungsten plug 53. Further, the outer periphery of the top surface of the tungsten plug 53 and the top edge part of the fist contact hole 43 form a tapered shape (not shown in FIG. 16A). Further, the space formed on the barrier metal 51 between the inner wall of the first contact hole 43 and the tungsten plug 53 is filled with a sputtering residue 55 (not shown in FIG. 16A), wherein the sputtering residue contains at least the material of the second layer interlayer insulation film, tungsten and Ar as the constituting elements.

In the second contact hole 45, the barrier metal 51, the tungsten plug 53 and the second layer interlayer insulation film have the respective top surfaces at the same height, and thus, no tapered shape or sputtering residue is formed contrary to the first contact hole 43.

Further, it should be noted that the CrSi thin-film resistance (metal thin-film resistance) 21 is formed on the first conductive plug 47 and on the second interlayer insulation film 15, wherein both end parts of the CrSi thin-film resistance 21 are connected to the first-layer metal interconnection patterns 11 via respective first conductive plugs 47. Further, the laser beam interruption film 13 is disposed underneath the CrSi thin-film resistance 21 via the second layer interlayer insulation film 15.

Further, on the second conductive plug 47 and on the second interlayer insulation film 15, it should be noted that is formed a second-layer metal interconnection pattern 57 as the uppermost metal interconnection pattern, wherein it should be toned that this second layer metal interconnection pattern 57 is connected to the first layer metal interconnection pattern 11 eclectically via a second conductive plug 49. Further, the passivation film 23 is formed on the second layer interlayer insulation film 15 including the region where the CrSi thin-film resistance 21 and the second layer metal interconnection pattern 57 are formed.

Because the laser beam interruption film 13 of a metal is formed between the second layer interlayer insulation film 15 and the silicon substrate 1 in the region underneath the CrSi thin-film resistance 21, the laser beam 25 passed through the second layer interlayer insulation film 15 is reflected away from the silicon substrate by the laser beam interruption film 13 when the laser beam 25 is irradiated to the CrSi thin-film resistance 21 at the time of laser beam trimming process with the intensity sufficient for disconnecting or modifying the CrSi thin-film resistance 21, and irradiation of the laser beam 25 upon the silicon substrate 1 is prevented.

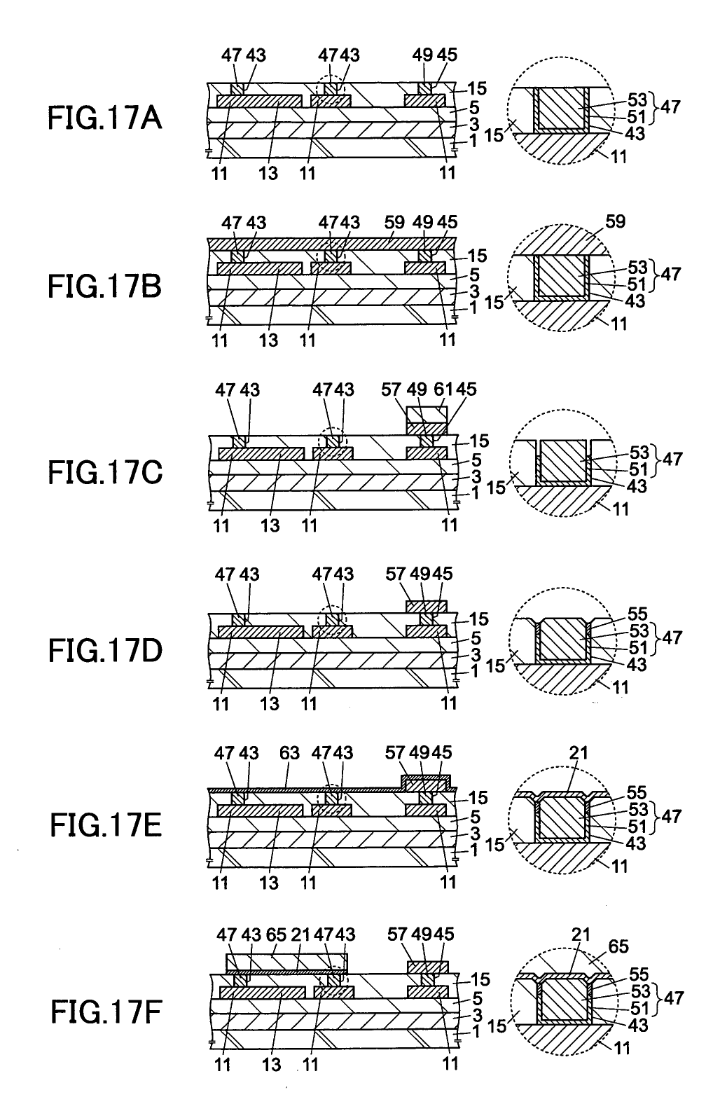

FIGS. 17A-17F are cross-sectional diagrams explaining the fabrication process of the semiconductor device of the present embodiment, wherein it should be noted that the cross-sectional diagrams circled at the right of FIGS. 17A-17F represent the state of the first contact hole for the respective process steps with magnification.

(1) First, the first interlayer insulation film 5 of BPSG or PSG is formed on the silicon substrate 1 still in the form of wafer, on which formation of the device isolation film 3 and transistors (not shown) is completed, with the thickness of about 8000 Angstroms, and the first layer metal interconnection pattern 11 and the laser beam interruption film 13 are formed on the first interlayer insulation film 5 in the form of lamination of an AlSiCu alloy having the thickness of about 5000 Angstroms and a TiN film having the thickness of about 800 Angstroms. Further, the second interlayer insulation film 15 is formed on the first interlayer insulation film 5 including the region where the first layer metal interconnection pattern 11 and the laser beam interruption film 13 have been formed, by consecutively forming a plasma CVD oxide film having the thickness of about 6000 Angstroms, an SOG film and a plasma CVD oxide film having the film thickness of about 2000 Angstroms.

Next, by using a known photolithographic process and dry etching process, the first contact hole 43 and the second contact hole 45 are formed in the second interlayer insulation film 15 in correspondence to the predetermined region of the first layer metal interconnection pattern 11.

Next, the barrier metal 51 of titanium, for example, is formed on the entire surface of the second interlayer insulation film 15 including the inner wall surface of the first contact hole 43 and the second contact hole 45 with the thickness of 1000 Angstroms, and after formation of a tungsten film 53 thereon with the thickness of 7500 Angstrom, an etch back process or CMP process is conducted for removing unnecessary tungsten film 53 and the barrier metal 51. With this, the first conductive plug 47 of the barrier metal 51 and the tungsten plug 53 is formed in the first contact hole 43 and the second conductive plug 49 of the barrier metal 51 and the tungsten plug 53 is formed in the second contact hole 45. Reference should be made to FIG. 17A.

(2), Next, in the step of FIG. 17B, a metal film of AlSiCu alloy is formed on the second layer interlayer insulation film 15 by using a DC magnetron sputtering apparatus with the thickness of about 5000 Angstroms. Further, a refractory metal film such as a TiN film is formed consecutively on the metal film with the thickness of about 500 Angstroms while maintaining the vacuum state to form an anti-reflection coating. With this, a metal film 59 for interconnection is formed.

(3) Next, in the step of FIG. 17C, a resist pattern 61 is formed on the interconnection metal film 59 by a photolithographic process to define the region where the second metal interconnection pattern is to be formed, and the second-layer metal interconnection pattern 57 is formed by pattering the interconnection metal film 59 while using the resist pattern 61 as a mask.

Here, it should be noted that the interconnection metal film 59 on the first conductive plug 47 is removed as a result of the foregoing dry etching process, while such a dry etching process also removes the top part of the barrier metal 51 constituting the first conductive plug 47, and as a result, there is formed a depression around the first conductive plug 47. Reference should be made to the enlarged view of FIG. 17C.

It should be noted that such a depression is formed in the case there is a large etching selectivity between the metal film 59 and the tungsten plug 53 (second conductive material) and that there is a small etching selectively between the metal film 59 and the barrier metal 51 (first conductive material).

Thus, it should be noted that formation of such a depression occurs not only in the case in which the material of the first conductive plug 47 and the material of the metal film 59 are used with this specific combination of the present embodiment but also in the case in which there exists a small etching selectivity for the first conductive material constituting the first conductive plug with respect to the metal film for the metal interconnection pattern and that there exists a large etching selectivity for the second conductive material constituting the first conductive plug with respect to the first conductive material.

(4) After removing the resist pattern 61, an Ar sputter etching is applied in the step of FIG. 17D to the surface of the second interlayer insulation film 15 including the region where the first conductive pug 47 is formed. Reference should be made to FIG. 17D. In the present example, the Ar sputter etching process has been conducted by using an Ar sputter etching chamber of a multi-chamber sputtering apparatus under the vacuum condition of 8.5 mTorr in pressure under the D.C. bias of 1250V for 20 seconds while flowing an Ar gas with the flow rate of 20 SCCM. It should be noted that this etching condition is equivalent to the condition of etching a thermal oxide film formed at 1000° C. under wet ambient with the depth of about 50 Angstroms.

As a result of this Ar sputter etching process, there is formed a tapered shape in the first contact hole 43 at the outer peripheral part surrounding the top surface of the tungsten plug 53 and further at the top edge part of the first contact hole 43, wherein it should be noted that the space formed on the barrier metal 51 between the inner wall of the first contact hole 43 and the tungsten plug 53 is filled with the Ar sputter etching residue 55, which contains at least the material of the second interlayer insulation film 15, tungsten and Ar as a constituting elements thereof. Reference should be made to the enlarged view of FIG. 17D.

(5) After completion of the Ar sputter etching process, formation of a CrSi thin-film (metal thin-film) 63 for the metal thin-film resistance is formed without breaking the vacuum state.

More specifically, the semiconductor wafer is transported from the Ar sputter etching chamber to the sputtering chamber equipped with a CrSi target, and formation of the CrSi thin-film 63 is conducted on the entire surface of the second interlayer insulation film 15 including the region where the first conductive plug 47 is formed with the thickness of about 50 Angstroms under the pressure of 8.5 mTorr by setting the D.C. power to 0.7 kilowatt for the duration of 9 seconds while supplying an Ar gas with the flow rate of 85 SCCM. Thereby, a target having the Si/Cr ratio of 80/20 wt % is used for the CrSi target. Reference should be made to FIG. 17E.

Thus, by conducting the Ar sputter etching process to the second interlayer insulation film 15 before formation of the CrSi thin-film 63 used for the metal thin-film resistance, and by trimming the first contact hole 43 such that there is formed a tapered surface at the outer periphery of the top surface of the tungsten plug 53 and further at the top edge part of the first contact hole 43, and further by filling the space formed on the barrier metal 51 between the inner wall of the first contact hole 43 and the tungsten plug 53 with the Ar sputter etching residue 55, it becomes possible to improve the step coverage of the CrSi thin-film 63 in the vicinity of the first contact hole 43.

Further, by conducting the foregoing Ar sputter etching process, it becomes possible to improve the dependence of the CrSi thin film resistance, formed from the CrSi thin-film 63 in the later process, on the underlying film as explained with reference to FIGS. 4 through 8.

(6) Next, in the step of FIG. 17F, there is formed a resist pattern 65 on the CrSi thin-film 63 so as to define the region where the metal thin-film resistance is to be formed. Further, by using an RIE (reactive ion etching) apparatus, the CrSi thin-film 63 is patterned while using the resist pattern 65 as a mask, and with this, the CrSi thin-film resistance 21 is obtained.

(7) Next, the resist pattern 37 is removed.

Here, it should be noted that, because the CrSi thin-film resistance 21 is already connected electrically to the first-layer metal interconnection pattern 11 via the first conductive plug 47. Thus, there is no need of conducting a metal oxide removal process to the surface of the CrSi thin-film resistance 21 by using a hydrofluoric acid.

Thereafter, a plasma CVD process is conducted and there is formed a silicon oxide film and a silicon nitride film consecutively on the second interlayer insulation film 15 including the region where the CrSi thin-film resistance 21 is formed as a passivation film 23. With this, the semiconductor device of FIGS. 16A-16C is obtained.

According to the foregoing embodiment, in which the first-layer metal interconnection pattern 11 and the contact holes 43 and 45 are formed at first and the CrSi thin-film resistance 21 is formed after formation of the conductive plugs 47 and 49 respectively in the contact holes 43 and 45 such that the CrSi thin-film resistance 21 is in electrical connection with the first-layer metal interconnection pattern 11 via the first conductive plug 47, there is no longer the need of carrying out a wet etching patterning process after patterning the CrSi thin-film resistance 21.

Further, because the contact surface of the CrSi thin-film resistance 21 to the first conductive plug 47 is not exposed to the air, good and reliable electrical connection can be achieved between the CrSi thin-film resistance 21 and the first conductive plug 47 without applying a surface oxide film removal processing and formation of an etching-resistance barrier film is made on the CrSi thin-film resistance 21.

With this, it is possible to achieve miniaturization of the CrSi thin-film resistance 21 and stabilization of the resistance value thereof, irrespective of the thickness of the CrSi thin-film resistance 21 and without increasing the number of the process steps.

Further, because the CrSi thin-film resistance 21 is formed on the first conductive plug 47 and the second interlayer insulation film 15, there arises no problem such as variation of the resistance value and increase of contact resistance to the electrode as explained with reference to FIG. 39, in which the metal thin-film resistance and the first conductive plug are electrically interconnected via a contact hole formed on the interconnection pattern.

Further, because the second conductive plug 49 for electrically connecting the first-layer metal interconnection pattern 11 and the second-layer metal interconnection pattern 57 is formed simultaneously to the first conductive plug 47, there is no such a dedicated process explained with reference to FIG. 38, in which there are provided a dedicated process of forming the insulation film 123 and a further dedicated process of forming the second contact hole 125 and the second conductive plug 127, and thus, it becomes possible to form the CrSi thin-film resistance 21 with low cost and with improved throughput.

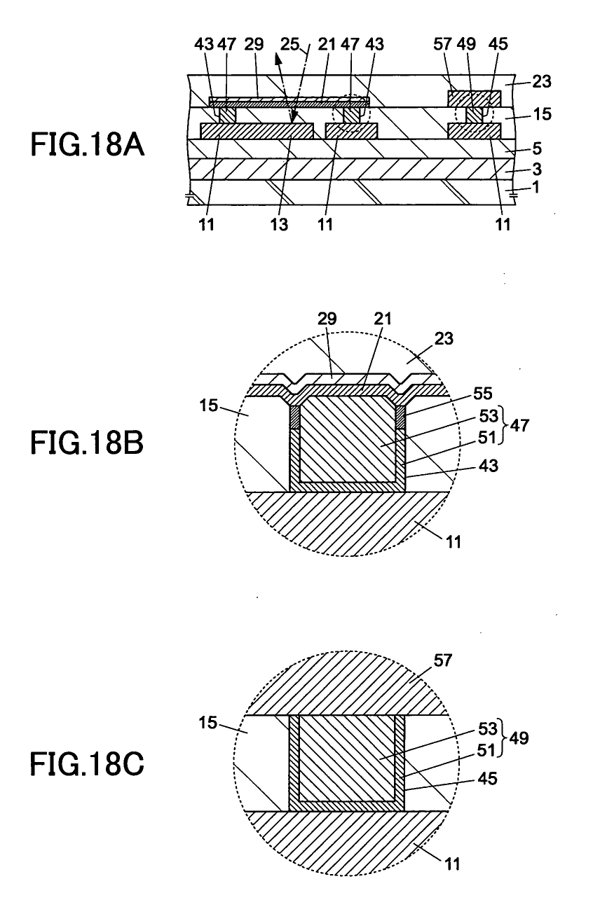

FIGS. 18A-18C are diagrams showing another embodiment of the second mode of the present invention, wherein FIG. 18A is a cross-sectional view, while FIG. 18B shows the region of the first contact hole with enlarged scale. Further, FIG. 18C shows the region of the second contact hole with enlarged scale. In the drawings those parts functionally corresponding to the parts explained previously with reference to FIGS. 16A-16C are designated by the same reference numerals and the description thereof will be omitted.

This embodiment is distinct over the foregoing embodiment of FIGS. 16A-16C in the point that the CrSi thin-film resistance 21 carries thereon the CrSiN film 29. Thereby, no CrSiO is formed between the Si thin-film resistance 21 and the CrSiN film 29.

Hereinafter the method of forming the CrSiN film 29 on the top surface of the CrSi thin-film resistance 21 will be explained with reference to FIGS. 18A-18C.

Thus, according to the steps (1)-(5) explained with reference to FIGS. 17A-17E, there is formed a structure on the silicon substrate 1 still in the form of silicon wafer, on which the formation of the device isolation oxide film 3 has been completed, such that the structure includes the first layer interlayer insulation film 5, the first layer metal interconnection pattern 11, the second layer interlayer insulation film 15, the contact holes 43 and 45, the conductive plugs 47 and 49, the second-layer metal interconnection pattern 27, the Ar sputter etching residue 55 and a CrSi thin film.

After formation of the CrSi thin film, there is formed a CrSiN film on the CrSi thin-film without breaking the vacuum, wherein the formation of the CrSiN film is conducted by using the CrSi target of the Si/Cr ratio of 80/20 wet % used for the CrSi thin film.

More specifically, the CrSiN film is formed under the pressure of 8.5 mTorr by setting the D.C. power to 0.7 kW while supplying a mixture of Ar and N₂ with the flow rate of 85 SCCM for the duration of 6 seconds. With this, the CrSiN film is formed on the CrSi thin-film with the thickness of about 50 Angstroms.

Next, the CrSiN film and the CrSi thin-film are patterned by a photolithographic process and dry etching process similarly to the step (6) explained with reference to FIG. 17F, and there is formed a laminated pattern of the CrSiN film pattern 29 and the CrSi thin-film resistance 21.

Thereafter, formation of the passivation film 29 is conducted on the second interlayer insulation film 15 including the formation region of the CrSi thin-film resistance 21 and the CrSiN film pattern 29.

Thus, with this mode, too, the CrSiN film 29 is formed on the top surface of the CrSi thin-film resistance 21 similarly to the embodiment of FIGS. 10A and 10B, and it is possible to avoid the problem of variation of the resistance value of the CrSi thin-film resistance 21 caused as a result of exposure of the top surface of the CrSi thin-film resistance 21 to the air.

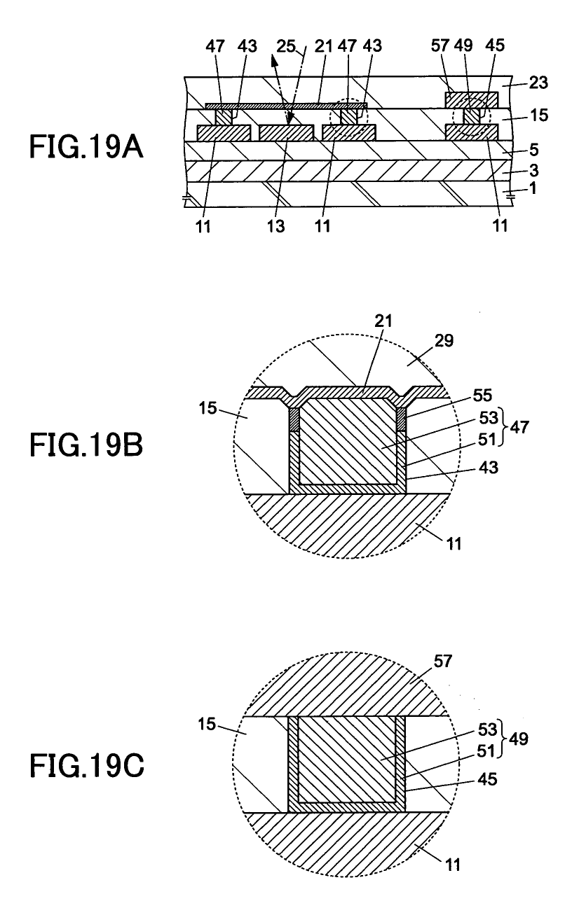

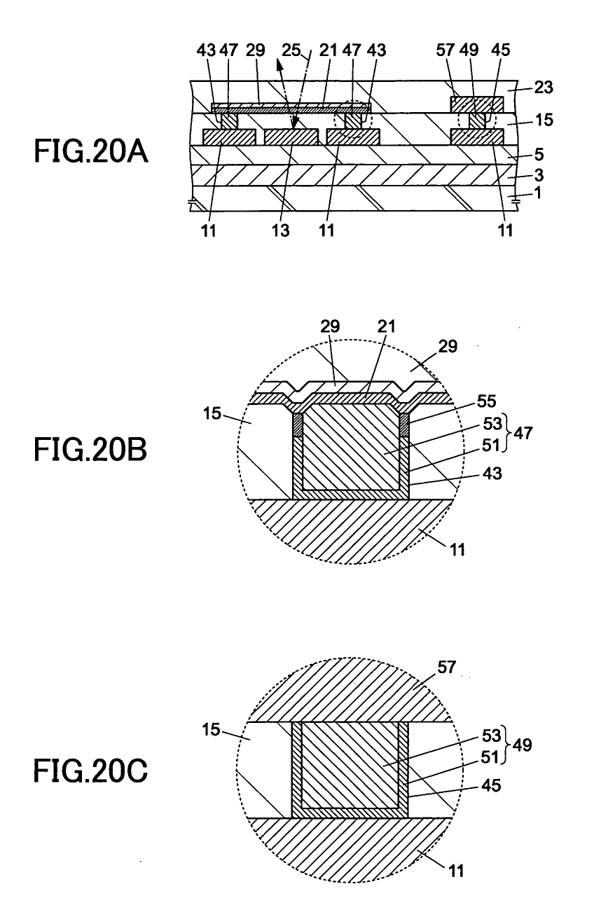

While the first layer metal interconnection pattern 11 and the laser beam interruption film 13 are formed continuously in the embodiments explained with reference to FIGS. 16A-16C and FIGS. 18A-18C, it is also possible to provide the laser beam interruption film 13 separately from the first layer metal interconnection pattern 11 as shown in FIGS. 19A-19C and FIGS. 20A-20C.

In the structures of FIGS. 19A-19C and FIGS. 20A-20C, too, the laser beam interruption film 13 of a metal material is provided between the second layer interlayer insulation film 15 and the silicon substrate 1 in the region underneath the CrSi thin-film resistance 21, and thus, the laser beam 25 passed through the second layer interlayer insulation film 15 is reflected by the laser beam interruption film 13 in the direction opposite to the silicon substrate 1 when a laser beam 25 is irradiated upon the CrSi thin-film resistance 21 at the time of laser trimming processing with the intensity sufficient for causing disconnection or modification of the CrSi thin-film resistance 21, and irradiation of the laser beam 25 upon the silicon substrate 1 is avoided.

It is noted that, in the embodiments shown in FIGS. 16A-16C, FIGS. 18A-18C, FIGS. 19A-19C and FIGS. 20A-20C, the laser beam interruption film 13 is formed of the same material as the first layer metal interconnection pattern 11 connected electrically to the CrSi thin-film resistance 21. However, the present invention is by no means limited to such a construction, and it is possible to construct the laser beam interruption film by a metal material different from the metal material used for the first layer metal interconnection pattern 11. Thereby, the laser beam interruption film is formed separately from the first layer metal interconnection pattern 11.

Further, while the laser beam interruption film 13 and the first layer metal interconnection pattern 11 connected electrically to the CrSi thin-film resistance 21 are both formed on the first layer interlayer insulation film 5 in the foregoing embodiment, the layer beam interruption film and the metal interconnection pattern may be formed on respective, different insulation films.

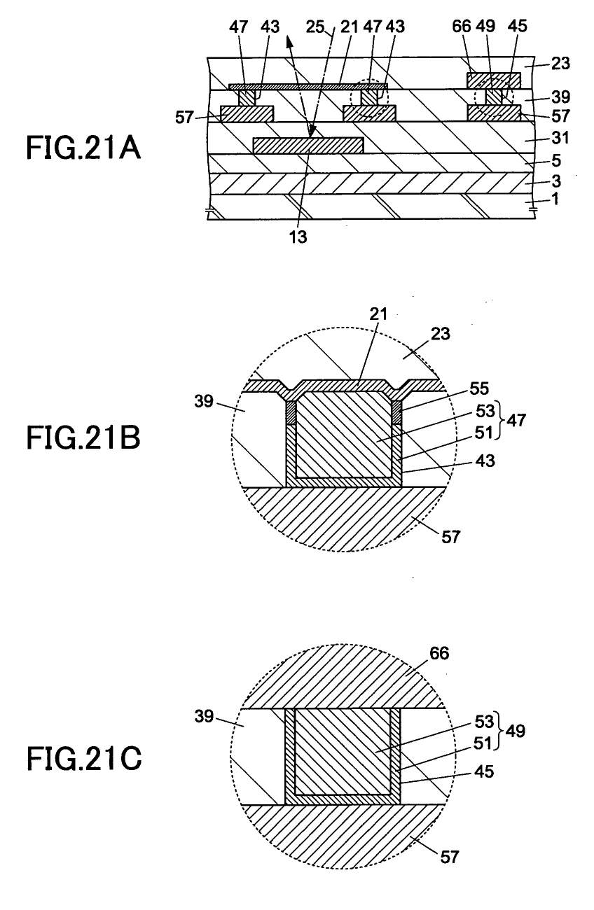

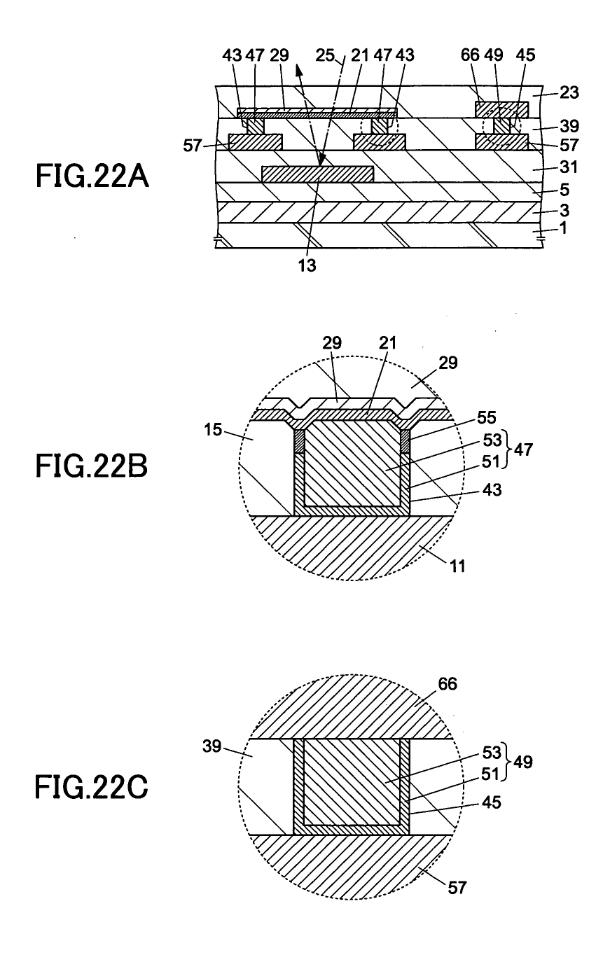

For example, the laser beam interruption film 13 may be formed on the first layer interlayer insulation film 5 as shown in FIGS. 21A-21C or FIGS. 22A-22C. Thereby, the CrSi thin-film resistance 21 is formed on the third layer interlayer insulation film 39 and the CrSi thin-film resistance 21 is connected to the second layer metal interconnection pattern 27 formed on the second layer interlayer insulation film 31 via the first conductive plug 47 filling the first contact hole 43 formed in the third layer interlayer insulation film 39.

In FIGS. 21A-21C and FIGS. 22A-22C, it should be noted that those parts functionally corresponding to the parts in FIGS. 16A-16C or FIGS. 18A-18C are designated by the same reference numerals and the description thereof will be omitted. Further, each of the second layer interlayer insulation film 31 and the third layer interlayer insulation film 39 are formed of consecutive lamination of a plasma CVD oxide film, an SOG film and a plasma CVD oxide film. The reference numeral 67 designates the uppermost metal interconnection pattern, wherein the uppermost metal interconnection pattern is the third layer metal interconnection pattern formed on the third layer interlayer insulation film 39. The third layer metal interconnection pattern 66 can be formed similarly to the second layer metal interconnection pattern 57 according to the process explained with reference to FIGS. 17A-17F.

With the semiconductor device of the embodiments of FIGS. 21A-21C and FIGS. 22A-22C, the laser beam interruption film 13 of a metal material is interposed between the semiconductor substrate 1 and the third interlayer insulation film 39 in the region underneath the metal thin-film resistance 21, and thus, it is possible to reflect the laser beam 25 passed through the third interlayer insulation film 39 and the second interlayer insulation film 31, in the case the laser beam 25 is irradiated to the metal thin-film resistance at the time of the laser trimming process with sufficient energy for causing disconnection or modification of the metal thin-film resistance, in the direction away from the silicon substrate 1. Thereby, irradiation of the laser beam 25 upon the silicon substrate 1 is successfully avoided.

Further, while titanium is used for the barrier metal 51 and tungsten is used for the tungsten plug 53 for the first conductive plug 47 and the second conductive plug 49 in each of the embodiments explained with reference to FIGS. 16A-16C through FIGS. 22A-22C, the first conductive plug and the second conductive plug of the present invention are not limited to these. For example, it is possible to use a material other than titanium such as TiW, TiN, W, WSi, and the like, for the first conducive material (barrier metal). Further, it is possible to use a material other than tungsten such as Cu, Al, WSi, or the like, for the second conductive material. Further, the material for the first conductive material and the second conductive material are not limited to the materials listed above.

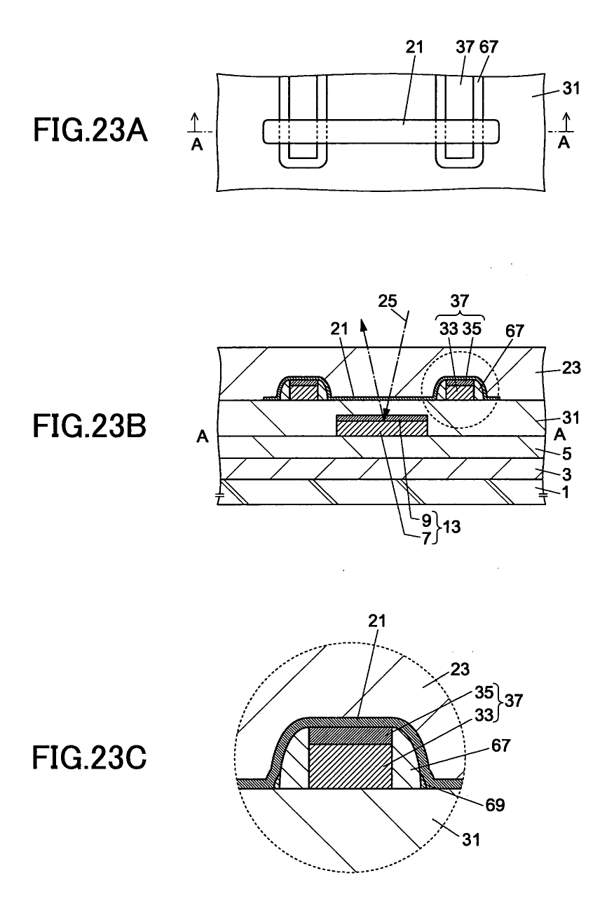

FIGS. 23A-23C are diagrams showing an embodiment of the third mode of the present invention, wherein FIG. 23A is a plan view while FIG. 23B is a cross-sectional view taken along an A-A line of FIG. 23A, and FIG. 23C is an enlarged cross-sectional view showing the part of FIG. 23B surrounded by the broken line with enlarged scale. In FIG. 23A, illustration of the passivation film is omitted. In the drawings, those parts functionally corresponding to the parts in FIGS. 14A and 14B are designated by the same reference numerals and the description thereof will be omitted.

Referring to FIG. 23A-23C, the device isolation oxide 3 is formed on the surface of the silicon substrate 1, and the first layer interlayer insulation film 5 is formed on the silicon substrate 1 including the device isolation oxide 3, wherein the first layer interlayer insulation film 5 carries the laser beam interruption film 13 formed of lamination of the metal pattern 7 and the refractory metal film 9. In other regions not illustrated, the first layer metal interconnection pattern is formed on the first layer interlayer insulation film 5 in the form of the lamination of the metal pattern 7 and the refractory metal film 9.

On the first layer interlayer insulation film 5 including the region of the laser beam interruption film, the second layer interlayer insulation film 31 is formed, and the second layer metal interconnection pattern 37 is formed on the second layer interlayer insulation film in the form of lamination of the metal pattern 33 and the refractory metal film 35.

Further, the second layer metal interconnection pattern 37 carries a sidewall insulation film 67 of a CVD oxide film, or the like, on the sidewall surface thereof, wherein it will be noted that there is formed an Ar sputter etching residue 69 on the surface of the sidewall insulation film 67 close to the surface of the second layer interlayer insulation film, wherein illustration of this Ar sputter etching residue 69 is omitted in the representation of FIGS. 23A and 23B. It should be noted that this Ar sputter etching residue 69 is formed by applying an Ar sputter etching process to the second layer interlayer insulation film 31 after formation of the second layer metal interconnection pattern 37 and the sidewall insulation film 67. This Ar sputter etching residue contains at least the material the second layer interlayer insulation film 31 and the sidewall insulation film 67 and Ar as the constituent elements thereof.

Further, it will be noted that the CrSi thin film-resistance 21 is formed in a band-like form so as to extend over the region of the second layer interlayer insulation film 31 between a pair of second layer metal interconnection patterns 37 including the surface of the sidewall insulation film 67 and the surface of the Ar sputter etching residue 69.

Further, both end parts of the CrSi thin-film resistance 21 extend over the respective surfaces of the sidewall insulation films 67 and over the surfaces of the Ar sputter etching residues 69 at the opposite sides of the foregoing mutually facing sides of the second layer metal interconnection pattern pair 37 and extend further over the surface of the second layer interlayer insulation film 31. Thereby, it should be noted that the CrSi thin-film resistance 21 and the second layer metal interconnection pattern 37 are formed so as to cross with each other.

Further, the passivation film 23 (not shown in FIG. 23A) is formed on the second layer interlayer insulation film 31 including the region where the CrSi thin-film resistance 21 is formed, as the final protective film.

With the semiconductor device of this embodiment, the laser beam interruption film 13 of a metal material is interposed between the semiconductor substrate 1 and the second interlayer insulation film 31 in the region underneath the metal thin-film resistance 21, and thus, it is possible to reflect the laser beam 25 passed through the second interlayer insulation film 31, in the case the laser beam 25 is irradiated to the metal thin-film resistance at the time of the laser trimming process with sufficient energy for causing disconnection or modification of the metal thin-film resistance, in the direction away from the silicon substrate 1. Thereby, irradiation of the laser beam 25 upon the silicon substrate 1 is successfully avoided.

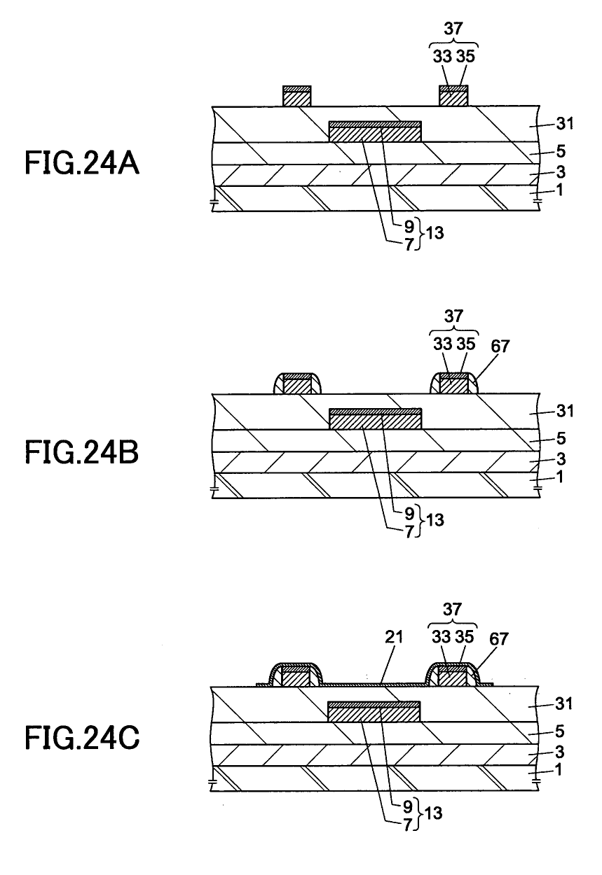

FIGS. 24A-24C are cross-sectional diagrams for explaining an example of fabricating the semiconductor device of the present embodiment. Hereinafter, the present embodiment will be explained with reference to FIGS. 23A-23C and FIGS. 24A-24C.

(1) First, the first layer insulation film 5 is formed on the silicon substrate 1 after formation of the transistor (not shown) in the device region defined thereon by the device isolation oxide 3 according to the process step (1) explained with reference to FIG. 2A. Further, the laser beam interruption film 13 is formed on the first layer interlayer insulation film 5 in the form of lamination of the metal interconnection pattern 7 and the refractory metal film 9.

Thereafter the second layer interlayer insulation film 15 is formed on the first interlayer insulation film 5 according to the process similar to the process step (2) explained with reference to FIG. 2B, such that second interlayer insulation film 15 has a laminated structure in which a CVD oxide film, an SOG film and a CVD oxide film are laminated consecutively.

Further, in the step of FIG. 24A, the second layer metal interconnection pattern 37 is formed on the second layer interlayer insulation film 31 in the form of lamination of the metal pattern 33 and the refractory metal film 35, similarly to the case of forming the first layer metal interconnection pattern 11 in the step (1) explained with reference to FIG. 2A.

In this state, no metal thin-film resistance is formed yet, contrary to the prior art process, and the underlying film of the second layer metal interconnection pattern 37 is provided by the second layer interlayer insulation film 37.

Thus, there is no problem in conducting the patterning of the refractory metal film and the interconnection metal film by using dry etching process with sufficient overetching, and thus, there is no need of using a wet etching process that has caused various problems in the prior art. Thus, no adversary effect is caused on device miniaturization.

(2) Next, by using a plasma CVD process, for example, a plasma CVD oxide film is formed on the second layer interlayer insulation film including the region where the second layer metal interconnection pattern 37 is formed with the thickness of about 2000 Angstroms, followed by an etch back process to form the sidewall insulation film 67 of the plasma CVD oxide on the sidewall surfaces of the second layer metal interconnection pattern 37. Reference should be made to FIG. 24B.

(3) Next, in an Ar sputter etching chamber of a multi-chamber sputtering apparatus, an Ar sputter etching process is applied to the second layer interlayer insulation film 31 including the region where the second layer metal interconnection pattern 37 and the sidewall insulation film 67 are to be formed, in vacuum environment under the condition of: DC bias set to 1250V; Ar flow rate set to 20 SCCM; and processing pressure set to 8.5 mTorr, for the duration of 20 seconds. This etching condition is identical to the etching condition for etching a thermal oxide film formed at 1000° C. in a wet ambient with the thickness of about 50 Angstroms.

As a result of this Ar sputter etching process, the Ar sputter etching residue 69 is formed on the surface of the sidewall insulation film 67 close to the surface of the second layer interlayer insulation film 31. Reference should be made to FIG. 23C.

Next, the CrSi thin-film for the metal thin-film resistance is formed after completion of the Ar sputter etching process in continuation therewith without breaking the vacuum.

In the present example, the semiconductor wafer is transported from the Ar sputter etching chamber to a sputter chamber in which the CrSi target is mounted, and formation of the CrSi thin film is conducted on the entire surface of the second layer insulation film 31 including the region where the interconnection pattern 11 and the sidewall insulation films 67 and 67 have been formed, with the thickness of about 50 Angstroms, by using the CrSi target of the composition of Sr/Cr=80/20 wt % under the condition of: DC power set to 0.7 kW; Ar flow rate set to 85 SCCM; processing pressure set to 8.5 mTorr, for the duration of 9 seconds.

Next, a resist pattern for defining the region of the metal thin-film resistance is formed on the CrSi thin film by a photolithographic process, For example, an RIE apparatus is used for patterning the CrSi thin-film while using the resist pattern as a mask, and the CrSi thin-film resistance 21 is formed as represented in FIG. 24C. Thereafter, the resist pattern is removed.

Here, it should be noted that the CrSi thin-film resistance 21 is connected to a part of the second layer metal interconnection pattern 37 electrically, and thus, it is no longer necessary to conduct a process of removing metal oxide from the surface of the CrSi thin-film resistance by using hydrofluoric acid for achieving electrical contact at the top surface of the metal thin-film resistance, contrary to the conventional art.

(4) Next, by using a plasma CVD process, a silicon oxide film and a silicon nitride film are deposited consecutively on the entire surface of the second layer insulation film 31 as the passivation film 23. With this, fabrication of the semiconductor device is completed. Reference should be made to FIGS. 23A-23C.

Thus, there is no longer the need of carrying out patterning by a wet etching process after formation of the CrSi thin-film resistance. Further, because there is no chance that the contact surface of the CrSi thin-film resistance 21 to the second layer metal interconnection pattern 37 is exposed to the air, and it is possible to achieve good electrical contact between the CrSi thin-film resistance 21 and the second layer metal interconnection pattern 37 without applying the surface oxide removal process and formation of etching stopper barrier on the CrSi thin-film resistance 21. With this, it is possible to achieve miniaturization of the CrSi thin-film resistance 21 and stabilization of the resistance value thereof irrespective of the thickness of the CrSi thin-film resistance 21, without increasing the number of the fabrication process steps.

Further, because the CrSi thin-film resistance 21 is formed so as to extend over the second layer interlayer insulation film 31 from the top surface of the second layer metal interconnection pattern 37 via the surface of the side wall insulation film 67 and the Ar sputter etching residue 69, there is no need of conducting a series of process steps for forming a contact hole contrary to the case of achieving electrical contact between the metal thin-film resistance and the interconnection pattern via a contact hole formed on the interconnection pattern, and it becomes possible to simplify the process and reduce the number of the process steps. Thereby, there is caused no problem such as variation of the resistance value of the metal thin-film resistance or degradation of contact resistance due to poor step coverage of the metal thin-film resistance at such a contact hole.

Further, because of existence of the sidewall insulation film 67 at the sidewall surface of the second layer metal interconnection pattern 37, it is possible to avoid deterioration of step coverage of the CrSi thin-film resistance 21 caused by the steep step at the sidewall surface of the interconnection pattern 11. Thus, with the present mode of the invention, it is possible to stabilize the resistance value of the CrSi thin-film resistance 21 including the contact resistance to the second layer metal interconnection pattern 37.

Further, because the end parts of the CrSi thin-film resistance 21 are formed so as to intersect with the second layer metal interconnection pattern 37, it becomes possible to eliminate the variation of the contact region between the second layer metal interconnection pattern 37 and the CrSi thin-film resistance 21 caused by misalignment of overlapping between the second layer metal interconnection pattern 27 and the CrSi thin-film resistance or caused by rounding at the end parts of the CrSi thin-film resistance 21.

Further, because the refractory metal film 35 functioning as a barrier film is interposed between the CrSi thin-film resistance 21 and the metal pattern 33, variation of contact resistance between the CrSi thin-film resistance 21 and the second layer metal interconnection pattern 38 is reduced, and precision of the resistance value is improved for the CrSi thin-film resistance 21 together with the yield of production.

Further, because the refractory metal film 35 functions as a barrier film and simultaneously an antireflection film, it is possible to form the refractory metal film 35 with the present mode of the invention without increasing the number of fabrication process steps as compared with the prior art. Thereby, it becomes possible to stabilize the contact resistance between the metal thin-film resistance and the interconnection pattern while avoiding increase of the production cost.

Further, because the Ar sputter etching process is conducted immediately before formation of the CrSi thin-film used for the CrSi thin-film resistance 21, the dependence of the CrSi thin-film resistance on the underlying film is improved as explained already with reference to FIGS. 4 through 8.

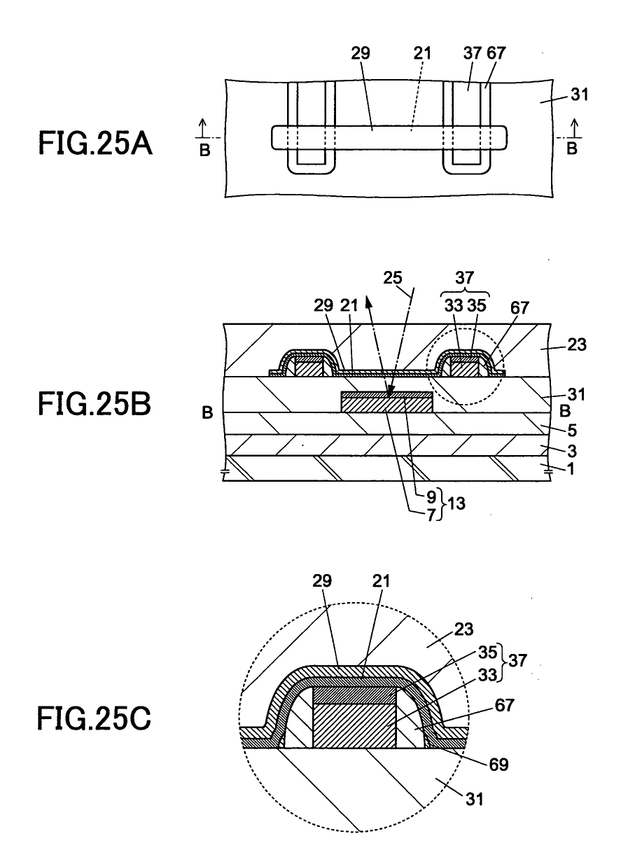

FIGS. 25A-25C are diagrams showing another embodiment of the third mode of the present invention, wherein FIG. 25A is a plan view while FIG. 25B is a cross-sectional view taken along an B-B line of FIG. 25A, and FIG. 25C is an enlarged cross-sectional view showing the part of FIG. 25B surrounded by the broken line with enlarged scale. In FIG. 25A, illustration of the passivation film is omitted. In the drawings, those parts functionally corresponding to the parts described previously in FIGS. 23A-23C are designated by the same reference numerals and the description thereof will be omitted.

The embodiment of FIGS. 23A-23C is different from the embodiment of FIGS. 18A-18C in the point that the CrSiN film 29 is formed on the top surface of the CrSi thin-film resistance 21. No CrSiO is formed between the CrSi thin-film resistance and the CrSiN film 29. The CrSiN film 29 can be formed similarly to the process explained with reference to FIGS. 10A and 10B.

In this embodiment, too, the CrSiN film 29 is provided on the top surface of the CrSi thin-film resistance 21 similarly to the embodiment shown in FIGS. 10A and 10B, and thus, variation of resistance value of the CrSi thin-film resistance 21 caused by exposure of the top surface of the CrSi thin-film resistance 21 to the air can be avoided.

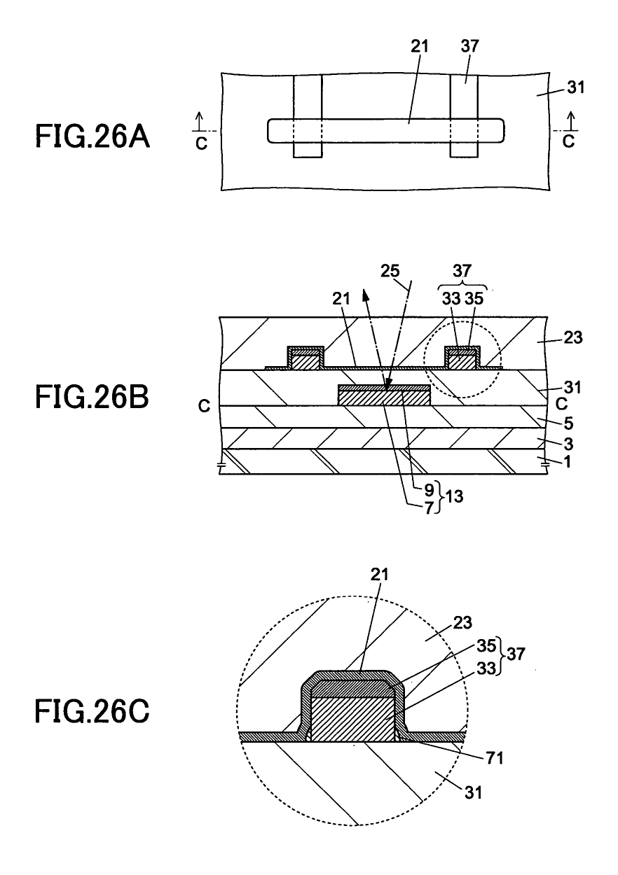

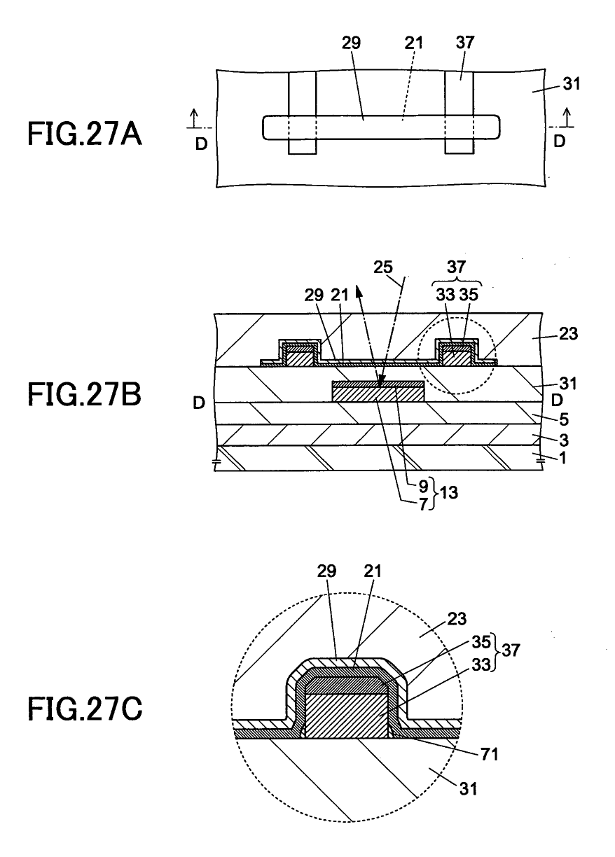

While the embodiments of FIGS. 23A-23C and FIGS. 25A and 25B uses the sidewall insulation film 67 on the sidewall surfaces of the second layer metal interconnection pattern 37, the semiconductor device according to the third mode of the present invention may have a construction in which no sidewall insulation film is formed on the sidewall surfaces of the second layer metal interconnection pattern 37 as shown in FIGS. 26A-26C and FIGS. 27A-27C.

In FIGS. 26A-26C and FIGS. 27A-27C, the reference numeral 71 designates the Ar sputter etching residue formed as a result of Ar sputter etching applied immediately before formation of the CrSi thin-film for the CrSi thin-film resistance 21. The Ar sputter etching residue 71 contains at least the material of the refractory metal 35 and the material of the second layer interlayer insulation film 31 as the constituent elements thereof. Further, tapered shape is formed at the top end part of the refractory metal film 35 as a result of the Ar sputter etching process. As a result of the Ar sputter etching residue 71 and the tapered shape of the refractory metal 35, the CrSi thin-film resistance 21 has improved step coverage. Further, as a result of the Ar sputter etching process applied immediately before formation of the CrSi thin-film for the CrSi thin-film resistance 21, dependence of the CrSi thin-film resistance 21 upon the underlying film is improved.

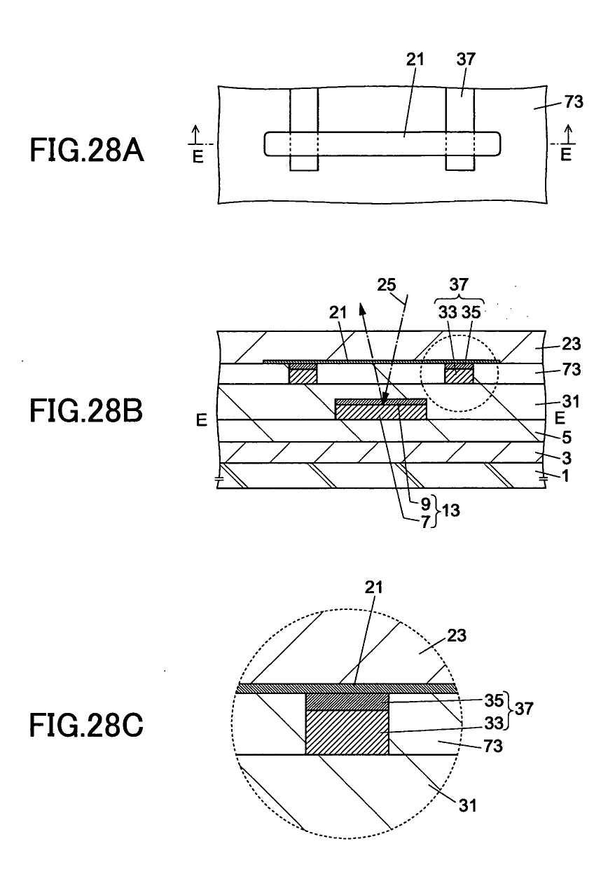

FIGS. 28A-28C are diagrams showing an embodiment of the fourth mode of the present invention, wherein FIG. 28A is a plan view while FIG. 28B is a cross-sectional view taken along an E-E line of FIG. 28A, and FIG. 28C is an enlarged cross-sectional view showing the part of FIG. 28B surrounded by the broken line with enlarged scale. In FIG. 28A, illustration of the passivation film is omitted. In the drawings, those parts corresponding to the parts described previously are designated by the same reference numerals and the description thereof will be omitted.

Referring to FIG. 28A-28C, the device isolation oxide 3 is formed on the surface of the silicon substrate 1, and the first layer interlayer insulation film 5 is formed on the silicon substrate 1, wherein the first layer interlayer insulation film 5 carries thereon the laser beam interruption film 13 formed of the metal pattern 7 and the refractory metal film 9 formed thereon. Further, the second layer interlayer insulation film 31 and the second layer metal interconnection pattern 37 formed of the metal pattern 33 and the refractory metal film 35 are formed further thereon.

On the second layer interlayer insulation film 31, there is formed an underlying insulation film (base insulation film) 73 formed of lamination of a lower plasma CVD film and an upper SOG film, wherein the underlying insulation film 73 is subjected to an etch back process or CMP process after lamination of the foregoing layers to the depth such that the top surface of the second layer metal interconnection pattern 37 is exposed. It should be noted that FIG. 28B illustrates the underlying insulation film 73, formed of the plasma CVD oxide film and the SOG film, as if it is a single layer film. Here, it should be noted that the underlying film 73 is not limited to the plasma CVD oxide film or the SOG film or to a specific material but any insulation film or material may be used with the thickness such that the top surface of the second layer metal interconnection pattern 37 on the second layer interlayer insulation film 31 is exposed.

Further, it will be noted that the CrSi thin film-resistance 21 is formed in a band-like form so as to extend over the region of the base insulation film 73 between a pair of second layer metal interconnection patterns 37. Further, both end parts of the CrSi thin-film resistance 21 extend over the base insulation film 73 existing at the opposite lateral sides of the foregoing mutually facing sides of the second layer metal interconnection pattern pair 37, and the CrSi thin-film resistance 21 and the second layer metal interconnection pattern 37 are formed so as to cross with each other.

Further, the passivation film 23 (not shown in FIG. 28A) is formed on the interlayer insulation film 5 including the region where the CrSi thin-film resistance 21 is formed.

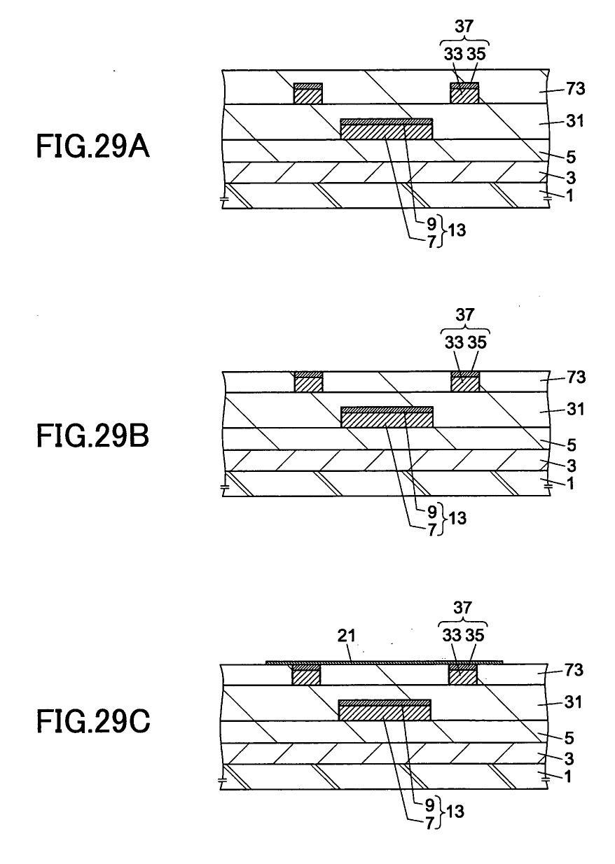

FIGS. 29A-29C are cross-sectional diagrams for explaining an example of fabricating the semiconductor device of the present embodiment. Hereinafter, the present embodiment will be explained with reference to FIGS. 28A-28C and FIGS. 29A-29C.

(1) First, in the step of FIG. 29A, the first layer insulation film 5 is formed on the silicon substrate 1 after formation of the transistor (not shown) in the device region defined thereon by the device isolation oxide 3 according to the process step (1) explained with reference to FIG. 2A, and the laser beam interruption film 13 of lamination of the metal pattern 7 and the refractory metal film 9 is formed on the first layer interlayer insulation film 5.

Further, the second layer interlayer insulation film 31 is formed on the entire surface of the first layer interlayer insulation film 5 in the form of consecutive lamination of the lowermost CVD oxide film, intermediate SOG film and the uppermost CVD oxide film, similarly to the process of forming the second layer interlayer insulation film 15 explained with reference to the step (2) of FIG. 2B, and the second layer metal interconnection pattern 37 is formed on the second layer interlayer insulation film 31 in the form of lamination of the metal pattern 33 and the refractory metal film 35 similarly to the step (1) explained with reference to FIG. 2A for forming the first layer metal interconnection pattern 11.

For example, a plasma CVD oxide film is formed on the second layer interlayer insulation film 31 including the region where the second layer metal interconnection pattern 37 is formed by using a plasma CVD process with the thickness of about 2000 Angstroms, and the SOG film is formed thereafter by applying an SOG with a known coating process. With this the underlying insulation film 73 is formed in the state that the top surface of the second layer metal interconnection pattern 37 is covered with the underlying insulation film 73. Reference should be made to FIG. 29A.

(2) Next, in the step of FIG. 29B, an etch back process or CMP process is applied to the base insulation film 73 until the top surface of the second layer metal interconnection pattern 37 is exposed.

(3) Next, an Ar sputter etching process is applied to the second layer interlayer insulation film 31 including the region where the second layer metal interconnection pattern 37 under the condition identical with the Ar sputter etching processing explained with reference to FIG. 2D. Subsequently, formation of the CrSi thin-film for the metal thin-film resistance is formed after completion of the Ar sputter etching process, without breaking the vacuum.

Next, a resist pattern for defining the region of the metal thin-film resistance is formed on the CrSi thin film by a photolithographic process, for example, and an RIE apparatus is applied for patterning the CrSi thin-film while using the resist pattern as a mask, and the CrSi thin-film resistance 21 is formed as represented in FIG. 29C. Thereafter, the resist pattern is removed.

(4) Next, by using a plasma CVD process, a silicon oxide film and a silicon nitride film are deposited consecutively on the entire surface of the second layer insulation film 31 as the passivation film 23. With this, fabrication of the semiconductor device is completed. Reference should be made to FIGS. 28A-28C.

Thus, there is no longer the need of carrying out patterning by a wet etching process after formation of the CrSi thin-film resistance in the embodiment of FIGS. 28A-28C. Further, because there is no chance that the contact surface of the CrSi thin-film resistance 21 to the second layer metal interconnection pattern 37 is exposed to the air, it is possible to achieve good electrical contact between the CrSi thin-film resistance 21 and the second layer metal interconnection pattern 37 irrespective of the thickness of the CrSi thin-film resistance 21, without increasing the number of the fabrication steps.

In this embodiment, too, there is no need of formation of the contact hole for electrically connecting the CrSi thin-film resistance 21 and the second layer metal interconnection pattern 37 similarly to the embodiment explained with reference to FIGS. 23A-23C, and it becomes possible to simplify the process and reduce the number of the process steps. Thereby, there is caused no problem such as variation of the resistance value of the metal thin-film resistance or degradation of contact resistance due to poor step coverage of the metal thin-film resistance at such a contact hole.

Thus, with the present mode of the invention, in which the base insulation film 73 is formed at both lateral sides of the second layer metal interconnection pattern, it is possible to avoid deterioration of step coverage of the CrSi thin-film resistance 21 caused by the steps at the sidewall surfaces of the second layer metal interconnection pattern 37.

Thus, with the present mode of the invention, it is possible to stabilize the resistance value of the CrSi thin-film resistance 21 including the contact resistance to the second layer metal interconnection pattern 37.

Further, because the end parts of the CrSi thin-film resistance 21 are formed so as to intersect with the second layer metal interconnection pattern 37, it becomes possible to eliminate the variation of the contact region between the second layer metal interconnection pattern 37 and the CrSi thin-film resistance 21 caused by misalignment of overlapping between the second layer metal interconnection pattern 27 and the CrSi thin-film resistance or caused by rounding at the end parts of the CrSi thin-film resistance 21.

Further, because the refractory metal film 35 functioning as a barrier film is interposed between the CrSi thin-film resistance 21 and the metal pattern 33, variation of contact resistance between the CrSi thin-film resistance 21 and the second layer metal interconnection pattern 38 is reduced, and precision of the resistance value is improved for the CrSi thin-film resistance 21 together with the yield of production.

Further, because the refractory metal film 35 functions as a barrier film and simultaneously an antireflection film, it is possible to form the refractory metal film 35 with the present mode of the invention without increasing the number of fabrication process steps as compared with the prior art. Thereby, it becomes possible to stabilize the contact resistance between the metal thin-film resistance and the interconnection pattern while avoiding increase of the production cost.

Further, by applying the Ar sputter etching process, the insulating material on the top surface of the refractory metal film 35 constituting the second layer metal interconnection pattern 37 is removed and the dependency of the CrSi thin-film resistance 21, which is to be formed later, on the underlying film, is improved at the same time.

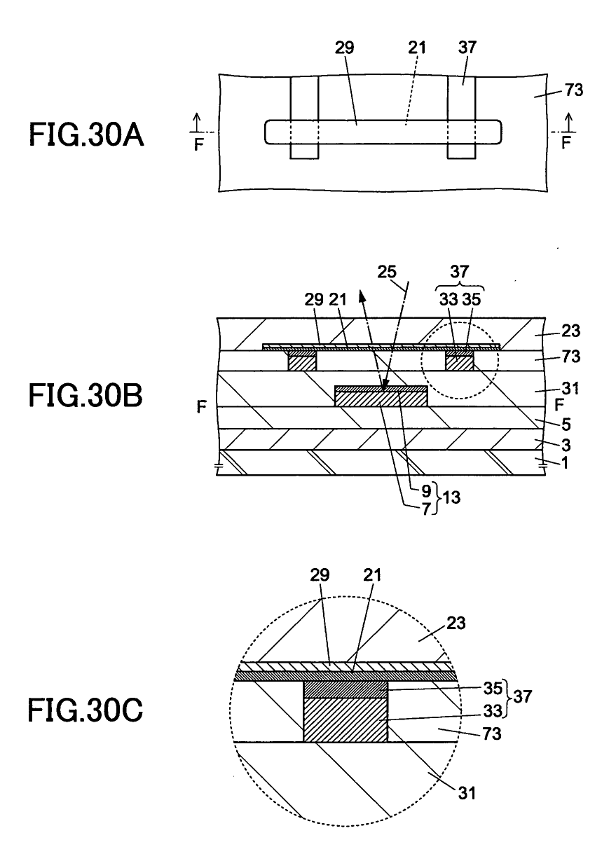

FIGS. 30A-30C are diagrams showing another embodiment of the fourth mode of the present invention, wherein FIG. 30A is a plan view while FIG. 30B is a cross-sectional taken along a F-F line of FIG. 30B and FIG. 30C is a cross-sectional view showing the part of FIG. 30B circled by a broken line with enlarged scale. In the drawings, those parts corresponding to the parts described previously with reference to FIGS. 28A-28C are designated by the same reference numerals and the description thereof will be omitted.

The present embodiment is distinct over the embodiment explained with reference to FIGS. 28A-28C in that the CrSiN film 29 is formed on the top surface of the CrSi thin-film resistance 21. Thus, no CrSiO is formed between the CrSi thin-film resistance 21 and the CrSiN film 29. The CrSiN film 29 can be formed similarly to the embodiment explained with reference to FIGS. 10A and 10B.

In this embodiment, too, the CrSiN film 29 is formed on the top surface of the CrSi thin-film resistance 21 similarly to the embodiment of FIG. 10, and it is possible to prevent the change of resistance value of the CrSi thin-film resistance 21 caused by exposure of the top source of the CrSi thin-film resistance 21 to the air.

While the CrSi thin-film resistance 21 and the second layer metal interconnection pattern 37 are formed so as to cross with each other in the embodiments of FIGS. 23A-23C, FIGS. 25A-25C, FIGS. 26A-26C, FIGS. 27A-27C, FIGS. 28A-28C and FIGS. 30A-30C, the present invention is by no means limited to this and the end part of the metal thin-film resistance may be disposed on the metal interconnection pattern. Alternatively, the end part of the metal thin-film resistance may be disposed under the metal interconnection pattern.

Further, it is not necessary that the metal thin-film resistance is disposed so as to cross perpendicularly to the metal interconnection pattern and it is possible to dispose the metal thin-film resistance so as to extend parallel with the metal interconnection pattern. Further, the shape, orientation and arrangement of the metal thin-film resistance and the metal interconnection pattern are by no means limited to those explained in the embodiments.

While the foregoing embodiments describe the example of using a TiN film for the refractory metal film 9, 33 or 57 formed on the top surface of the metal interconnection pattern, the refractory metal film constituting the metal interconnection pattern is by no means limited to this, but other refractory metal films such as TiW or WSi may also be used.

Further, while the experiments explained with reference to FIGS. 1A and 1B through FIGS. 30A-30C use CrSi for the material of the metal thin-film resistance, the present invention is not limited to this, but other materials such as NiCr, TaN, CrSi2, CrSiN, CrSi, CrSiO, and the like, may also be used for the metal thin-film resistance.

Further, while the foregoing embodiments explain the present invention as applied to a semiconductor device having the metal interconnection pattern of single layer, dual layer, or triple layer, the present invention is by no means limited to this and it is possible to apply the present invention to the semiconductor devices having a multilayer interconnection structure in which there are provided four or more layers of metal interconnection patterns. Thereby, the metal interconnection pattern to which the metal thin-film resistance is connected for electrical connection may be the metal interconnection pattern of any layer.

Further, the laser beam interruption film disposed underneath the metal thin-film resistance may be formed together with the metal interconnection pattern of any layer, as long as it is located underneath the metal thin-film resistance. Further, the laser beam interruption film may be formed of a metal material formed separately to the metal interconnection pattern.

In the embodiments explained with reference to FIGS. 1A and 1B, FIGS. 10A and 10B, FIGS. 12A and 12B, FIGS. 13A and 13B, FIGS. 14A and 14B, FIGS. 15A and 15B, FIGS. 23A-23C, FIGS. 25A-25C, FIGS. 26A-26C, FIGS. 27A-27C, FIGS. 28A-28C and FIGS. 30A-30C, the first layer metal interconnection pattern 11 or second layer interconnection pattern 37 is used as the uppermost metal interconnection pattern. Further, in the embodiments of FIGS. 16A-16C, FIGS. 18-18C, FIGS. 19-19C, FIGS. 20A-20C, FIGS. 21A-21C and FIGS. 22A-22C, the second layer metal interconnection pattern 57 forming the same layer as the CrSi thin-film resistance 21 or the third layer metal interconnection pattern 66 is used as the uppermost metal interconnection pattern.

With this, the degree of freedom of design is improved such as achieving the layout change of the CrSi thin-film resistance 21 by way of the layout change of the CrSi thin-film resistance 21 and the uppermost metal interconnection pattern.

Further, because the passivation film 23 of insulation material is formed over the CrSi thin-film resistance 21 except of the thin CrSiN film 29, it becomes possible to reduce the variation of thickness of the insulating material over provided the CrSi thin-film resistance 21 together with the thickness thereof as compared with the case in which the insulation film other than the final protective film is formed over the metal thin-film resistance. With this, variation of laser energy provided to the CrSi thin-film resistance 21 is reduced at the time of trimming the CrSi thin-film resistance 21 with the laser beam, by reducing the variation of laser interference caused by the insulating material on the CrSi thin-film resistance 21. Thereby, precision of the trimming is improved, and it is further possible to improve the efficiency of heat radiation when there is caused a temperature rise in the CrSi thin-film resistance at the time of the trimming as a result of the laser beam irradiation.

Further, while there is formed a refractory metal film on the top surface of the metal interconnection patterns used for the metal interconnection patterns 11, 37 and 57 in the foregoing embodiments, the present invention is by no means limited to such a construction and it is possible to use a metal pattern not carrying a refractory metal film thereon for the metal interconnection pattern. In the case an Al alloy is used for the metal pattern, there is formed a strong native oxide film on the surface of the metal pattern, and thus, it is preferable to remove the native oxide film from the surface of the metal pattern at the bottom of the contact hole after the formation of the contact hole but before the formation of the metal thin-film for the formation of the metal thin-film resistance. It should be noted that such native oxide film removal process may be conducted by way of the Ar sputter etching process conducted primarily for suppressing the aging of resistance value of the metal thin-film resistance. Further, the metal interconnection pattern is not limited to those containing an Al alloy but the metal interconnection patterns of other metals such as a Cu interconnection pattern formed by a so-called damascene process may also be used.

The metal thin-film resistance constituting the semiconductor device of the present invention can be used for example in a semiconductor device having an analog circuit. Hereinafter, an embodiment of the semiconductor device having an analog circuit that uses such a metal thin-film resistance will be explained.

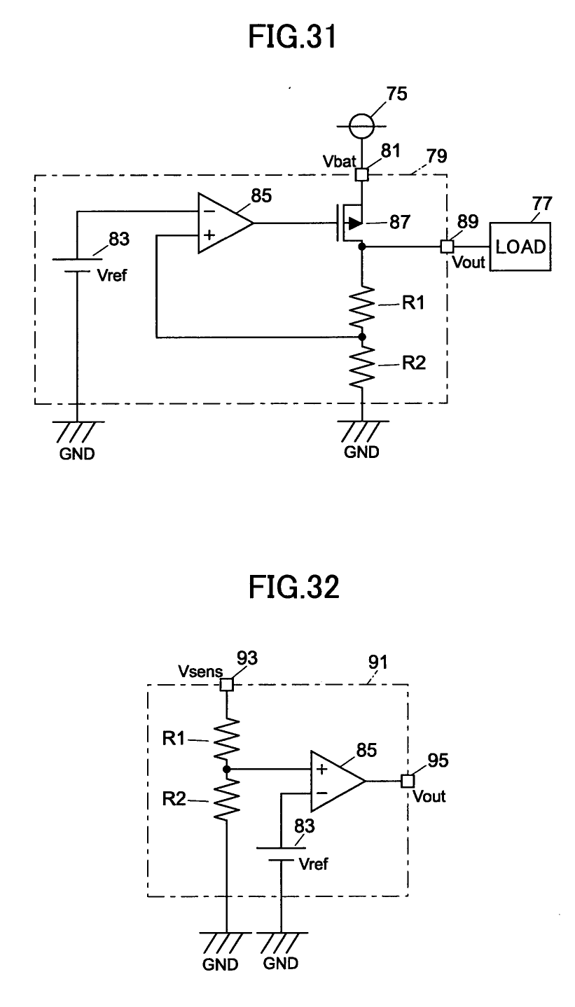

FIG. 31 is a circuit diagram showing an embodiment of the semiconductor device having an analog circuit that forms a constant voltage generator.

Referring to FIG. 31, there is provided a constant voltage generator 79 for supplying a stabilized power from a D.C. power supply 75 to a load 77. Thereby, it should be noted that the constant voltage generator 79 includes: an input terminal (Vbat) 81 to which the D.C. power supply 75 is connected; a reference voltage generator (Vref) 83; an operational amplifier (comparator) 85, a p-channel MOS transistor (designated hereinafter as PMOS) 87 constituting an output driver; voltage dividers R1 and R2; and an output terminal (Vout) 39.

In the operational amplifier 85 of the constant voltage generator 79, the output terminal thereof is connected to the gate electrode of the PMOS 87 and the reference voltage Vref of the reference voltage generator 83 is supplied to an inversion input terminal (−) thereof. Further, a voltage obtained by dividing the output voltage Vout by the resistance elements R1 and R2 is supplied to the non-inversion input terminal (+) thereof, and the voltage dividend out by the resistance elements R1 and R2 is controlled to be equal to the reference voltage Vref.

FIG. 32 is a circuit diagram showing an embodiment of the semiconductor device having an analog voltage detector.

Referring to FIG. 32, the voltage detector 91 includes an operational amplifier 85 having an inversion input terminal (−) connected to a reference voltage gubernator 83, wherein the inversion input terminal is supplied with a reference voltage Vref from the reference voltage generator 83. Further, the voltage of an input terminal 93 supplied for voltage detection is divided by the resistances R1 and R2 and the divided voltage is supplied to a non-inversion input terminal (+) of the operational amplifier 85. The output of the operational amplifier 85 is output via an output terminal (Vout) 95.

In such a voltage detector 91, it should be noted that the output of the operational amplifier 85 maintains a high level state (H) in the case the input voltage of the input terminal for voltage detection is high and the divided voltage divided out by the resistances R1 and R2 is higher than the reference voltage Vref. On the other hand, when the voltage to be measured has dropped and the voltage divided by the resistance elements R1 and R2 has decreased below the reference voltage Vref, the output of the operational amplifier 85 turns to the low level state (L).

Generally, the constant voltage generator of FIG. 31 or the voltage detector of FIG. 32 adjusts the resistance value of the resistance elements constituting the voltage divider by using an adjustable resistance circuit (called voltage divider) capable of changing the resistance value thereof by irradiation of laser beam to the resistance elements constituting the voltage divider, in view of variation of the reference voltage Vref of the reference voltage generator caused by the variation at the time of the fabrication process.

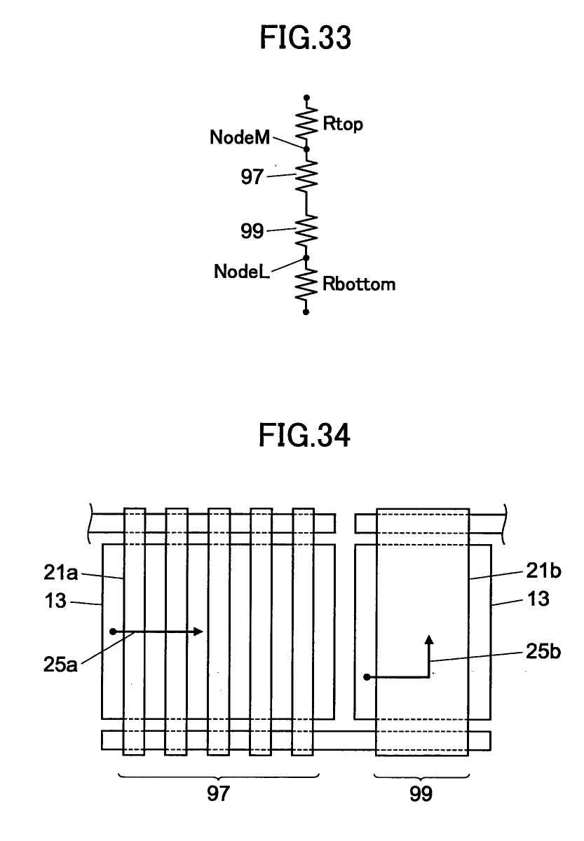

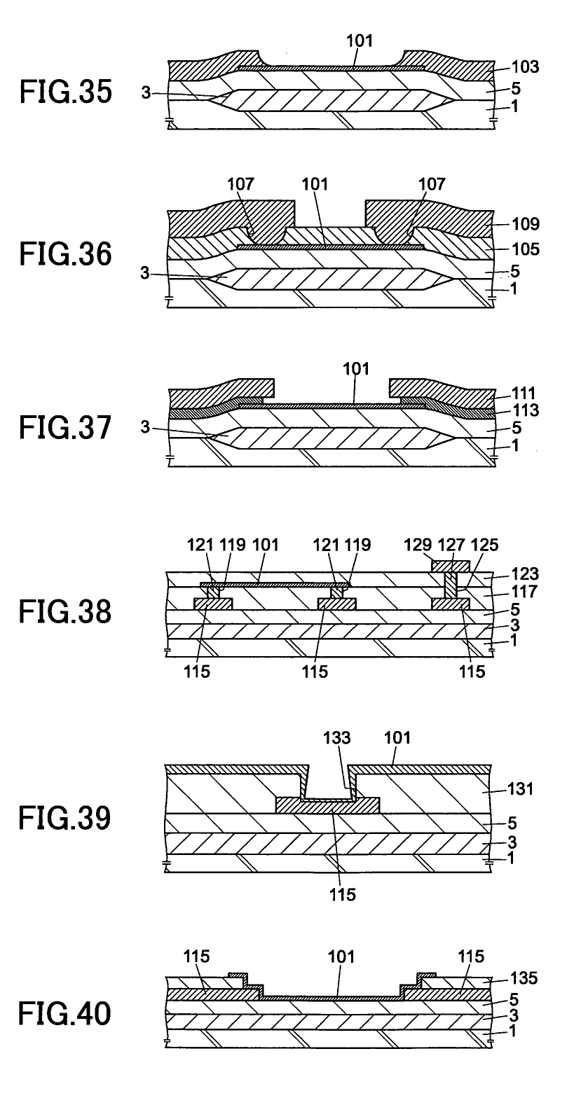

FIG. 33 is a circuit diagram showing an example of such an adjustable resistance circuit to which the metal thin-film resistance of the present invention is applied, while FIG. 34 is a layout diagram showing the example of layout of the adjustable resistance circuit.

As shown in FIG. 33, the resistance element Rbottom, the coarse adjustment resistance element 97, the fine adjustment resistance element 99 and the resistance element Rtop are connected in series.

As shown in FIG. 34, the coarse adjustment resistance element 97 is formed of parallel connection of plural band-like metal thin-film resistances 21a, while the fine adjustment resistance element 99 is formed of a plate-like metal thin-film resistance 21a. Underneath the metal thin-film resistances 21a and 21b, the layer beam interruption film 13 is disposed via an insulation film not illustrated. For the metal thin-film resistances 21a and 21b, the metal thin-film constituting the present invention is used.

With such a voltage divider circuit, arbitrary number of metal thin-film resistances 21a are disconnected or modified by the laser beam 25a and a desired serial resistance value is achieved by modifying an arbitrary region of the metal thin-film resistance 21b by disconnection or modification by the laser beam 25b as shown in FIG. 34.

According to the metal thin-film resistance and the laser beam interruption film constituting the semiconductor device of the present invention, at least a part of the constituting elements of the semiconductor integrated circuit other than the metal thin-film resistance is disposed in the region underneath the metal thin-film resistance, and it becomes possible to reduce the chip area. Thus, it becomes possible to reduce the chip area of the semiconductor device including the voltage divider shown in FIG. 33.

In the case of applying the voltage divider circuit of FIG. 33 to the resistor elements R1 and R2 of the constant voltage generator of FIG. 31, an end of the resistance element Rbottom is grounded and an end of the resistance element Rtop is connected to the drain of the PMOS 87. Further, the node NodeL between the resistance element Rbottom and the fine adjustment resistance element 99 or the node NodeM between the resistance element Rtop and the coarse adjustment resistance element 97 is connected to the non-inverting input terminal of the operational amplifier 85.

Because the precision of the output voltage of the voltage divider is improved by applying the metal thin-film resistance and the laser beam interruption film to the resistance elements R1 and R2 of the voltage divider, it becomes possible to stabilize the output voltage of the constant voltage generator 79.

In the case of applying the voltage divider circuit of FIG. 40 to the resistor elements R1 and R2 of the voltage detector 91 shown in FIG. 40, an end of the resistance element Rbottom is grounded and an end of the resistance element Rtop is connected to the input terminal 93. Further, the node NodeL between the resistance element Rbottom and the fine adjustment resistance element 99 or the node NodeM between the resistance element Rtop and the coarse adjustment resistance element 97 is connected to the non-inverting input terminal of the operational amplifier 85.

Because the precision of the output voltage of the voltage divider is improved by applying the metal thin-film resistance and the laser beam interruption film to the resistance elements R1 and R2 of the voltage divider, it becomes possible to improve the precision of the voltage detector 91.

While description has been made with reference to FIGS. 31-34 with regard to the example of the semiconductor device having the voltage divider with the construction of disposing the constituting elements of the semiconductor integrated circuit underneath the metal thin-film resistance of the present invention or the construction of the semiconductor device of disposing the laser beam interruption film underneath the metal thin-film resistance, the semiconductor device applied with such a voltage divider circuit is not limited to the semiconductor device having a constant voltage generator or the semiconductor device having a voltage detector, but the present invention can be applied to any semiconductor device having a voltage divider circuit.

Further, the construction of the semiconductor device of disposing the constituting elements of the semiconductor integrated circuit underneath the metal thin-film resistance or disposing the additional laser beam interruption film underneath the metal thin-film resistance of the present invention is by no means limited to the semiconductor device having a voltage divider circuit, but the present invention is applicable to any semiconductor device having a metal thin-film resistance.

Further, the present invention is by no means limited to the embodiments described heretofore, but various variations and modifications may be made without departing from the scope of the invention. It should be noted that the size, shape, material and arrangement explained heretofore are merely for the purpose of example.

The present application is based on the Japanese priority application 2004-074946 filed on Mar. 16, 2004, the entire contents of which are incorporated herein as reference.

1. A semiconductor device, comprising:
a base insulation film formed on a semiconductor substrate via another layer;
a metal thin-film resistance formed on said base insulation film; and
a laser beam interruption film of a metal material interposed between said semiconductor substrate and said base insulation film.

2. The semiconductor device as claimed in claim 1, further comprising: a lower insulation film formed underneath said base insulation film; a metal interconnection pattern formed on said lower insulation film; and a contact hole formed in said base insulation film in correspondence to said metal interconnection pattern, said metal thin-film resistance extending from a top surface of said base insulation film to said contact hole and connected electrically to said metal interconnection pattern in said contact hole.

3. The semiconductor device as claimed in claim 2, wherein said contact hole has a tapered form at least at a top edge part thereof, said contact hole having an inner wall surface carrying an Ar sputter etching residue containing a material of said metal interconnection pattern, a material of said base insulation film and Ar as constituent elements thereof.

4. The semiconductor device as claimed in claim 2, wherein said metal interconnection pattern comprises a metal pattern and a refractory metal film formed at least on a top surface of said metal pattern.

5. The semiconductor device as claimed in claim 2, wherein said metal interconnection pattern forms an uppermost interconnection pattern.

6. The semiconductor device as claimed in claim 2, wherein said laser beam interruption film is formed on said lower insulation film with a material identical with said metal interconnection pattern.

7. The semiconductor device as claimed in claim 2, wherein said laser beam interruption film is provided at a lower level of said metal interconnection pattern.

8. The semiconductor device as claimed in claim 1, wherein said metal thin-film resistance has a thickness of 5-1000 Angstroms.

9. The semiconductor device as claimed in claim 1, further comprising: a lower insulation film formed underneath said base insulation film; a metal interconnection pattern formed on said lower insulation film; a contact hole formed in said base insulation film in correspondence to said metal interconnection pattern; and a conductive plug formed in said contact hole, said metal thin-film resistance extending on a top surface of said base insulation film over said contact plug.

10. The semiconductor device as claimed in claim 9, wherein said metal interconnection pattern forms an uppermost interconnection pattern.

11. The semiconductor device as claimed in claim 9, wherein said contact hole constitutes a first contact hole and said contact plug constitutes a first contact plug, said semiconductor device further comprising: a second contact hole formed in said base insulation film in correspondence to said metal interconnection pattern in a region different from said first contact hole; a second conductive plug formed in said second contact hole simultaneously to said first conductive plug; and a second interconnection pattern formed on said base insulation film so as to extend over said second conductive plug, each of said first conductive plug and said second conductive plug comprising a first conductive material formed on an inner wall surface of respective, corresponding contact holes and a second conductive material formed on said first conductive material, an upper end part of said first conductive material being formed, in said first contact hole, with a separation from a top edge part of said first contact hole and with a separation from a top surface of said second conductive material. said second conductive material in said first contact hole having said top surface such that an outer periphery thereof forms a tapered shape together with said top edge part of first contact hole, and an Ar sputter etching residue is formed in a space formed in said first contact hole on said first conductive material between said inner wall surface of said first contact hole and said second conductive material such that said Ar sputter etching residue contains, as constituent elements thereof, at least an element constituting a material of said base insulation film, an element constituting said first conductive material and Ar.

12. The semiconductor device as claimed in claim 11, wherein said second metal interconnection pattern forms an uppermost metal interconnection pattern.

13. The semiconductor device as claimed in claim 9, wherein said laser beam interruption film is formed on said lower insulation film with a material identical with said metal interconnection pattern.

14. The semiconductor device as claimed in claim 9, wherein said laser beam interruption film is provided at a lower level of said metal interconnection pattern.

15. The semiconductor device as claimed in claim 1, further comprising a metal interconnection pattern on said base insulation film, said metal thin-film resistance extending on said base insulation film over said metal interconnection pattern.

16. The semiconductor device as claimed in claim 15, further comprising a sidewall insulation film on a sidewall surface of said metal interconnection pattern, said metal thin-film resistance extending over said metal interconnection via a surface of said sidewall insulation film.

17. The semiconductor device as claimed in claim 16, further comprising an Ar sputter etching residue on a surface of said sidewall insulation film close to said base insulation film, said Ar sputter etching residue containing, as constituent elements thereof, at least an element of a material forming said sidewall insulation film and Ar.

18. The semiconductor device as claimed in claim 16, wherein said metal interconnection pattern comprises a metal pattern and a refractory metal film formed at least on a top surface of said metal interconnection pattern.

19. The semiconductor device as claimed in claim 15, wherein said metal thin-film resistance intersects with said metal interconnection pattern.

20. The semiconductor device as claimed in claim 15, wherein said metal interconnection pattern forms an uppermost metal interconnection pattern.

21. The semiconductor device as claimed in claim 1, further comprising: a lower insulation film underneath said base insulation film; and a metal interconnection pattern formed on said lower insulation film, said base insulation film being formed on said lower insulation film with a thickness such that a top surface of said metal interconnection pattern is exposed, said metal thin-film resistance extending on said base insulation film over said metal interconnection pattern.

22. The semiconductor device as claimed in claim 21, wherein said metal interconnection pattern comprises a metal pattern and a refractory metal film formed at least on a top surface of said metal interconnection pattern.

23. The semiconductor device as claimed in claim 21, wherein said metal thin-film resistance intersects with said metal interconnection pattern.

24. The semiconductor device as claimed in claim 21, wherein said metal interconnection pattern forms an uppermost metal interconnection pattern.

25. The semiconductor device as claimed in claim 1, wherein said base insulation film has a planarized surface.

26. The semiconductor device as claimed in claim 1, further comprising a metal nitride film covering a top surface of said metal thin-film resistance, wherein no metal oxide is formed between said top surface of said metal thin-film resistance and said metal oxide film.

27. A semiconductor device including a voltage divider providing a voltage output by dividing a voltage by two or more resistance elements, said voltage divider capable of adjusting said voltage output by irradiation of a laser beam upon at least one of said resistance elements,
said resistance element comprising:
a base insulation film formed on a semiconductor substrate via another layer;
a metal thin-film resistance formed on said base insulation film; and
a laser beam interruption film of a metal material interposed between said semiconductor substrate and said base insulation film.

28. A semiconductor device including a voltage detector, said voltage detector comprising: a voltage divider dividing an input voltage and providing a divided voltage; a reference voltage generator providing a reference voltage; and a comparator circuit comparing said divided voltage from said voltage divider and said reference voltage from said reference voltage generator,
said voltage divider providing said divided voltage by dividing said input voltage by two or more resistance elements, said voltage divider further capable of adjusting said voltage output by irradiation of a laser beam upon at least one of said resistance elements,
said resistance element comprising:
a base insulation film formed on a semiconductor substrate via another layer;
a metal thin-film resistance formed on said base insulation film; and
a laser beam interruption film of a metal material interposed between said semiconductor substrate and said base insulation film.

29. A semiconductor device having a constant voltage generator, said constant voltage generator comprising: an output driver supplied with an input voltage and producing an output voltage; a voltage divider dividing said output voltage of said output driver to produce a divided voltage; a reference voltage generator providing a reference voltage; and a comparator comparing said divided voltage of said voltage divider with said reference voltage from said reference voltage generator, said comparator controlling operation of said output driver in response to a result of comparison of said divided voltage and said reference voltage,
said voltage divider providing said divided voltage by dividing said output voltage by two or more resistance elements, said voltage divider further being capable of adjusting said voltage output by irradiation of a laser beam upon at least one of said resistance elements,
said resistance element comprising:
a base insulation film formed on a semiconductor substrate via another layer;
a metal thin-film resistance formed on said base insulation film; and
a laser beam interruption film of a metal material interposed between said semiconductor substrate and said base insulation film.
